(19) United States
(12) Patent Application Publication
(10) Pub. No.: US 2013/0126860 A1
(43) Pub. Date: May 23, 2013

(54) THIN FILM TRANSISTOR SUBSTRATE

(71) Applicants: Shunji FUKUDA, Tokyo-to (JP); Katsuya SAKAYORI, Tokyo-to (JP); Keita ARIHARA, Tokyo-to (JP)

(72) Inventors: Shunji FUKUDA, Tokyo-to (JP); Katsuya SAKAYORI, Tokyo-to (JP); Keita ARIHARA, Tokyo-to (JP)

(21) Appl. No.: 13/645,226

(22) Filed: Oct. 4, 2012

Related U.S. Application Data
(63) Continuation of application No. PCT/JP2011/058822, filed on Apr. 7, 2011.

(30) Foreign Application Priority Data
Apr. 9, 2010 (JP) 2010-090951
Apr. 9, 2010 (JP) 2010-090988
Apr. 9, 2010 (JP) 2010-090989

(51) Int. Cl. H01L 21/02; H01L 29/40

(52) U.S. Cl. CPC H01L 21/02118; H01L 29/408
USPC 257/43; 438/780

(57) ABSTRACT

A main object of the present invention is to provide a TFT substrate having excellent switching characteristics. The object is attained by providing a thin film transistor substrate comprising: a substrate, and a thin film transistor having an oxide semiconductor layer that is formed on the substrate and is formed from an oxide semiconductor, and a semiconductor layer-adjoining insulating layer formed to be in contact with the oxide semiconductor layer, wherein at least one semiconductor layer-adjoining insulating layer included in the thin film transistor is a photosensitive polyimide insulating layer formed by using a photosensitive polyimide resin composition.

### TECHNICAL FIELD

The present invention relates to a thin film transistor substrate having excellent switching characteristics.

### BACKGROUND ART

It is a trend of recent years that the range of applications of semiconductor transistors, which are represented by thin film transistors (hereinafter, may be referred to as TFTs), is ever expanding along with the development of display apparatuses. Such a semiconductor transistor has electrodes connected to one another through a semiconductor material, and thereby, the semiconductor transistor accomplishes the function as a switching element.

Regarding the insulating layers such as a gate insulating layer and a passivation layer that are used in TFTs, insulating layers formed by a vapor deposition method using an inorganic compound such as silicon oxide have been put to use (for example, JP 2000-324368 A).

However, when an insulating layer is formed by using such a vapor deposition method, vacuum facilities necessary for vapor deposition may be needed, or complicated processes such as patterning of a resist, etching of inorganic compounds, and peeling of the resist may be needed in order to form patterned insulating layers. Thus, there is a problem of increasing production cost. Furthermore, an insulating layer which uses an inorganic compound has a problem that the insulating layer is susceptible to cracking when used in a flexible substrate. Furthermore, in an insulating layer which uses an inorganic compound, it is difficult to make the layer thick, and there is a problem that there is a risk for the occurrence of a short circuit when foreign materials such as contaminants are present in the gate electrode, source/drain electrodes, pixel electrodes, and the like.

Contrary to such problems, when a resin insulating layer prepared by using a resin is used, the resin insulating layer can be produced by a simple process, as compared with an insulating layer made from an inorganic compound. Furthermore, since the vacuum facilities that are required for vapor deposition can be eliminated, the production cost can be reduced. Also, when resin insulating layers are used in a flexible substrate, the flexible substrate can be made unsusceptible to cracking. In addition, when such resin insulating layers are used, unlike those insulating layers formed from inorganic compounds as described above, the thickness of the insulating layers can be easily increased. Therefore, even if foreign materials are incorporated into the resin insulating layers, the occurrence of inconveniences such as short-circuiting can be prevented.

Furthermore, investigations have been conducted on photosensitive resin insulating layers which use photosensitive resins. In the case of a photosensitive resin insulating layer, the insulating layer can be formed by applying a photosensitive resin into a layer, and subjecting the photosensitive resin to exposure and development, so that the production process can be made simple as compared with the case of an insulating layer formed from an inorganic compound. Also, among such photosensitive resins, polyimides are preferably used because the resins have excellent heat resistance.

However, when a TFT is produced by using such resin insulating layers, there is a problem that, for example, switching characteristics are deteriorated, and thus, the characteristics required from TFTs are not sufficiently satisfactory.

### SUMMARY OF INVENTION

### Technical Problem

The present invention was achieved in view of the problems described above, and it is an object of the present invention to provide a TFT substrate having excellent switching characteristics.

### Solution to Problem

In order to solve the problem described above, the present invention provides a TFT substrate comprises a substrate; and a TFT having an oxide semiconductor layer that is formed on the substrate and is formed of an oxide semiconductor, and a semiconductor layer-adjoining insulating layer formed to be in contact with the oxide semiconductor layer, wherein at least one semiconductor layer-adjoining insulating layer included in the TFT is a photosensitive polyimide insulating layer formed by using a photosensitive polyimide resin composition.

According to the present invention, since at least one semiconductor layer-adjoining insulating layer included in the TFT is a photosensitive polyimide insulating layer as described above, that is, a layer formed by using a photosensitive polyimide resin composition, the TFT substrate may have excellent processability, heat resistance and insulating properties, the production can be achieved by a simple process, and excellent switching characteristics may be obtained.

Furthermore, since oxide semiconductors are known to have superior semiconductor characteristics among semiconductor materials, excellent semiconductor characteristics can be obtained by employing an oxide semiconductor layer as described above.

Also, in the case where the photosensitive polyimide insulating layer is a layer formed by using a photosensitive polyimide resin composition containing a polyimide precursor, it is necessary to imidize the polyimide precursor by subjecting the polyimide precursor to a dehydration-ring closure reaction through an annealing treatment. Furthermore, simultaneously with this imidization, water is generated. When an annealing treatment in the presence of water as such is carried out, that is, when a steam annealing treatment is carried out, the polyimide precursor can be imidized, and at the same time, the semiconductor characteristics of the oxide semiconductor can be enhanced. Thus, superior switching characteristics can be obtained. In other words, when a TFT substrate has both the oxide semiconductor layer and the photosensitive polyimide insulating layer, in particular, the TFT substrate can be produced by a simple process and can have excellent switching characteristics.

Furthermore, the inventors of the present invention repeatedly conducted research in order to solve the problem described above. As a result, the inventors found that in an insulating layer formed by using a conventional photosensitive polyimide resin composition, the photosensitive components and the like that are included in the photosensitive polyimide resin composition remain in large quantities, and that when these residual photosensitive components and the like are exposed to a high temperature atmosphere or a vacuum atmosphere in the subsequent production processes, the residual photosensitive components and the like are volatilized and outgassed, and these outgassed components are incorporated into the semiconductor layer as impurities, thereby causing deterioration in the semiconductor characteristics of the semiconductor layer, and making the TFT substrate unable to exhibit satisfactory switching characteristics. Thus, the inventors completed the present invention.

That is, the present invention provides a thin film transistor substrate comprising a substrate; and a thin film transistor having a semiconductor layer that is formed on the substrate, and a semiconductor layer-adjoining insulating layer formed to be in contact with the semiconductor layer, wherein at least one semiconductor layer-adjoining insulating layer is a low-outgassing photosensitive polyimide insulating layer formed by using a low-outgassing photosensitive polyimide resin composition having a 5% weight loss temperature of 450° C. or higher.

According to the present invention, since at least one semiconductor layer-adjoining insulating layer is a low-outgassing photosensitive polyimide insulating layer which has a small weight loss in the high temperature atmosphere or the vacuum atmosphere that is employed when the semiconductor layer and the like are formed, that is, which has less outgassing, the semiconductor layer can have fewer impurities originating from the semiconductor layer-adjoining insulating layer. As a result, the TFT substrate can have excellent switching characteristics.

Furthermore, since the low-outgassing photosensitive polyimide insulating layer is formed by using the low-outgassing photosensitive polyimide resin composition, the TFT substrate can be produced by a simple process.

In the present invention, it is preferable that the low-outgassing photosensitive polyimide resin composition contains a polyimide component and a photosensitive component, and the content of the photosensitive component be in the range of greater than or equal to 0.1 part by weight and less than 30 parts by weight relative to 100 parts by weight of the polyimide component. It is because the low-outgassing photosensitive polyimide insulating layer can have less outgassing, and thus, the TFT substrate can have excellent switching characteristics.

In the present invention, it is preferable that as for the semiconductor layer-adjoining insulating layer, a gate insulating layer in a top gate type thin film transistor, or at least one of a gate insulating layer and a passivation layer in a bottom gate type thin film transistor be the low-outgassing photosensitive polyimide insulating layer. It is because the TFT substrate can have further excellent switching characteristics.

It is preferable that the semiconductor layer be a deposited semiconductor layer formed by a vapor deposition method. Since the deposited semiconductor layer is usually formed in a high temperature vacuum atmosphere, if the TFT substrate has a semiconductor layer-adjoining insulating layer that is formed by using a conventional photosensitive polyimide resin composition, there is a high possibility that a large amount of outgassing from the semiconductor layer-adjoining insulating layer may occur at the time of forming the deposited semiconductor layer, and this may be incorporated into the deposited semiconductor layer as impurities. On the contrary, when a low-outgassing photosensitive polyimide insulating layer is used as the semiconductor layer-adjoining insulating layer, since less outgassing occurs even in a high temperature/vacuum atmosphere, the deposited semiconductor layer can have fewer impurities, and therefore, the effect of the present invention can be exhibited more effectively.

In the present invention, it is preferable that the semiconductor layer be an oxide semiconductor layer.

It is because since the oxide semiconductor is known to have excellent semiconductor characteristics even among semiconductor materials, the TFT substrate can have excellent semiconductor characteristics by employing the oxide semiconductor layer.

Furthermore, when the low-outgassing photosensitive polyimide resin composition contains a polyimide precursor as a polyimide component, it is necessary to imidize the polyimide precursor by subjecting the polyimide precursor to a dehydration-ring closure reaction through an annealing treatment. Furthermore, simultaneously with this imidization, water is generated. When an annealing treatment in the presence of water as such is carried out, that is, when a steam annealing treatment is carried out, the semiconductor characteristics of the oxide semiconductor can be enhanced simultaneously with the imidization of the polyimide precursor, and further excellent switching characteristics can be obtained.

Moreover, since the oxide semiconductor layer has a high curing temperature, the oxide semiconductor layer tends to be easily affected by outgassing. However, as discussed above, since the low-outgassing photosensitive polyimide insulating layer is used, the oxide semiconductor layer can be made less susceptible to the influence of outgassing, and the effect of the present invention can be more effectively exhibited.

As such, when the TFT has both the oxide semiconductor layer and the low-outgassing photosensitive polyimide insulating layer, in particular, the TFT substrate can be produced by a simple process, and can have excellent switching characteristics.

In the present invention, as for the semiconductor layer-adjoining insulating layer, at least the semiconductor layer-adjoining insulating layer on which the deposited semiconductor layer is directly laminated is preferably the low-outgassing photosensitive polyimide insulating layer.

When the deposited semiconductor layer is directly formed on a semiconductor layer-adjoining insulating layer formed by using a general photosensitive polyimide resin composition, the outgassing from the semiconductor layer-adjoining insulating layer is likely to be incorporated particularly into the deposited semiconductor layer, and the deposited semiconductor layer comes to contain a large amount of impurities.

On the contrary, when a low-outgassing photosensitive polyimide insulating layer formed by using the low-outgassing photosensitive polyimide resin composition is used as the semiconductor layer-adjoining insulating layer on which such a deposited semiconductor layer is directly formed, the occurrence of outgassing can be reduced, and the amount of outgassing incorporated into the deposited semiconductor layer can be reduced. As a result, even in the case of the deposited semiconductor layer as described above, a deposited semiconductor layer with fewer impurities can be provided, and thus the effect of the present invention can be more effectively exhibited.

Furthermore, the present invention also provides a TFT substrate comprising a substrate; and a TFT having a semiconductor layer formed on the substrate, and a semiconductor layer-adjoining insulating layer formed to be in contact with the semiconductor layer, wherein at least one semiconductor layer-adjoining insulating layer is a non-photosensitive polyimide insulating layer formed of a non-photosensitive polyimide resin.

According to the present invention, when the non-photosensitive polyimide insulating layer formed of a non-photosensitive polyimide resin is used, the non-photosensitive polyimide insulating layer can be made not to contain a photosensitive component which is a main cause of outgassing in the high temperature atmosphere or the vacuum atmosphere employed when the semiconductor layer and the like are formed, and thereby the occurrence of outgassing can be reduced. As a result, the semiconductor layer can be made to contain fewer impurities originating from the semiconductor layer-adjoining insulating layer, and a TFT substrate having excellent switching characteristics can be obtained.

In the present invention, it is preferable that the content of the polyimide resin contained in the non-photosensitive polyimide insulating layer be 80% by mass or greater. It is because a TFT substrate having excellent insulating properties can be obtained.

In the present invention, it is preferable that 5% weight loss temperature of the non-photosensitive polyimide insulating layer be 470° C. or higher. It is because the amount of outgassing can be reduced, and thus a TFT substrate having excellent switching characteristics can be obtained.

In the present invention, it is preferable that the semiconductor layer be an oxide semiconductor layer. It is because since the oxide semiconductor is known to have excellent semiconductor characteristics even among semiconductor materials, when the oxide semiconductor layer is employed, a TFT substrate having excellent semiconductor characteristics can be obtained. Furthermore, since the oxide semiconductor layer has a high curing temperature, the oxide semiconductor layer tends to be easily affected by outgassing. Accordingly, when the semiconductor layer-adjoining insulating layer is the non-photosensitive polyimide insulating layer, the oxide semiconductor layer can be made less susceptible to the influence of outgassing, and thereby, the effect of the present invention can be more effectively exhibited.

In the present invention, it is preferable that the non-photosensitive polyimide insulating layer be formed by using a non-photosensitive polyimide resin composition containing at least a polyimide precursor as a polyimide component.

When the non-photosensitive polyimide insulating layer is a layer formed by using a non-photosensitive polyimide resin composition containing a polyimide precursor, it is necessary to imidize the polyimide precursor by subjecting the polyimide precursor to a dehydration-ring closure reaction through an annealing treatment. However, water is generated simultaneously with this imidization. When an annealing treatment in the presence of water as such is carried out, that is, a steam annealing treatment is carried out, the semiconductor characteristics of the oxide semiconductor can be enhanced simultaneously with the imidization of the polyimide precursor, and thus a TFT substrate having further excellent switching characteristics can be obtained. Therefore, a TFT substrate having excellent switching characteristics can be obtained particularly by a simple process.

In the present invention, it is preferable that as for the semiconductor layer-adjoining insulating layer, the gate insulating layer in a top gate type TFT, or at least one of the gate insulating layer and the passivation layer in a bottom gate type TFT, be the non-photosensitive polyimide insulating layer. It is because a TFT substrate having excellent switching characteristics can be obtained.

In the present invention, it is preferable that the photosensitive component include a photoacid generator or a photobase generator as a main component. It is because a TFT substrate with less outgassing can be obtained.

In the present invention, it is preferable that the photosensitive component be a photobase generator. It is because the influence on the metals and the like that are contained in the TFT substrate of the present invention can be decreased.

In the present invention, it is preferable that the base generated from the photobase generator be aliphatic amine or amidine. It is because an excellent catalytic effect and the like can be obtained.

In the present invention, it is preferable that the 5% weight loss temperature of the photobase generator be in the range of 150° C. to 300° C. It is because the photosensitive polyimide insulating layer and the low-outgassing photosensitive polyimide insulating layer can be easily formed, and the amount of outgassing can be reduced.

In the present invention, it is preferable that the photobase generator be a compound represented by the following formula (a):

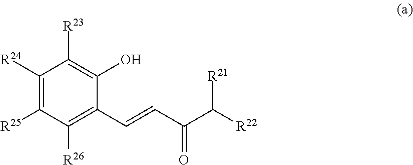

in the formula (a), R²¹ and R²², which may be identical with or different from each other, each independently represent a hydrogen atom or a monovalent organic group; R²¹ and R²² may be bonded to each other and form a cyclic structure, and may contain a bond with a heteroatom, provided that at least one of R²¹ and R²² is a monovalent organic group; R²³, R²⁴, R²⁵ and R²⁶, which may be identical with or different from each other, each independently represent a hydrogen atom, a halogen atom, a hydroxyl group, a mercapto group, a sulfide group, a silyl group, a silanol group, a nitro group, a nitroso group, a sulfino group, a sulfo group, a sulfonato group, a phosphino group, a phosphinyl group, a phosphono group, a phosphonato group, an amino group, an ammonia group, or a monovalent organic group; and two or more of R²³, R²⁴, R²⁵ and R²⁶ may be bonded to each other and form a cyclic structure, or may also contain a bond with a heteroatom.

In the present invention, it is preferable that the substrate be a flexible substrate having a metal foil, and a planarizing layer that is formed on the metal foil and contains a polyimide.

It is because by the substrate having the planarizing layer, since a planarizing layer containing a polyimide is formed on a metal foil, the surface unevenness of the metal foil can be planarized, and a decrease in the electrical performance of the TFT can be prevented. It is also because, unlike the insulating layers formed from inorganic substances, the photosensitive polyimide insulating layer, the low-outgassing photosensitive polyimide insulating layer, and the non-photosensitive polyimide insulating layer do not cause inconveniences such as cracking even if a flexible substrate is used as the substrate.

In the present invention, it is preferable that the flexible substrate have an adhesion layer containing an inorganic compound on the planarizing layer.

When the flexible substrate has the adhesion layer, the flexible substrate can be made to have excellent adhesiveness to a TFT, and even in the case where moisture or heat is applied at the time of production of the TFT substrate, and the dimension of the planarizing layer containing a polyimide is changed, the electrode, oxide semiconductor layer, and semiconductor layer that constitute a TFT can be prevented from undergoing peeling or cracking.

The present invention provides a method for producing a TFT substrate, the TFT substrate comprises a substrate, and a TFT including a semiconductor layer formed on the substrate and a semiconductor layer-adjoining insulating layer formed to be in contact with the semiconductor layer, in which at least one semiconductor layer-adjoining insulating layer is a non-photosensitive polyimide insulating layer formed of a non-photosensitive polyimide resin, the method comprising steps of: a non-photosensitive polyimide film forming step of forming a non-photosensitive polyimide film formed of a non-photosensitive polyimide resin on the substrate; and a non-photosensitive polyimide film patterning step of patterning the non-photosensitive polyimide film and thereby forming the non-photosensitive polyimide insulating layer.

According to the present invention, by having the non-photosensitive polyimide film patterning step, that is, by patterning an imidized non-photosensitive polyimide film, the member at a site that is covered by the non-photosensitive polyimide insulating layer can be made unsusceptible to the influence of development. Therefore, a TFT having high reliability can be obtained.

The present invention provides a method for producing a TFT substrate, TFT substrate comprising a substrate, and a TFT having a semiconductor layer formed on the substrate and a semiconductor layer-adjoining insulating layer formed to be in contact with the semiconductor layer, in which at least one semiconductor layer-adjoining insulating layer is a non-photosensitive polyimide insulating layer formed of a non-photosensitive polyimide resin, the method comprises steps of: a non-photosensitive polyimide precursor film forming step of forming a non-photosensitive polyimide precursor film containing a polyimide precursor on the substrate; a non-photosensitive polyimide precursor pattern forming step of patterning the non-photosensitive polyimide precursor film and thereby forming a non-photosensitive polyimide precursor pattern; and an imidization step of imidizing the polyimide precursor contained in the non-photosensitive polyimide precursor pattern and thereby forming a non-photosensitive polyimide insulating layer.

According to the present invention, the polyimide precursor prior to imidization has a carboxyl group and is capable of alkali development. Also, since the polyimide precursor has higher solubility than a polyimide resin and is capable of solvent development, pattern forming can be easily achieved by having the non-photosensitive polyimide precursor pattern forming step. Therefore, a non-photosensitive polyimide insulating layer can be formed with high pattern accuracy, and a TFT substrate having an excellent product quality can be obtained.

### Advantageous Effects of Invention

The present invention offers an effect that a TFT substrate having excellent switching characteristics can be provided.

### BRIEF DESCRIPTION OF DRAWINGS

FIGS. 1A and 1B are each a schematic cross-sectional diagram illustrating an example of a TFT substrate of the present invention.

FIGS. 2A and 2B are each a schematic cross-sectional diagram illustrating another example of the TFT substrate of the present invention.

FIGS. 3A and 3B are each a schematic cross-sectional diagram illustrating yet another example of the TFT substrate of the present invention.

FIG. 4 is a schematic cross-sectional diagram illustrating an example of a flexible substrate used in the present invention.

FIGS. 5A and 5B are each a schematic cross-sectional diagram illustrating another example of a flexible substrate used in the present invention.

FIGS. 6A to 6E is a process diagram illustrating an example of a method for producing a TFT substrate of the present invention.

FIGS. 7A to 7E is a process diagram illustrating another example of the method for producing a TFT substrate of the present invention.

### DESCRIPTION OF EMBODIMENTS

The present invention relates to a TFT substrate and a method for producing the TFT substrate.

Hereinafter, the TFT substrate and the method for producing a TFT substrate of the present invention will be described in detail.

A. TFT Substrate

First, the TFT substrate of the present invention will be described.

The TFT substrate of the present invention comprises: a substrate, and a TFT having a semiconductor layer formed on the substrate and a semiconductor layer-adjoining insulating layer formed to be in contact with the semiconductor layer, wherein the semiconductor layer is an oxide semiconductor layer formed of an oxide semiconductor. The TFT substrate can be classified into three embodiments, including an embodiment in which at least one semiconductor layer-adjoining insulating layer included in the TFT is a photosensitive polyimide insulating layer formed by using a photosensitive polyimide resin composition (first embodiment); an embodiment in which at least one semiconductor layer-adjoining insulating layer is a low-outgassing photosensitive polyimide insulating layer formed by using a low-outgassing photosensitive polyimide resin composition having a 5% weight loss temperature of 450° C. or higher (second embodiment); and an embodiment in which at least one semiconductor layer-adjoining insulating layer is a non-photosensitive polyimide insulating layer formed of a photosensitive polyimide resin (third embodiment).

Hereinafter, each embodiment of the TFT substrate of the present invention will be described.

### I. First Embodiment

The TFT substrate of the present embodiment comprises: the substrate described above, and a TFT having a semiconductor layer formed on the substrate and a semiconductor layer-adjoining insulating layer formed to be in contact with the semiconductor layer, and the semiconductor layer is an oxide semiconductor layer formed of an oxide semiconductor, wherein at least one semiconductor layer-adjoining insulating layer included in the TFT is a photosensitive polyimide insulating layer formed by using a photosensitive polyimide resin composition.

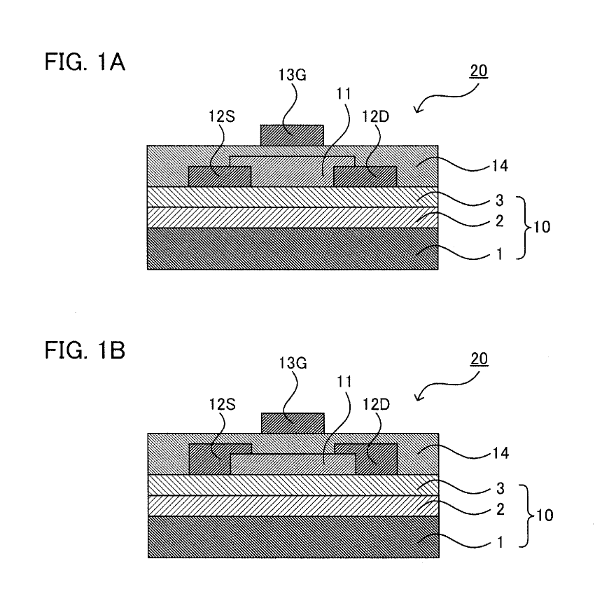

Such TFT substrate of the present invention will be explained with reference to the attached drawings. FIGS. 1A and 1B are each a schematic cross-sectional diagram illustrating an example of a TFT substrate according to the present embodiment. As illustrated in FIG. 1A, a TFT substrate 20 according to the present embodiment comprises a flexible substrate 10 having a metal foil 1, a planarizing layer 2 that is formed on the metal foil 1 and contains polyimide, and an adhesion layer 3 that is formed on the planarizing layer 2 and contains an inorganic compound; a source electrode 12S and a drain electrode 12D as well as an oxide semiconductor layer 11 that are formed on the adhesion layer 3 of the flexible substrate 10; a gate insulating layer 14 that is formed on the source electrode 12S, the drain electrode 121D and the oxide semiconductor layer 11 by using the photosensitive polyimide resin composition described above; and a gate electrode 13G that is formed on the gate insulating layer 14; and has a top-gate bottom-contact structure.

Furthermore, a TFT substrate 20 illustrated in FIG. 1B includes a TFT having a top-gate top-contact structure, and comprises: an oxide semiconductor layer 11 as well as a source electrode 12S and a drain electrode 12D formed on an adhesion layer 3 of a flexible substrate 10; a gate insulating layer 14 formed on the oxide semiconductor layer 11 as well as the source electrode 12S and the drain electrode 12D by using the photosensitive polyimide resin composition described above; and a gate electrode 13G formed on the gate insulating layer 14.

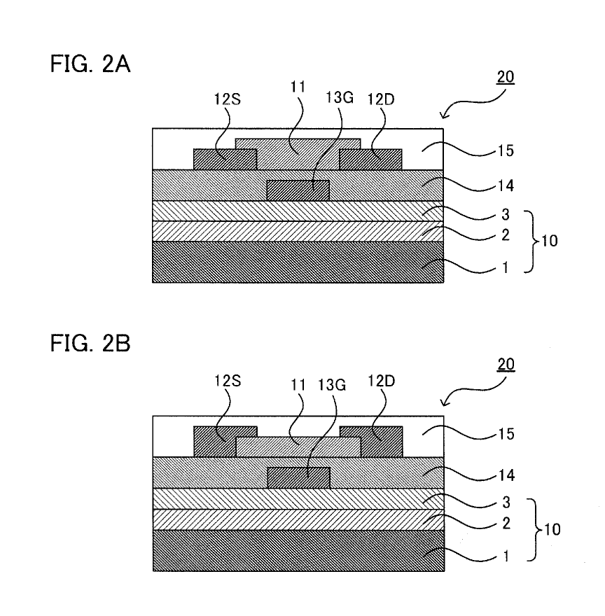

Furthermore, as illustrated in FIG. 2A as another example of the TFT substrate of the present embodiment, a TFT substrate 20 includes a TFT having a bottom-gate bottom-contact structure, and comprises: a gate electrode 13G formed on an adhesion layer 3 of a flexible substrate 10; a gate insulating layer 14 formed so as to cover the gate electrode 13G by using the photosensitive polyimide resin composition described above; a source electrode 12S and a drain electrode 12D as well as an oxide semiconductor layer 11 formed on the gate insulating layer 14; and a passivation layer 15 formed on the source electrode 12S, the drain electrode 12D and the oxide semiconductor layer 11 by using the photosensitive polyimide resin composition described above.

Also, a TFT substrate 20 illustrated in FIG. 2B includes a TFT having a bottom-gate top-contact structure, and comprises: a gate electrode 13G formed on an adhesion layer 3 of a flexible substrate 10; a gate insulating layer 14 formed so as to cover the gate electrode 13G by using the photosensitive polyimide resin composition described above; an oxide semiconductor layer 11 as well as a source electrode 12S and a drain electrode 12D formed on the gate insulating layer 14; and a passivation layer 15 formed on the oxide semiconductor layer 11, the source electrode 12S and the drain electrode 12D by using the photosensitive polyimide resin composition described above.

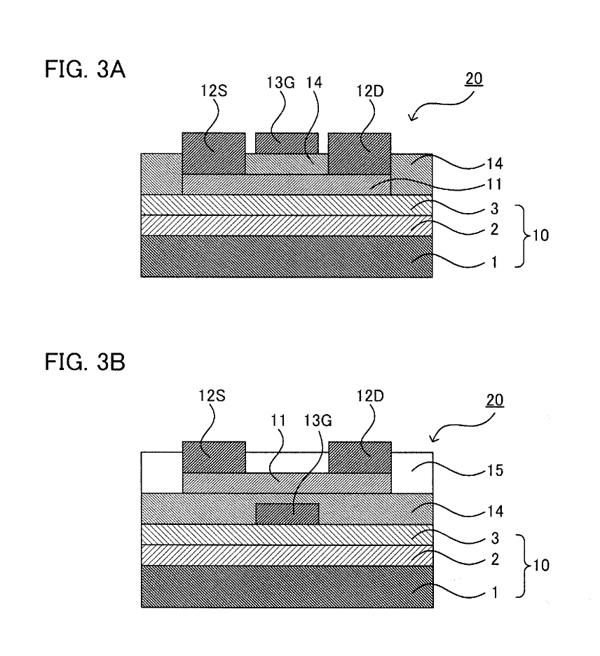

Moreover, as illustrated in FIG. 3A as another example of the TFT substrate of the present embodiment, a TFT substrate 20 includes a TFT having a top gate type coplanar structure, and comprises: an oxide semiconductor layer 11 formed on an adhesion layer 3 of a flexible substrate 10; a source electrode 12S and a drain electrode 12D formed on the oxide semiconductor layer 11; a gate insulating layer 14 formed on the oxide semiconductor layer 11 by using the photosensitive polyimide resin composition described above; and a gate electrode 13G formed on the gate insulating layer 14.

Furthermore, a TFT substrate 20 illustrated in FIG. 3B includes a TFT having a bottom gate type coplanar structure, and comprises: a gate electrode 13G formed on an adhesion layer 3 of a flexible substrate 10; a gate insulating layer 14 formed on the gate electrode 13G by using the photosensitive polyimide resin composition; an oxide semiconductor layer 11 formed on the gate insulating layer 14; a source electrode 12S and a drain electrode 12D formed on the oxide semiconductor layer 11; and a passivation layer 15 formed on the oxide semiconductor layer 11 by using the photosensitive polyimide resin composition.

Furthermore, the semiconductor layer-adjoining insulating layer in the top gate type TFT illustrated in FIGS. 1A to 1B and FIG. 3A is a gate insulating layer, and the semiconductor layer-adjoining insulating layers in the bottom gate type TFT illustrated in FIG. 2 and FIG. 3B are a gate insulating layer and a passivation layer (FIGS. 2A and 2B). In this example, all of these semiconductor layer-adjoining insulating layers are the photosensitive polyimide insulating layers described above.

According to the present invention, at least one of the semiconductor layer-adjoining insulating layers included in the TFTs is a photosensitive polyimide insulating layer formed by using the photosensitive polyimide resin composition, that is, a layer formed by using the photosensitive polyimide resin composition. Thus, the insulating layers can be formed by applying and patterning the photosensitive polyimide resin composition without carrying out a vapor deposition process using vacuum facilities that are required in the formation of insulating layers formed from inorganic compounds, and therefore, a simple process can be employed.

Furthermore, when the photosensitive polyimide insulating layer contains polyimide, an insulating layer having excellent heat resistance can be obtained, and even in the case of being exposed to a high temperature atmosphere at the time of production of the oxide semiconductor layer or other members, the decrease in the insulating performance can be reduced. Therefore, a TFT substrate having excellent switching characteristics can be obtained. Furthermore, since the substrate is made of a resin, for example, even in the case of obtaining a flexible TFT substrate by using a flexible substrate as the substrate, the photosensitive polyimide insulating layers can be made unsusceptible to cracking.

Moreover, since the oxide semiconductor is known to have excellent semiconductor characteristics among semiconductor materials, the TFT substrate of the present embodiment can be made to have excellent semiconductor characteristics by employing the oxide semiconductor layer.

Here, it is known that the oxide semiconductor can have the semiconductor characteristics further enhanced by subjecting the oxide semiconductor to an annealing treatment in the presence of water (a steam annealing treatment) (Appl. Phys. Lett. 93, 192107 (2008), and the like).

On the other hand, in the case of forming the photosensitive polyimide insulating layer by using a photosensitive polyimide resin composition containing a polyimide precursor as a polyimide component, it is necessary to imidize the polyimide precursor by subjecting the polyimide precursor to a dehydration-ring closure reaction through an annealing treatment. Furthermore, water is generated simultaneously with this imidization. When such an annealing treatment in the presence of water, that is, a steam annealing treatment is carried out, the semiconductor characteristics of the oxide semiconductor can be enhanced simultaneously with imidizing the polyimide precursor, and a TFT substrate having further excellent switching characteristics can be obtained. Therefore, the semiconductor characteristics of the oxide semiconductor layer can be enhanced without adding another steam annealing process.

As such, by having both the oxide semiconductor layer and the photosensitive polyimide insulating layer, the TFT substrate can be produced particularly by a simple process, and can have excellent switching characteristics.

The TFT substrate of the present embodiment has at least a substrate and a TFT.

Hereinafter, the various constitutions of the TFT substrate of the present embodiment will be described in detail.

1. TFT

The TFT used in the present embodiment comprises at least the oxide semiconductor layer and the semiconductor layer-adjoining insulating layer described above.

(1) Semiconductor Layer-Adjoining Insulating Layer

The semiconductor layer-adjoining insulating layer used in the present embodiment is a layer that is in contact with the oxide semiconductor layer, and at least one is the photosensitive polyimide insulating layer.

(a) Photosensitive Polyimide Insulating Layer

The photosensitive polyimide insulating layer used in the present embodiment is formed by using a photosensitive polyimide resin composition.

(i) Photosensitive Polyimide Resin Composition

The photosensitive polyimide resin composition used in the present embodiment is not particularly limited as long as a photosensitive polyimide insulating layer having desired insulating properties can be accurately formed, but an example of the resin composition may be a composition containing: a) a polyimide component, b) a photosensitive component, c) a solvent, and d) others.

Specific examples of the resin composition include a solvent development negative type photosensitive polyimide resin composition obtained by introducing an ethylenic double bond to the carboxyl group of polyamic acid which is a polyimide component, to the polyimide component as a photosensitive component, by ester bonding or ionic bonding, and further incorporating a photoradical initiator; an alkali development positive type photosensitive polyimide resin composition obtained by adding a naphthoquinone diazide compound as a photosensitive component to polyamic acid or a partial esterification product thereof, which is a polyimide component; a negative type photosensitive polyimide resin composition obtained by adding a photoacid generator as a photosensitive component to polyimide or a polyimide precursor, to which an acid-crosslinkable substituent has been introduced, as a polyimide component; a positive type photosensitive polyimide resin composition obtained by adding a photoacid generator as a photosensitive component to polyimide or a polyimide precursor, to which an acid-decomposable substituent has been introduced, as a polyimide component; an alkali development negative type photosensitive polyimide resin composition obtained by adding a photoacid generator as a photosensitive component to polyamic acid which is a polyimide component, or an alkali development negative type photosensitive polyimide resin composition obtained by adding a nifedipine-based compound or the like as a photosensitive component to polyamic acid which is a polyimide component; and an alkali development negative type photosensitive polyimide resin composition obtained by adding a photobase generator as a photosensitive component to polyamic acid which is a polyimide component.

The photosensitive polyimide resin composition used in the present embodiment preferably has a 5% weight loss temperature of 450° C. or higher.

Here, a photosensitive polyimide resin composition having a 5% weight loss temperature of 450° C. or higher means that with regard to a polyimide film containing a polyimide resin that is obtained by curing of the photosensitive polyimide resin composition, on the occasion of measuring the weight loss by using a thermogravimetric analyzer, the 5% weight loss temperature measured by increasing the temperature of the polyimide film to 100° C. at a rate of temperature increase of 10° C./min in a nitrogen atmosphere, subsequently heating the polyimide film at 100° C. for 60 minutes, subsequently leaving the polyimide film to cool for 15 minutes or longer in a nitrogen atmosphere, and then measuring the 5% weight loss temperature at a rate of temperature increase of 10° C./min, on the basis of the weight after cooling, is 450° C. or higher.

Meanwhile, the 5% weight loss temperature is the temperature at a time point when the weight of a sample has decreased by 5% from the initial weight (that is, a time point when the sample weight becomes 95% of the initial weight) when the weight loss is measured by using a thermogravimetric analyzer.

In the present embodiment, above all, the 5% weight loss temperature of the photosensitive polyimide resin composition is preferably 480° C. or higher, and particularly preferably 500° C. or higher. It is because when the 5% weight loss temperature is in the range described above, a photosensitive polyimide resin composition having a small weight loss, that is, which produces less outgassing, in a high temperature atmosphere or a vacuum atmosphere when the oxide semiconductor layer or other members are formed, and a TFT substrate having excellent switching characteristics can be obtained. Particularly, since the oxide semiconductor layer is usually formed in a high temperature, vacuum atmosphere, when the oxide semiconductor layer is formed in an environment where a large amount of outgassing may occur, there is a high possibility that the outgassed components may be incorporated into the oxide semiconductor layer as impurities. On the contrary, when a photosensitive polyimide resin composition having a 5% weight loss temperature as described above is used to form a photosensitive polyimide insulating layer, even in a high temperature, vacuum atmosphere, the generation of outgassed components from the photosensitive polyimide insulating layer is small, and therefore, the oxide semiconductor layer can have fewer impurities.

Furthermore, the outgassed components that are included in the photosensitive polyimide insulating layer formed by using such a photosensitive polyimide resin composition usually do not undergo an increase in the amount to a large extent under general TFT production conditions or general TFT use environment. Therefore, the 5% weight loss temperature of the photosensitive polyimide insulating layer is equivalent to the 5% by weight loss temperature of the photosensitive polyimide resin composition.

a. Polyimide Component

The polyimide component used in the present embodiment means a component that becomes a polyimide resin after being cured among a photosensitive polyimide resin composition.

Specific examples thereof include a polyimide having a structure represented by the following formula (1), and polyimide precursors having structures represented by the following formulas (2) and (3).

As the polyimide component in the present embodiment, only a polymer having a structure represented by any one of the formula (1), formula (2) and formula (3) may be used, a mixture of polymers each having a structure represented by any one of the formula (1), formula (2) and formula (3) may be used, or a polymer having the structures of the formula (1), formula (2) and formula (3) mixed in one polymer molecule chain may be used.

In the present embodiment, it is preferable that the polyimide component include at least the polyimide precursor described above. It is because since water is generated at the time of the annealing treatment for imidization, the oxide semiconductor layer can be subjected to steam annealing simultaneously with imidization, so that the semiconductor characteristics can be enhanced.

In the present embodiment, above all, the polyimide component desirably has a carboxyl group derived from an acid anhydride (or a derivative thereof such as an esterification product) at a proportion of 50% or greater, and preferably 75% or greater, of the total amount of the component, and it is preferable that the polyimide component is entirely a polyamic acid represented by the following formula (2) or a derivative thereof. It is because the steam annealing treatment described above can be effectively carried out.

Furthermore, in regard to the polyamic acid represented by the formula (2) (and) a derivative thereof, it is particularly preferable that the compound be a polyamic acid in which R³'s all represent hydrogen atoms, from the viewpoints of the ease of synthesis and high solubility in alkali developing liquids.

Meanwhile, the content of the carboxyl group (or an ester thereof) derived from an acid anhydride can be determined by means of the 100% imidization ratio (%). Therefore, when the content of the carboxyl group (or an ester thereof) derived from an acid anhydride is 50% of the total amount, this indicates that the imidization ratio is 50%.

Meanwhile, the imidization ratio can be checked by using, for example, infrared absorption spectroscopy. Specifically, the imidization ratio can be determined by quantitatively determining the content of the carboxyl group from the peak area of the C═O double bond derived from an imide bond that is contained in the polyimide resin.

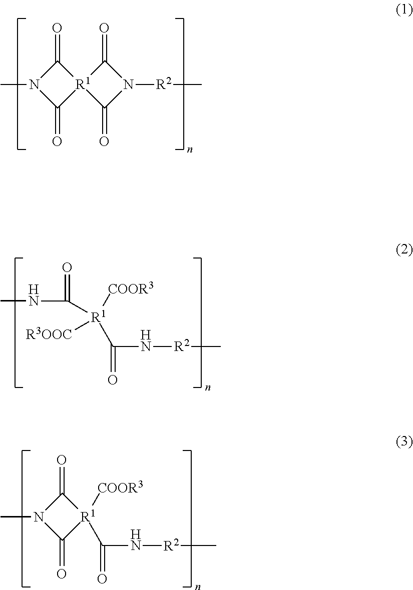

In the formulas (1) to (3), R¹ represents a tetravalent organic group; R² represents a divalent organic group; R³ represents a hydrogen atom or a monovalent organic group; repeating R¹'s, R²'s and R³'s may be identical with or different from each other; and “n” represents a natural number of 1 or greater.

Furthermore, although the formula (3) is laterally asymmetric, but a compound in which the direction of the structure is laterally different in one polymer molecule chain may also be included.

Furthermore, as in the case of a solvent development negative type photosensitive polyimide resin composition obtained by introducing an ethylenic double bond to the carboxyl group of polyamic acid by ester bonding, and further incorporating a photoradical initiator therein, in a compound in which a photosensitive moiety is introduced by covalent bonding through the carboxyl group of polyamic acid, up to the C(═O)—O moiety of the carboxyl group of polyamic acid is regarded as the polyimide component, while the substituent moiety including the photosensitive moiety introduced further than the C(═O)—O moiety is regard as the photosensitive component.

Also, in a solvent development negative type photosensitive polyimide resin composition obtained by introducing an ethylenic double bond to the carboxyl group of polyamic acid by ionic bonding, and further incorporating a photoradical initiator therein, polyamic acid is used as the polyimide component, and the amine having an ethylenic double bond that is bound by ionic bonding is used as the photosensitive component.

In the formulas (1) to (3), generally, R¹ represents a structure derived from a tetracarboxylic acid dianhydride; and R² represents a structure derived from diamine.

As the method for producing the polyimide component used in the present embodiment, conventionally known techniques can be applied. Examples of a method for forming a polyimide precursor having a structure represented by the formula (2) include, but are not limited to, (i) a technique of synthesizing polyamic acid from acid dianhydride and diamine; and (ii) a technique of forming a polyimide precursor by allowing acid dianhydride to react with a monohydric alcohol, an amino compound, an epoxy compound or the like to synthesize ester acid or amide acid monomer, and allowing the carboxylic acid of the ester acid or amide acid monomer to react with a diamino compound or a derivative thereof.

Furthermore, examples of a method for forming a polyimide precursor having a structure represented by the formula (3) or polyimide represented by the formula (1) include a method of imidizing a polyimide precursor represented by the formula (2) by heating.

Examples of tetracarboxylic acid dianhydride that is applicable to the polyimide component in the present embodiment include aliphatic tetracarboxylic acid dianhydrides such as ethylenetetracarboxylic acid dianhydride, butanetetracarboxylic acid dianhydride, cyclobutanetetracarboxylic acid dianhydride, methylcyclobutanetetracarboxylic acid dianhydride, and cyclopentanetetracarboxylic acid dianhydride; and aromatic tetracarboxylic acid dianhydrides such as pyromellitic dianhydride, 3,3′,4,4′-benzophenonetetracarboxylic acid dianhydride, 3,3′,4,4′-biphenyltetracarboxylic acid dianhydride, 2,2′,6,6′-biphenyltetracarboxylic acid dianhydride, bis(3,4-dicarboxyphenyl)ether dianhydride, and 2,2-bis(3,4-dicarboxyphenyl)-1,1,1,3,3,3-hexafluoropropane dianhydride.

On the other hand, as the diamine component that is applicable to the polyimide component, one kind of diamine can be used alone, or two or more kinds of diamines can be used in combination.

In regard to the photosensitive polyimide resin composition according to the present embodiment, from the viewpoint of adjusting the 5% weight loss temperature of the insulating layers to a predetermined range, and thereby making the 5% weight loss temperature of the insulating layers suitable for the TFT substrate of the present embodiment, it is preferable that the polyimide component contain an aromatic backbone. It is because a polyimide resin obtainable by heating and curing a polyimide component containing an aromatic backbone has excellent heat resistance and excellent insulating properties as a thin film, which are derived from the rigid backbone with high planarity, has a high 5% weight loss temperature, and has less outgassing, and therefore, the polyimide resin can be preferably used in the insulating layers of the TFT substrate of the present embodiment.

Furthermore, it is desirable that the polyimide component of the photosensitive polyimide resin composition has a high 5% weight loss temperature and has less outgassing, the moiety derived from an acid dianhydride has an aromatic structure, and the moiety derived from diamine also contains an aromatic structure. Therefore, it is preferable that the structure derived from the diamine component be also a structure derived from aromatic diamine. Particularly, it is preferable that the polyimide component be all-aromatic polyimide or an all-aromatic polyimide precursor in which both the moiety derived from acid dianhydride and the moiety derived from diamine contain aromatic structures.

Here, the all-aromatic polyimide precursor refers to a polyimide precursor or a derivative thereof, which is obtainable by copolymerization of an aromatic acid component and an aromatic amine component, or polymerization of aromatic acid/amino component. Furthermore, the aromatic acid component means a compound in which four acid groups that form a polyimide backbone are all substituted on an aromatic ring, the aromatic amine component means a compound in which two amino groups that form a polyimide backbone are both substituted on an aromatic ring, and the aromatic acid/amino component means a compound in which the acid group and the amino group that form a polyimide backbone are all substituted on an aromatic ring. However, as is obvious from the specific examples of the aromatic acid dianhydride and the aromatic diamine as the raw materials described above, it is not necessary that all acid groups or amino groups be present on the same aromatic ring.

From the reasons described above, a polyimide precursor is preferably such that in the case where the polyimide resin finally obtainable is required to have heat resistance and dimensional stability, the copolymerization ratio of the aromatic acid component and/or aromatic amine component be as high as possible. Specifically, the proportion of the aromatic acid component in the acid components that constitute repeating units having an imide structure is preferably 50% by mole or greater, and particularly preferably 70% by mole or greater, and the proportion of the aromatic amine component in the amine components that constitute repeating units having an imide structure is preferably 40% by mole or greater, and particularly preferably 60% by mole or greater. It is also preferable that the polyimide component be all-aromatic polyimide or an all-aromatic polyimide precursor.

In the present embodiment, above all, it is preferable that 33% by mole or more of R¹ in the polyimide component having a structure represented by any one of the formulas (1) to (3) have any of structures represented by the following formulas. It is because there is an advantage that a polyimide resin which exhibits excellent heat resistance and has a low coefficient of linear thermal expansion is obtained.

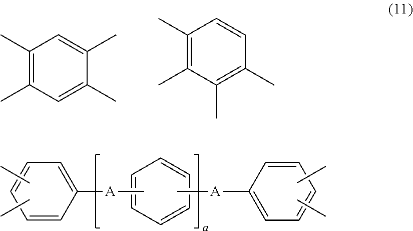

In the formula (11), “a” represents 0 or a natural number of 1 or greater; A represents any one of a single bond (biphenyl structure), an oxygen atom (ether bond), and an ester bond, and A's may be all identical with or different from each other; and the bond group is located at the 2-position and 3-position, or the 3-position and 4-position of the aromatic ring when viewed from the bonding site of the aromatic ring.

In the present embodiment, particularly, if the polyimide component having a structure represented by any of the formulas (1) to (3) contains a structure represented by the formula (11), the polyimide resin exhibits low hygroscopic expansion. There is also an advantage that the polyimide resin is easily commercially available and is inexpensive.

The polyimide component having a structure as described above can form a polyimide resin which exhibits high heat resistance and a low coefficient of linear thermal expansion. Accordingly, it is more preferable if the content of the structures represented by the above formulas is closer to 100% by mole among R¹'s in the formulas (1) to (3), but it is acceptable if the content is at least 33% or more among R¹'s in the formulas (1) to (3). Above all, the content of the structures represented by the above-shown formulas is preferably 50% by mole or greater, and more preferably 70% by mole or greater, among R¹'s in the formulas (1) to (3).

According to the present embodiment, examples of the structure of acid dianhydride which makes the polyimide resin less hygroscopic include a structure represented by the following formula (12):

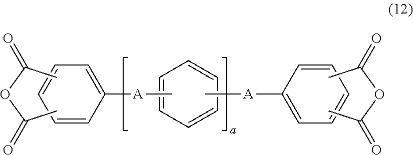

in the formula (12), “a” represents 0 or a natural number of 1 or greater; A represents any one of a single bond (biphenyl structure), an oxygen atom (ether bond), and an ester bond, and all A's may be identical with or different from each other; the acid anhydride backbone (—CO—O—CO—) is bonded at the 2-position and 3-position, or the 3-position and 4-position of the aromatic ring when viewed from the bonding site of the adjacent aromatic ring.

In the above formula (12), examples of acid dianhydride in which A represents a single bond (biphenyl structure) or an oxygen atom (ether bond) include 3,3′,4,4′-biphenyltetracarboxylic acid dianhydride, 2,3,3′,4′-biphenyltetracarboxylic acid dianhydride, 2,3,2′,3′-biphenyltetracarboxylic acid dianhydride, and bis(3,4-dicarboxyphenyl)ether dianhydride. These are preferred from the viewpoint of decreasing the coefficient of hygroscopic expansion and from the viewpoint of broadening the selectivity for diamine.

In the above formula (12), phenyl ester-based acid dianhydride in which A represents an ester bond is particularly preferred from the viewpoint of making the polyimide resin less hygroscopic. Examples thereof include acid dianhydrides represented by the following formulas. Specific examples include p-phenylenebistrimellitic acid monoester acid dianhydride, and p-biphenylenebistrimellitic acid monoester acid dianhydride. These are particularly preferred from the viewpoint of decreasing the coefficient of hygroscopic expansion and from the viewpoint of broadening the selectivity for diamine.

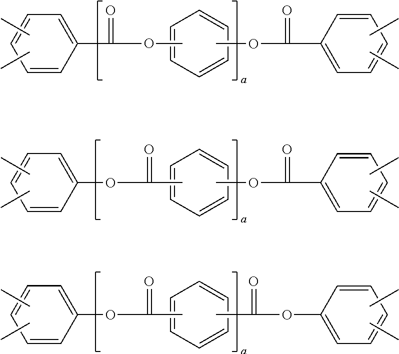

In the formula, “a” represents 0 or a natural number of 1 or greater; and the acid anhydride backbone (—CO—O—CO—) is bonded to the 2-position and 3-position or the 3-position and 4-position of the aromatic ring when viewed from the bonding site of the adjacent aromatic ring.

In the case of a tetracarboxylic acid dianhydride having a small coefficient of hygroscopic expansion, the diamine that will be described below can be selected from a wide range.

As the tetracarboxylic acid dianhydride to be used in combination, a tetracarboxylic acid dianhydride having at least one fluorine atom represented by the following formula can be used. When the tetracarboxylic acid dianhydride having fluorine introduced therein is used, the coefficient of hygroscopic expansion of the polyimide resin finally obtainable is decreased. Above all, the tetracarboxylic acid dianhydride having at least one fluorine atom is preferably a tetracarboxylic acid dianhydride having a fluoro group, a trifluoromethyl group, or a trifluoromethoxy group. Specific examples thereof include 2,2-bis(3,4-dicarboxyphenyl)-1,1,1,3,3,3-hexafluoropropane dianhydride. However, when a polyimide precursor that is included as the polyimide component has a backbone structure containing fluorine, the polyimide precursor tends to be not easily soluble in basic aqueous solutions, so that when patterning is carried out by using a resist or the like while the polyimide component is still in the state of being a precursor, it may be necessary to carry out development by means of a solution mixture of an organic solvent such as an alcohol and a basic aqueous solution.

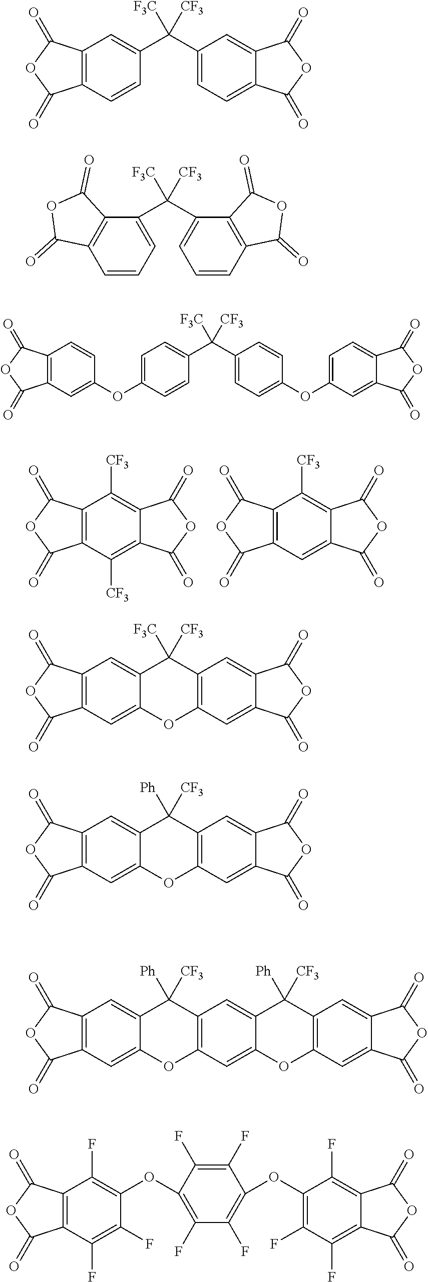

Here, the diamine to be selected is preferably aromatic diamine from the viewpoint of heat resistance, that is, low outgassing; however, in accordance with the intended properties, a diamine other than aromatic diamine, such as aliphatic diamine or siloxane-based diamine, may also be used in an amount in the range of no greater than 60% by mole, and preferably 40% by mole, of the total amount of diamines.

Also, the polyimide component is preferably such that 33% by mole or more of R²'s in the above formulas (1) to (3) have a structure represented by any one of the following formulas:

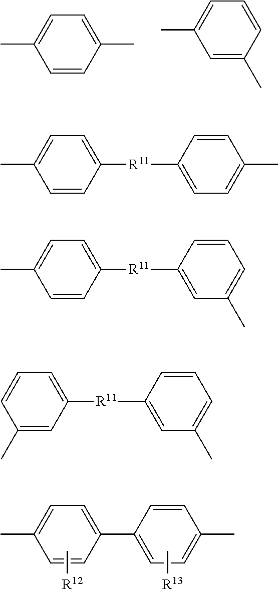

in which, R¹¹ represents a divalent organic group, an oxygen atom, a sulfur atom, or a sulfone group; and R¹² and R¹³ each represent a monovalent organic group or a halogen atom.

When the polyimide component contains any of the structures represented by the above formulas, the polyimide component exhibits low linear thermal expansion and low hygroscopic expansion due to these rigid backbone structures. Also, there is an advantage that the polyimide component is easily commercially available and is inexpensive.

When the polyimide component has a structure such as described above, the heat resistance of the polyimide resin is enhanced, while the coefficient of linear thermal expansion is decreased. Therefore, it is more preferable if the content of the structures represented by the above formulas is closer to 100% by mole of R²'s in the formulas (1) to (3), but the content may be at least 33% or more among R²'s in the formulas (1) to (3). Above all, the content of the structures represented by the above formulas is preferably 50% by mole or greater, and more preferably 70% by mole or greater, of R²'s in the formula (1).

From the viewpoint of making the polyimide resin more likely to undergo low hygroscopic expansion, the diamine structure is preferably represented by the following formula (13) or (14):

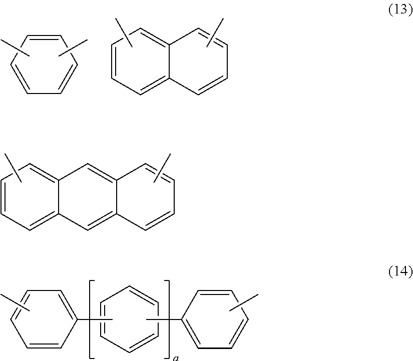

in the formula (13), two amino groups may be bonded to the same aromatic ring; and

in the formula (14), “a” represents 0 or a natural number of 1 or greater; the amino group is bonded at the meta-position or the para-position with respect to the bond between benzene rings; and a portion or all of the hydrogen atoms on the aromatic rings may be substituted by a substituent selected from a fluoro group, a methyl group, a methoxy group, a trifluoromethyl group and a trifluoromethoxy group.

Specific examples of the diamine represented by the formula (13) include p-phenylenediamine, m-phenylenediamine, 1,4-diaminonaphthalene, 1,5-diaminonaphthalene, 2,6-diaminonaphthalene, 2,7-diaminonaphthalene, and 1,4-diaminoanthracene.

Specific examples of the diamine represented by the formula (14) include 2,2′-dimethyl-4,4′-diaminobiphenyl, 2,2′-ditrifluoromethyl-4,4′-diaminobiphenyl, 3,3′-dichloro-4,4′-diaminobiphenyl, 3,3′-dimethoxy-4,4′-diaminobiphenyl, and 3,3′-dimethyl-4,4′-diaminobiphenyl.

Furthermore, when fluorine is introduced as a substituent of the aromatic ring, the coefficient of hygroscopic expansion of the polyimide resin can be decreased. For example, a structure in which fluorine is introduced into a diamine represented by the formula (14) may be a structure represented by the following formula. However, a polyimide precursor, particularly polyamic acid, containing fluorine is not easily soluble in a basic aqueous solution, and in the case of partially forming a photosensitive polyimide insulating layer on a substrate, it may be necessary to develop the insulating layer with a mixed solution with an organic solvent such as an alcohol at the time of processing of the insulating layer.

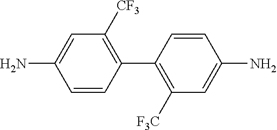 [SMILES: Nc1ccc(-c2ccc(N)cc2C(F)(F)F)c(C(F)(F)F)c1]

The polyimide component used in the present embodiment is preferably a compound which exhibits a transmittance of at least 5% or greater, and more preferably a transmittance of 15% or greater, to the exposure wavelength when a film having a thickness of 1 μm is formed, in order to increase sensitivity when the polyimide component is used in the photosensitive polyimide resin composition described above and to thereby obtain a pattern shape that accurately reproduces the mask pattern.

Furthermore, when exposure is carried out by using a high pressure mercury lamp which is a general exposure light source, the transmittance to the electromagnetic waves at one wavelength at least among the electromagnetic waves having wavelengths of 436 nm, 405 nm and 365 nm, when a film is formed on a film having a thickness of 1 μm, is preferably 5% or greater, more preferably 15% or greater, and even more preferably 50% or greater.

It can be said that a high transmittance of a polyimide component to an exposure wavelength corresponds to small loss of light, and thus a photosensitive polyimide resin composition having high sensitivity can be obtained.

In order to impart transmittance properties, it is desirable to have acid dianhydride having fluorine introduced thereto, or acid dianhydride having an alicyclic backbone, as the acid dianhydride. However, when acid dianhydride having an alicyclic backbone is used, there is a risk that heat resistance may be decreased, and thus the low outgassing properties may be impaired. Therefore, the acid dianhydride having an alicyclic backbone may be used in combination while caution is taken on the copolymerization ratio.

In the present embodiment, in order to impart transmittance properties, it is more preferable to use aromatic acid dianhydride having fluorine introduced thereto as the acid dianhydride, from the viewpoint that hygroscopic expansion can be reduced while heat resistance is maintained (since the compound is aromatic).

As tetracarboxylic acid dianhydride having at least one fluorine atom that is used in the present embodiment, those tetracarboxylic acid dianhydrides having fluorine atoms described above can be used, and among them, tetracarboxylic acid dianhydrides having a fluoro group, a trifluoromethyl group, or a trifluoromethoxy group are preferred. Specific examples thereof include 2,2-bis(3,4-dicarboxyphenyl)-1,1,1,3,3,3-hexafluoropropane dianhydride.

However, a polyimide precursor having a backbone containing fluorine tends to be not easily dissoluble in a basic aqueous solution, and when patterning is carried out by using a resist or the like while the polyimide component is still in the state of being a precursor, it may be necessary to carry out development by means of a solution mixture of an organic solvent such as an alcohol and a basic aqueous solution.

Also, when a rigid acid dianhydride such as pyromellitic anhydride, 3,3′,4,4′-biphenyltetracarboxylic acid dianhydride, or 1,4,5,8-naphthalenetetracarboxylic acid dianhydride is used, the coefficient of linear thermal expansion of the polyimide resin that is finally obtained is small; however, since such an acid dianhydride tends to inhibit an enhancement of transparency, the rigid acid dianhydride may be used in combination while caution is taken on the copolymerization ratio.

In order to impart transmittance properties to the polyimide component, it is desirable to use diamine having fluorine introduced thereto, or diamine having an alicyclic backbone as the diamine. However, when diamine having an alicyclic backbone is used, there is a risk that heat resistance may be decreased, and thus the low outgassing properties may be impaired. Therefore, the diamine having an alicyclic backbone may be used in combination while caution is taken on the copolymerization ratio.

In order to impart transmittance properties, it is more preferable to use aromatic diamine having fluorine introduced thereto as the diamine, from the viewpoint that hygroscopic expansion can be reduced while heat resistance is maintained (since the diamine is aromatic).

As aromatic diamine having fluorine introduced thereto, specifically, diamine having a structure having fluorine introduced thereto as described above may be used, and more specific examples thereof include 2,2′-ditrifluoromethyl-4,4′-diaminobiphenyl, 2,2-di(3-aminophenyl)-1,1,1,3,3,3-hexafluoropropane, 2,2-di(4-aminophenyl)-1,1,1,3,3,3-hexafluoropropane, 2-(3-aminophenyl)-2-(4-aminophenyl)-1,1,1,3,3,3-hexafluoropropane, 1,3-bis(3-amino-α,α-ditrifluoromethylbenzyl)benzene, 1,3-bis(4-amino-α,α-ditrifluoromethylbenzyl)benzene, 1,4-bis(3-amino-α,α-ditrifluoromethylbenzyl)benzene, 1,4-bis(4-amino-α,α-ditrifluoromethylbenzyl)benzene, 2,2-bis[3-(3-aminophenoxy)phenyl]-1,1,1,3,3,3-hexafluoropropane, and 2,2-bis[4-(4-aminophenoxy)phenyl]-1,1,1,3,3,3-hexafluoropropane.

However, a polyimide precursor, particularly polyamic acid, containing fluorine is not easily dissoluble in a basic aqueous solution, and in the case of partially forming a photosensitive polyimide insulating layer on a substrate, it may be necessary to carryout development by means of a solution mixture of an organic solvent such as an alcohol at the time of processing of the insulating layer.

Furthermore, in regard to the proportions of the cyclic structures after imidization that are contained in the formula (1) and the formula (3), since the cyclic structures after imidization tend to have lower transmittances than the carboxylic acid moieties before imidization that are contained in the polyimide precursors represented by the formula (3) and the formula (2), respectively, it is desirable to use polyimide precursors having high transparency, which contain large proportions of structures before imidization. The proportion of a carboxyl group (or an ester thereof) derived from acid anhydride is desirably 50% or greater, and more preferably 75% or greater, relative to the total content, and it is preferable that all of the polyimide precursors be polyimide precursors represented by the formula (2), that is, a polyamic acid (and) derivatives thereof.

In addition, when development is performed by using an alkali developing liquid, the solubility of the polyimide component in the alkali developing liquid can be changed by the residual amount of the carboxylic acid moiety before imidization that is contained in the formulas (2) and (3). From the viewpoint of increasing the developing speed, it is desirable to use a polyimide precursor having high solubility, which contains a large portion of structures before imidization, and the polyimide precursor is preferably polyamic acid in which R³'s in the formulas (2) and (3) are all hydrogen atoms. However, if the developing speed is so fast that the dissolvability for residual pattern areas is too high, a polyimide precursor that has undergone imidization may be used, or the dissolution rate can be decreased by introducing a monovalent organic group to R³'s in the formulas (2) and (3).

On the other hand, when diamine having a siloxane backbone, such as 1,3-bis(3-aminopropyl)tetramethyldisiloxane, is used as the diamine, the adhesiveness to a substrate can be improved, the elastic modulus of the polyimide resin may decrease, or the glass transition temperature may be decreased.

The weight average molecular weight of the polyimide component used in the present embodiment may vary with the application, but the weight average molecular weight is preferably in the range of 3,000 to 1,000,000, more preferably in the range of 5,000 to 500,000, and even more preferably in the range of 10,000 to 500,000. If the weight average molecular weight is less than 3,000, it is difficult to obtain sufficient strength when a coating film or film is produced. Furthermore, the strength of the film is decreased when the polyimide component is produced into a polymer such as a polyimide resin by performing a heating treatment or the like. On the other hand, if the weight average molecular weight is more than 1,000,000, viscosity increases, and solubility also decreases. Therefore, it is difficult to obtain a coating film or a film which has a smooth surface and a uniform thickness.

The molecular weight as used herein may be a value measured by gel permeation chromatography (GPC) and calculated relative to polystyrene standards, and the molecular weight may be the molecular weight of the polyimide precursor itself, or may be the molecular weight of a polyimide that has been subjected to a chemical imidization treatment with acetic anhydride or the like.

The content of the polyimide component used in the present embodiment is preferably 50% by weight or greater, and more preferably 70% by weight or greater, relative to the total solids content of the photosensitive polyimide resin composition, from the viewpoints of the film properties of the resulting pattern, particularly the film strength and heat resistance.

Meanwhile, the solids content of the photosensitive polyimide resin composition includes all the components other than the solvent, and liquid monomer components are also included in the solids content.

b. Photosensitive Component

The photosensitive component according to the present embodiment is included in order to cure the polyimide component, and examples thereof include: photoinitiators such as a photoradical generator, a photoacid generator, and a photobase generator that are included in the photosensitive polyimide resin composition described above; components in which the solubility of the compounds themselves change with light irradiation, such as naphthoquinone diazide compounds; components that are crosslinked by radicals, such as an ethylenic double bond site introduced to the carboxyl group of polyamic acid through ester bonding or ionic bonding; main photosensitive components such as a radical-crosslinkable monomer, an acid-crosslinkable monomer, and an acid-decomposable substituent introduced to the carboxyl group of polyamic acid; and auxiliary photosensitive components such as a sensitizer that is used together with such a main photosensitive component.

More specifically, in a solvent development negative type photosensitive polyimide resin composition obtained by introducing an ethylenic double bond to the carboxyl group of polyamic acid through ester bonding or ionic bonding, and further incorporating a photoradical initiator thereto, a double bond site and a photoradical generator correspond to the photosensitive component; in an alkali development positive type photosensitive polyimide resin composition obtained by adding a naphthoquinone diazide compound to polyamic acid or a partial esterification product thereof, a naphthoquinone diazide compound corresponds to the photosensitive component; in a negative type photosensitive polyimide resin composition obtained by adding a photoacid generator to polyimide or polyimide precursor having an acid-crosslinkable substituent introduced thereto, a photoacid generator and an acid-crosslinkable substituent correspond to the photosensitive component; in a positive type photosensitive polyimide resin composition obtained by adding a photoacid generator to polyimide or polyimide precursor having an acid-decomposable substituent introduced thereto, a photoacid generator and an acid-decomposable substituent correspond to the photosensitive component; an alkali development negative type photosensitive polyimide resin composition obtained by adding a photoacid generator to polyamic acid, a photoacid generator corresponds to the photosensitive component; in an alkali development negative type photosensitive polyimide resin composition obtained by adding a nifedipine-based compound and the like to polyamic acid, a nifedipine-based compound corresponds to the photosensitive component; and in an alkali development negative type photosensitive polyimide resin composition obtained by adding a photobase generator to polyamic acid, a photobase generator corresponds to the photosensitive component.

The content of the photosensitive component used in the present embodiment is not particularly limited as long as a photosensitive polyimide insulating layer of a desired pattern can be formed, and any general content can be employed.

In general, polyimide resins are known for highly heat resistant, and since they have high heat resistance, photosensitive components tend to have lower heat resistance than the polyimide components. Therefore, low outgassing properties are obtained by decreasing the proportion of the photosensitive component relative to the proportion of the polyimide component.

Under such circumstances, it is preferable that the content of the photosensitive component be smaller, and in the present embodiment, the content of the photosensitive component is preferably in the range of greater than or equal to 0.1 part by weight and less than 30 parts by weight, more preferably in the range of 0.5 part by weight to 20 parts by weight, and particularly preferably in the range of 0.5 part by weight to 15 parts by weight, relative to 100 parts by weight of the polyimide component.

Among the photosensitive components used in the present embodiment, it is preferable to use a photoacid generator or a photobase generator as a main component. It is because the photoacid generator or photobase generator can be preferably used since the generated chemical species works catalytically, and thus the content of additives other than the polyimide component and the solvent, which are constituent components of the polyimide resin, can be reduced.

Particularly, in a system in which a photoacid generator or a photobase generator is added to a polyimide precursor such as polyamic acid, an imidization reaction is catalytically accelerated by the acid or base generated upon light irradiation, and the exposed areas are selectively insolubilized, patterning can be achieved only by adding a photoacid generator or a photobase generator. Since it is not needed to introduce a cross-linkable component or a decomposable substituent, the amount of additives can be further reduced.

Under such circumstances, while the content of the photosensitive component that is included in a general photosensitive polyimide resin composition is frequently 30 parts by weight or greater relative to 100 parts by weight of the polyimide component, in the photoacid generator or photobase generator described above, since the generated chemical species works catalytically as described above, even if the content of the photoacid generator or photobase generator is adjusted to be within the range described above, the photoacid generator or photobase generator acquires an exposure sensitivity that is sufficiently capable of curing. Furthermore, since the photosensitive components described above have lower heat resistance than the polyimide components and can be considered as main components of outgassing, when the content of the photosensitive components is adjusted to be within the range described above, the photosensitive polyimide insulating layer can be made to have a smaller weight loss, that is, a sufficiently smaller amount of outgassing.

In the present embodiment, particularly, it is preferable that the photosensitive component includes the photobase generator described above as a main component, and among others, it is particularly preferable that the photosensitive component be the photobase generator, that is, the photosensitive component include only the photobase generator. It is desirable because bases, which are the generated chemical species, have less influence on metals and the like as compared with acids.

Meanwhile, including photobase generator as a main component implies that the content of the photobase generator or the like among the photosensitive components is 50% by mass or greater.

There are no particular limitations on the photobase generator to be used in the present embodiment, as long as the photobase generator does not exhibit activity under typical conditions of normal temperature and normal pressure, but generates a base (a basic substance) when subjected to the irradiation of electromagnetic waves and heating as external stimuli.

Meanwhile, in the present invention, electromagnetic waves include not only the electromagnetic waves having wavelengths in the visible and non-visible regions, but also particle radiations such as electron beam, and radiations that collectively refer to electromagnetic waves and particle radiations, or ionizing radiations except a case when a wavelength is specified. In the present specification, irradiation of electromagnetic waves is referred to as exposure.

In the present embodiment, known compounds can be used as the photobase generator. Examples thereof include, as described in M. Shirai and M. Tsunooka, Prog. Polym. Sci., 21, 1 (1996); Masahiro Tsunooka, Kobunshi Kakou (Polymer Processing), 46, 2 (1997); C. Kutal, Coord. Chem. Rev., 211, 353 (2001); Y. Kaneko, A. Sarker, and D. Neckers, Chem. Mater., 11, 170 (1999); H. Tachi, M. Shirai, and M. Tsunooka, J. Photopolym. Sci. Technol., 13, 153 (2000); M. Winkle and K. Graziano, J. Photopolym. Sci. Technol., 3, 419 (1990); M. Tsunooka, H. Tachi, and S. Yoshitaka, J. Photopolym. Sci. Technol., 9, 13 (1996); and K. Suyama, H. Araki, M. Shirai, J. Photopolym. Sci. Technol., 19, 81 (2006), transition metal compound complexes; ionic compounds that have been neutralized as the basic component forms a salt, such as ionic compounds having a structure of an ammonium salt or the like or ionic compounds that have become latent as the amidine moiety forms a salt with a carboxylic acid; and nonionic compounds that have become latent by urethane bonding or oxime bonding, such as carbamate derivatives, oxime ester derivatives, and acyl compounds.

Here, specific examples of ionic compounds that may be used as the photobase generator include compounds represented by the following formulas.

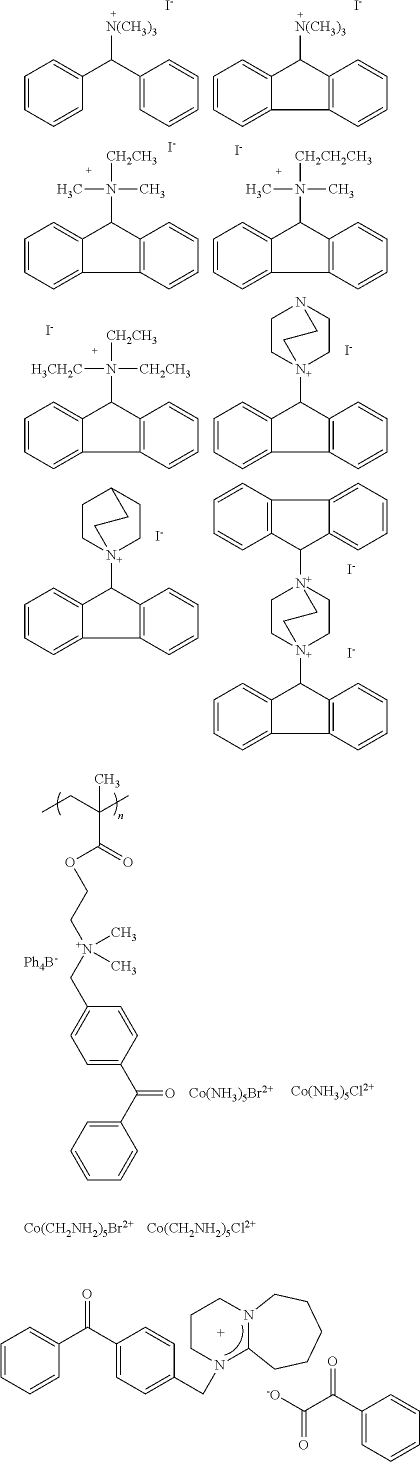

Furthermore, examples of oxime ester derivatives that may be used as the photobase generator include compounds represented by the following formulas.

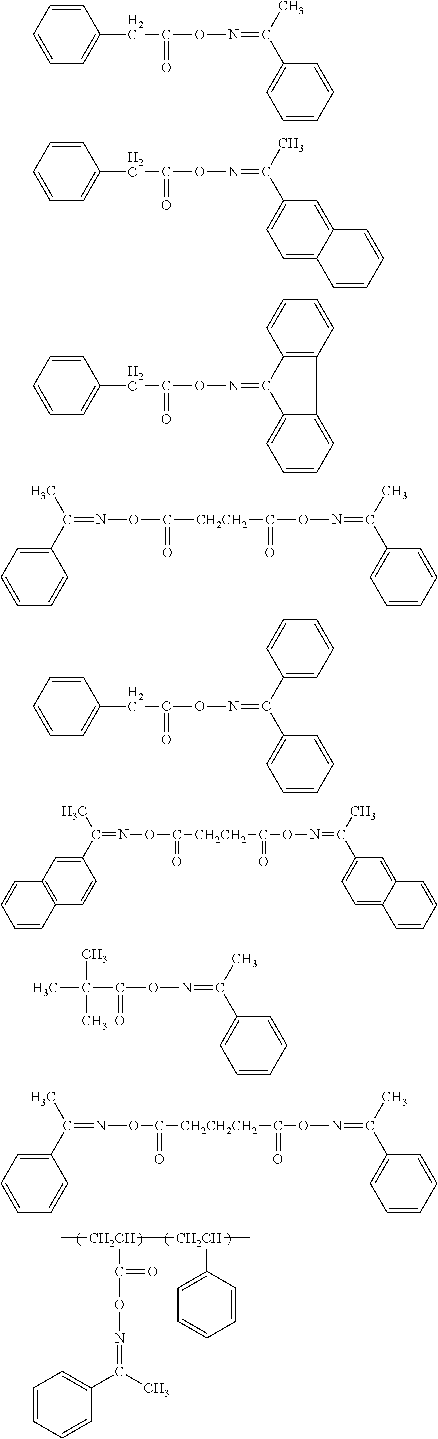

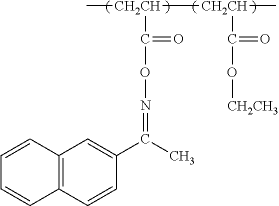

Examples of acyl compounds include compounds represented by the following formulas.

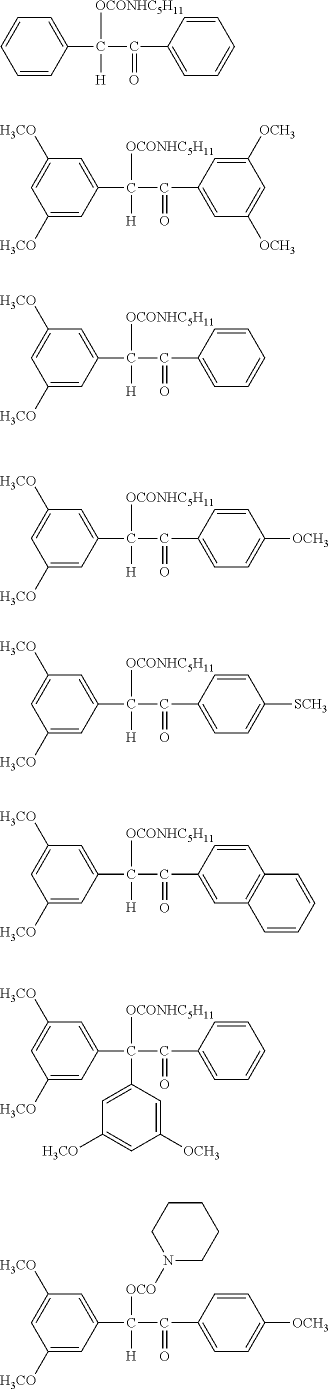

Examples of carbamate compounds that may be used as the photobase generator include compounds represented by the following formulas.

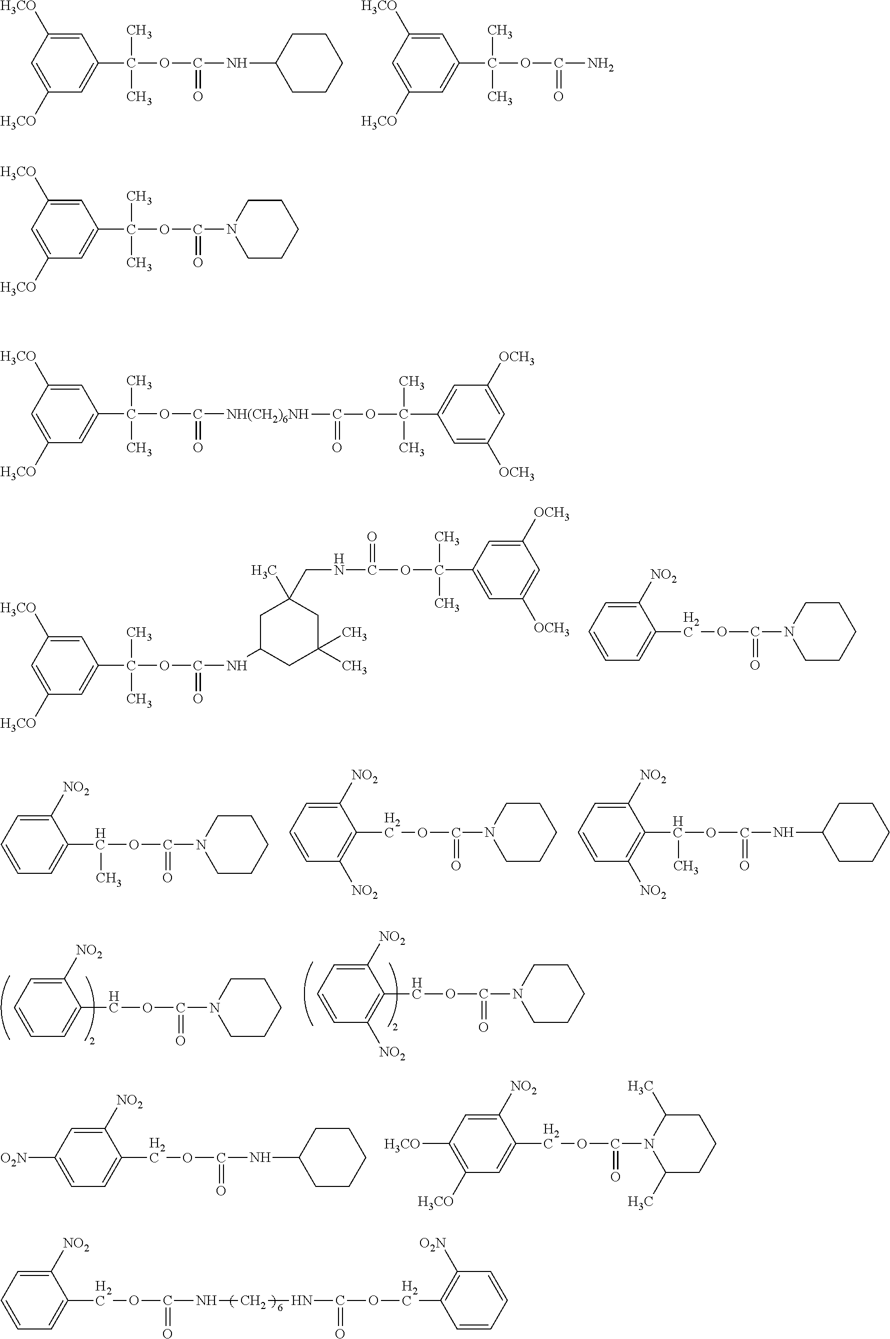

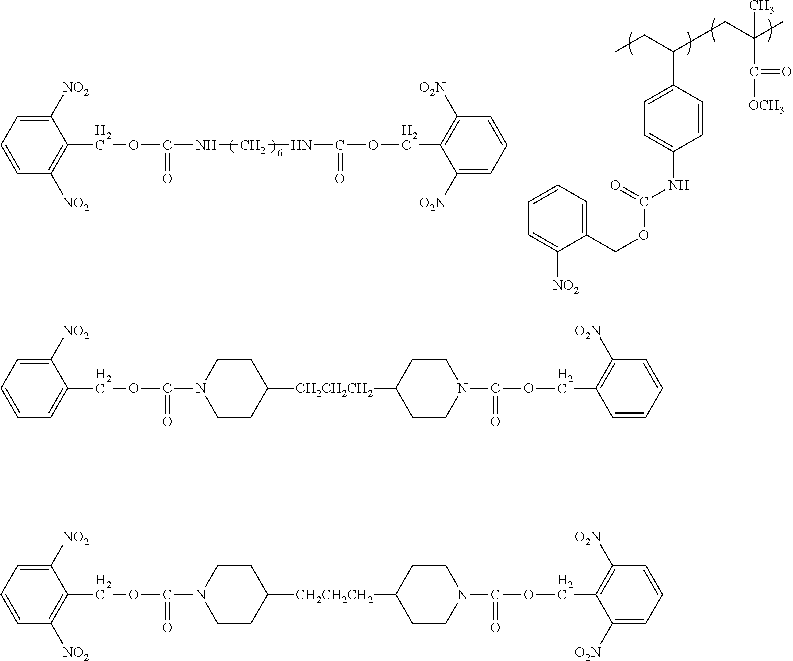

Furthermore, examples of the photobase generator include a compound represented by the following formula:

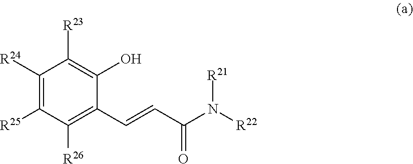

in the formula (a), R²¹ and R²², which may be identical with or different from each other, each independently represent a hydrogen atom or a monovalent organic group; R²¹ and R²² may be bonded to each other and form a cyclic structure, or may contain a bond with a heteroatom, provided that at least one of R²¹ and R²² is a monovalent organic group; R²³, R²⁴, R²⁵ and R²⁶, which may be identical with or different from each other, each independently represent a hydrogen atom, a halogen atom, a hydroxyl group, a mercapto group, a sulfide group, a silyl group, a silanol group, a nitro group, a nitroso group, a sulfino group, a sulfo group, a sulfonato group, a phosphino group, a phosphinyl group, a phosphono group, a phosphonato group, an amino group, an ammonio group, or a monovalent organic group; and two or more of R²³, R²⁴, R²⁵ and R²⁶ may bonded to each other and form a cyclic structure, or may contain a bond to a heteroatom.

Since the photobase generator represented by the formula (a) has a particular structure such as described above, when irradiated with light rays such as ultraviolet radiation, the (—CH═CH—C(═O)—) moiety in the above formula (a) is isomerized into a cis-form, and is cyclized by heating, thereby producing a base (NHR²¹R²²). That is, the photobase generator represented by the formula (a) can produce, depending on the structure, primary amine, secondary amine, or an amidine-based compound as a base.

The photobase generator described above may be used as a single compound, or plural kinds may be used in combination.

The photobase generator used in the present embodiment is used in combination with the polyimide component described above. Since the polyimide component exhibits, together with the polyimide and polyimide precursor, strong absorption in the wavelength range of less than 350 nm, it is desirable that the photobase generator have sensitivity in the wavelength range of 350 nm or greater. In order for the photobase generator to sufficiently exhibit the function of base generation in order to make the polyimide component the final product, it is necessary that the polyimide component exhibit absorption for at least a portion of the exposure wavelength. Wavelengths of high pressure mercury lamps that are used as general exposure light sources include 365 nm, 405 nm, and 436 nm. Therefore, the photobase generator according to the present embodiment preferably exhibits absorption for the electromagnetic waves of at least one wavelength among the electromagnetic waves having wavelengths of at least 365 nm, 405 nm, and 436 nm. In this case, it is preferable from the viewpoint that the number of kinds of applicable polyimide components further increases.

Examples of the basic substance that is generated from the photobase generator according to the present embodiment include amine represented by the following formula (A), and amidine represented by the following formula (B):

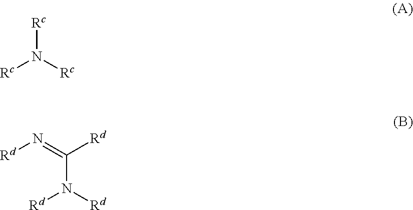

in which R^{c}'s each independently represent a hydrogen atom or a monovalent organic group, and may be identical with or different from each other; R^{c}'s may be bonded to each other and form a cyclic structure, or may contain a bond to a heteroatom, provided that at least one of R^{c}'s is a monovalent organic group; R^{d}'s each independently represent a hydrogen atom or a monovalent organic group, and may be identical with or different from each other; R^{d}'s may be bonded to each other and form a cyclic structure, or may contain a bond to a heteroatom.

Meanwhile, when R^{c} in the formula (A) has the amidine structure that is contained in the formula (B), the base generated is not the amine of the formula (A), but is defined to belong to the amidine of the formula (B).

From the viewpoint that the effects provided by the basic substance generated, such as the catalytic effect described above, are significant, it is preferable that the basic substance that is generated be aliphatic amine or amidine, from the viewpoint of being amine of high basicity. Among them, from the viewpoint of basicity, secondary or tertiary aliphatic amine or amidine is preferred. However, even in the case of using aliphatic primary amine, a sufficient catalyst effect can be obtained as compared with the case of using aromatic amine. Therefore, even among aliphatic amines, from the viewpoints of the thermal properties such as 5% weight loss temperature or 50% weight loss temperature, and thermal decomposition temperature, and other properties such as solubility, and from the viewpoints of convenience of synthesis and cost, it is desirable to select amine or amidine.

In the present embodiment, from the viewpoint of generating the aliphatic amine described above, achieving high sensitivity, and increasing the solubility contrast between the exposed area and the unexposed area, it is preferable that all the atoms that are directly bonded to the nitrogen atom of R^{c} in the formula (A) be hydrogen atoms or carbon atoms having the SP3 orbit (provided that the case where all of R^{c}'s are hydrogen atoms is excluded).

Specific examples of the amine that is generated at the time of decomposition of the photobase generator according to the present embodiment include primary amines such as n-butylamine, amylamine, hexylamine, cyclohexylamine, octylamine, and benzylamine; secondary amines, including linear secondary amines such as diethylamine, dipropylamine, diisopropylamine and dibutylamine, cyclic secondary amines such as aziridine, azetidine, pyrrolidine, piperidine, azepane and azocane, and alkyl-substituted forms thereof; aliphatic tertiary amines such as trimethylamine, triethylamine, tripropylamine, tributylamine, triethylenediamine, 1,4-diazabicyclo[2.2.2]octane, quinuclidine, and 3-quinucridinol; aromatic tertiary amines such as dimethylaniline; and heterocyclic tertiary amines such as isoquinoline, pyridine, collidine, and beta-picoline.

Specific examples of the amidine that is generated at the time of decomposition of the photobase generator according to the present embodiment include secondary amidines such as imidazole, purine, triazole and guanidine, and derivatives thereof; and tertiary amidines such as pyrimidine, triazine, 1,8-diazabicyclo[5.4.0]undec-7-ene (DBU) and 1,5-diazabicyclo[4.3.0]non-5-ene (DBN), and derivatives thereof.

The photobase generator according to the present embodiment is preferably such that the temperature at which, when the compound is heated, the weight of the compound decreases by 5% from the initial weight (5% weight loss temperature) is 150° C. or higher, and more preferably 200° C. or higher. In the case of forming a low-outgassing photosensitive polyimide insulating layer by using a low-outgassing photosensitive polyimide resin composition containing a photobase generator as a photosensitive component, since the heating process that is carried out after exposure and before development is usually carried out at about 150° C. to 200° C., it is preferable from the viewpoint that the photobase generator at the unexposed areas is not easily decomposed. Furthermore, in the case of a polyimide precursor or polyimide, it is necessary to use a high-boiling point solvent such as N-methyl-2-pyrrolidone when a coating film is formed; however, when the 5% weight loss temperature is high as such, a coating film can be formed under the drying conditions in which the influence of the residual solvent is reduced. Thereby, a decrease in the solubility contrast between the exposed area and the unexposed area due to the influence of residual solvent can be suppressed.

On the other hand, since it is preferable that impurities originating from the base generator do not remain in the photosensitive polyimide insulating layer according to the present embodiment, the base generator according to the present invention is preferably decomposed, or volatilized, by the heating process that is carried out after development (for example, in the case where the polymer to be combined is a polyimide precursor, the process of imidization). Specifically, for the base generator according to the present embodiment, preferably the 5% weight loss temperature is 300° C. or lower, more preferably 280° C. or lower, and particularly preferably 260° C. or lower.

Also, in the present embodiment, it is preferable that the 25% weight loss temperature be 300° C. or lower, and above all, it is particularly preferable that the 50% weight loss temperature be 300° C. or lower.

Furthermore, in the present embodiment, it is preferable that the weight loss ratio at 300° C. be 50% or higher, above all, more preferably 70% or higher, and particularly preferably 85% or higher.

In the present embodiment, among the base generators described above, a base generator represented by the above formula (a) is preferred. It is because, since the compound is easily decomposed or volatilized by the heating process that is carried out after development, even when exposed to a high temperature atmosphere or a vacuum atmosphere by the subsequent processes of forming an oxide semiconductor layer or the like, the amount of the components that volatilize and outgas can be small. Therefore, the low-outgassing polyimide insulating layer thus obtainable can be made to have less outgassing.

The base generator represented by the formula (a) can efficiently generate a base at a smaller dose of electromagnetic irradiation by combining irradiation of electromagnetic waves and heating, and has higher sensitivity as compared with conventional so-called photobase generators.

Since the base generator represented by the formula (a) has the particular structure indicated above, when irradiated with electromagnetic waves, the (—CH═CH—C(═O)—) moiety in the formula (a) is isomerized into a cis-form as shown in the following formula, and is further cyclized by heating, thereby producing a base (NHR²¹R²²). Through the catalytic action of the amine, the temperature at which the reaction is initiated when the polyimide component is converted to the final product can be lowered, or the curing reaction by which the polyimide component is converted to the final product can be initiated.

The base generator represented by the formula (a) generates a base only by being irradiated with electromagnetic waves, but when appropriate heat is applied, the generation of a base is accelerated.

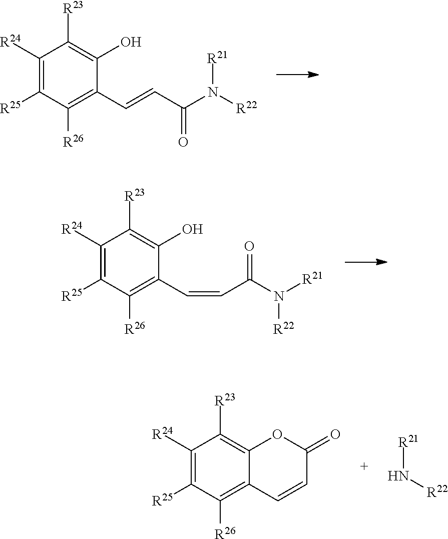

The base generator represented by the formula (a) loses a phenolic hydroxyl group when cyclized, and has its solubility changed, so that in the case of a basic aqueous solution or the like, the solubility is decreased. Thereby, the base generator has a function of further assisting the decrease in solubility due to the reaction by which the polyimide component is converted to the final product, and thereby can increase the solubility contrast between the exposed area and the unexposed area.

R²¹ and R²² each independently represent a hydrogen atom or a monovalent organic group, but at least one of R²¹ and R²² is a monovalent organic group. Furthermore, although NHR²¹R²² is a base (basic substance), it is preferable that R²¹ and R²² each represent an organic group that does not contain an amino group. If R²¹ and R²² contain amino groups, the base generator itself becomes a basic substance and accelerates the reaction of the polyimide component, and there is a risk that the difference of the solubility contrast between the exposed area and the unexposed area may become small. However, for example, as in the case where an amino group is bonded to the aromatic ring that is present in the organic group of R²¹ and R²², when there occurs a difference between the basicity of the base generator and the basicity of the base that is generated after irradiation of electromagnetic waves and heating, a base generator in which the organic group of R²¹ and R²² contains an amino group may also be used.

Examples of the monovalent organic group include a saturated or unsaturated alkyl group, a saturated or unsaturated cycloalkyl group, an aryl group, an aralkyl group, and a saturated or unsaturated halogenated alkyl group. These organic groups may contain a bond or a substituent other than a hydrocarbon group, such as a heteroatom, in the relevant organic group, and these organic groups may be linear or branched.

Also, R²¹ and R²² may also be bonded to each other and form a cyclic structure.

The cyclic structure may be a saturated or unsaturated alicyclic hydrocarbon, a heterocyclic ring or a fused ring, or may be a structure in which two or more kinds selected from the group consisting of the relevant alicyclic hydrocarbon, heterocyclic ring and fused ring are combined.

The bond other than a hydrocarbon group in the organic group of R²¹ and R²² is not particularly limited as long as the effects of the present embodiment are not impaired, and examples thereof include an ether bond, a thioether bond, a carbonyl bond, a thiocarbonyl bond, an ester bond, an amide bond, a urethane bond, an imino bond (—N═C(—R)—, —C(═NR)—; in which R represents a hydrogen atom or a monovalent organic group), a carbonate bond, a sulfonyl bond, a sulfinyl bond, and an azo bond.

In view of heat resistance, the bond other than a hydrocarbon group in the organic group is preferably an ether bond, a thioether bond, a carbonyl bond, a thiocarbonyl bond, an ester bond, an amide bond, a urethane bond, an imino bond (—N═C(—R)—, —C(═NR)—; in which R represents a hydrogen atom or a monovalent organic group), a carbonate bond, a sulfonyl bond, or a sulfinyl bond.

The substituent other than a hydrocarbon group in the organic group of R²¹ and R²² is not particular limited as long as the effects of the present embodiment are not impaired, and examples thereof include a halogen atom, a hydroxyl group, a mercapto group, a sulfide group, a cyano group, an isocyano group, a cyanato group, an isocyanato group, a thiocyanato group, an isothiocyanato group, a silyl group, a silanol group, an alkoxy group, an alkoxycarbonyl group, a carbamoyl group, a thiocarbamoyl group, a nitro group, a nitroso group, a carboxyl group, a carboxylato group, an acyl group, an acyloxy group, a sulfino group, a sulfo group, a sulfonato group, a phosphino group, a phosphinyl group, a phosphono group, a phosphonato group, a hydroxyimino group, a saturated or unsaturated alkyl ether group, a saturated or unsaturated alkyl thioether group, an aryl ether group, an aryl thioether group, an amino group (—NH₂, —NHR, —NRR′; in which R and R′ each independently represent a hydrocarbon group), and an ammonio group. The hydrogen that is contained in the substituent may be substituted by a hydrocarbon group. Also, the hydrocarbon group contained in the substituent may be linear, branched or cyclic.

Preferred examples of the substituent other than a hydrocarbon group in the organic group of R²¹ and R²² include a halogen atom, a hydroxyl group, a mercapto group, a sulfide group, a cyano group, an isocyano group, a cyanato group, an isocyanato group, a thiocyanato group, an isothiocyanato group, a silyl group, a silanol group, an alkoxy group, an alkoxycarbonyl group, a carbamoyl group, a thiocarbamoyl group, a nitro group, a nitroso group, a carboxyl group, a carboxylato group, an acyl group, an acyloxy group, a sulfino group, a sulfo group, a sulfonato group, a phosphino group, a phosphinyl group, a phosphono group, a phosphonato group, a hydroxyiminio group, a saturated or unsaturated alkyl ether group, a saturated or unsaturated alkyl thioether group, an aryl ether group, and an aryl thioether group.

Since the basic substance that is produced is NHR²¹R²², examples thereof include primary amine, secondary amine, or a heterocyclic compound. Also, the amines respectively include aliphatic amines and aromatic amines. Meanwhile, the heterocyclic compound as used herein means a compound in which the NHR²¹R²² moiety has a cyclic structure and has aromatic characteristics. Non-aromatic heterocyclic compounds, which are not aromatic heterocyclic compounds, are included in the class of aliphatic amines as alicyclic amines.

Furthermore, NHR²¹R²² to be produced may be a basic substance such as monoamine, which has only one NH group that is capable of forming an amide bond, or may also be a basic substance having two or more NH groups that are capable of forming an amide bond, such as diamine, triamine or tetraamine. When the NHR²¹R²² to be produced is a basic substance having two or more NH groups, the basic substance may have a structure in which a photolatent site which generates a base having an NH group that is capable of forming an amide bond under irradiation of electromagnetic waves and heating, is further bonded to one or more ends of R²¹ and/or R²² of the above formula (a). Examples of the photolatent site include a structure in which a residue other than R²¹ and/or R²² of the formula (a) is further bonded to one or more ends of R²¹ and/or R²² of the formula (a).

Examples of the aliphatic primary amine include methylamine, ethylamine, propylamine, isopropylamine, n-butylamine, sec-butylamine, tert-butylamine, pentylamine, isoamylamine, tert-pentylamine, cyclopentylamine, hexylamine, cyclohexylamine, heptylamine, cycloheptanamine, octylamine, 2-octanamine, 2,4,4-trimethylpentan-2-amine, and cyclooctylamine.

Examples of the aromatic primary amine include aniline, 2-aminophenol, 3-aminophenol, and 4-aminophenol.

Examples of the aliphatic secondary amine include dimethylamine, diethylamine, dipropylamine, diisopropylamine, dibutylamine, ethylmethylamine, aziridine, azetidine, pyrrolidine, piperidine, azepane, azocane, methylaziridine, dimethylaziridine, methylazetidine, dimethylazetidine, trimethylazetidine, methylpyrrolidine, dimethylpyrrolidine, trimethylpyrrolidine, tetramethylpyrrolidine, methylpiperidine, dimethylpiperidine, trimethylpiperidine, tetramethylpiperidine, and pentamethylpiperidine, and among them, alicyclic amines are preferred.

Examples of the aromatic secondary amine include methylaniline, diphenylamine, and N-phenyl-1-naphthylamine. Furthermore, an aromatic heterocyclic compound having an NH group that is capable of forming an amide bond, preferably has an imino bond (—N═C(—R)—, —C(═NR)—; in which R represents a hydrogen atom or a monovalent organic group) in the molecule in view of basicity, and examples thereof include imidazole, purine, triazole, and derivatives thereof.

Examples of amines as diamine and higher amines include linear aliphatic alkylenediamine such as ethylenediamine, 1,3-propanediamine, 1,4-butanediamine, 1,5-pentanediamine, 1,6-hexanediamine, 1,7-heptanediamine, 1,8-octanediamine, 1,9-nonanediamine, and 1,10-decanediamine; branched aliphatic alkylenediamines such as 1-butyl-1,2-ethanediamine, 1,1-dimethyl-1,4-butanediamine, 1-ethyl-1,4-butanediamine, 1,2-dimethyl-1,4-butanediamine, 1,3-dimethyl-1,4-butanediamine, 1,4-dimethyl-1,4-butanediamine, and 2,3-dimethyl-1,4-butanediamine; polyethyleneamines represented by the formula: NH₂(CH₂CH₂NH)ₙH, such as diethylenetriamine, triethylenetetramine, and tetraethylenepentamine; alicyclic diamines such as cyclohexanediamine, methylcyclohexanediamine, isophoronediamine, norbornanedimethylamine, tricyclodecanedimethylamine, and menthenediamine; aromatic diamines such as p-phenylenediamine, m-phenylenediamine, p-xylenediamine, m-xylenediamine, 4,4′-diaminodiphenylmethane, and diaminodiphenylsulfone; triamines such as benzenetriamine, melamine, and 2,4,6-triaminopyrimidine; and tetraamines such as 2,4,5,6-tetraminopyrimidine.

The thermal properties and the degree of basicity of the basic substance that is produced may vary depending on the substituent that is introduced at the positions of R²¹ and R²².

In the catalytic action of decreasing the reaction initiation temperature for the reaction that produces the final product from the polyimide component described above, a basic substance having higher basicity is more effective as the catalyst, and by addition of a smaller amount thereof, the reaction that produces the final product can be achieved at a lower temperature. Generally, secondary amine has higher basicity than that of primary amine, and the catalytic effect of a secondary amine is greater.

Furthermore, aliphatic amine is preferred to aromatic amine because aliphatic amine has stronger basicity.

Also, when the base generated in the present embodiment is secondary amine and/or a heterocyclic compound, it is preferable from the viewpoint that the compound's sensitivity as a base generator is higher. This is speculated that it is because, when secondary amine or a heterocyclic compound is used, active hydrogen at the amide bond site disappears, and thereby, the electron density is changed, and the sensitivity of isomerization is enhanced.

Also, from the viewpoints of the thermal properties and the degree of basicity of the base to be detached, the organic groups of R²¹ and R²² each independently preferably have 1 to 20 carbon atoms, more preferably 1 to 12 carbon atoms, and particularly preferably 1 to 8 carbon atoms.

Furthermore, the base that is generated from the base generator represented by the formula (a) is preferably a base having one NH group that is capable of forming an amide bond. When the base to be generated has two or more NH groups that are capable of forming amide bonds, the base generator has two or more amide bonds that are to be cut by irradiation of electromagnetic waves and heating, and there are two or more light-absorbing groups such as, for example, cinnamic acid derivative residues, in one molecule. In this case, since the molecular weight is usually large, there is a problem that solvent solubility is poor. Furthermore, when the base generator has two or more light-absorbing groups in one molecule, if one amide bond by which a light-absorbing group is bonded to a base is cut, the base generator produces a base; however, since a base which still contains a light-absorbing group has a large molecular weight, the base has poor diffusivity, and the sensitivity becomes poor when the compound is used as a base generator. Furthermore, when a base generator is synthesized, if there is one light-absorbing group, synthesis is carried out by adding an excess amount of a base that is relatively inexpensive; however, if there are two or more light-absorbing groups, there is a need to add an excess amount of the raw material of the light-absorbing group moiety, which is relatively expensive. Also, in the case of a base having two or more NH groups that are capable of forming amide bonds, there is also a problem that purification after synthesis becomes difficult. Among them, particularly, in the case where the base generator is combined with a polyimide precursor, it is preferable that the base generator have one NH group that is capable of forming an amide bond.

The structure of the secondary amine and/or heterocyclic compound to be generated is preferably represented by, among others, the following formula (b):

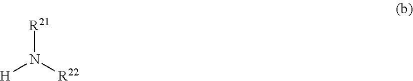

in the formula (b), R²¹ and R²² each independently represent a monovalent organic group, specifically an alkyl group having 1 to 20 carbon atoms which may have substituents, or a cycloalkyl group having 4 to 22 carbon atoms which may have substituents; R²¹ and R²² may be identical with or different from each other; and R²¹ and R²² may be bonded to each other and form a cyclic structure, or may contain a bond to a heteroatom.

With regard to R²¹ and R²² of the formula (b), the alkyl group may be linear or branched. The alkyl group preferably has 1 to 12 carbon atoms, and the cycloalkyl group preferably has 4 to 14 carbon atoms. Also, an alicyclic amine in which R²¹ and R²² are bonded to each other and form a cyclic structure having 4 to 12 carbon atoms which may have substituents is also preferred. Furthermore, a heterocyclic compound in which R²¹ and R²² are bonded to each other and form a cyclic structure having 2 to 12 carbon atoms which may have substituents is also preferred.

R²³, R²⁴, R²⁵ and R²⁶ each independently represent a hydrogen atom, a halogen atom, a hydroxyl group, a mercapto group, a sulfide group, a silyl group, a silanol group, a nitro group, a nitroso group, a sulfino group, a sulfa group, a sulfonato group, a phosphino group, a phosphinyl group, a phosphono group, a phosphonato group, an amino group, an ammonia group, or a monovalent organic group, and these may be identical with or different from each other. Two or more of R²³, R²⁴, R²⁵ and R²⁶ may be bonded to each other and form a cyclic structure, or may contain a bond to a heteroatom.

Examples of the halogen atom include fluorine, chlorine, and bromine.

The monovalent organic group is not particularly limited, and examples thereof include a saturated or unsaturated alkyl group, a saturated or unsaturated cycloalkyl group, an aryl group, an aralkyl group, a saturated or unsaturated halogenated alkyl group, a cyano group, an isocyano group, a cyanato group, an isocyanato group, a thiocyanato group, an isothiocyanato group, an alkoxy group, an alkoxycarbonyl group, a carbamoyl group, a thiocarbamoyl group, a carboxyl group, a carboxylato group, an acyl group, an acyloxy group, and a hydroxyimino group. These organic groups may contain a bond or a substituent other than a hydrocarbon group such as a heteroatom in the relevant organic group, and these may be linear or branched.

In the present embodiment, it is desirable that at least one of R²³, R²⁴, R²⁵ and R²⁶ be a hydroxyl group, a mercapto group, a sulfide group, a silyl group, a silanol group, a nitro group, a nitroso group, a sulfino group, a sulfo group, a sulfonato group, a phosphino group, a phosphinyl group, a phosphono group, a phosphonato group, an amino group, or an ammonio group. When at least one of the substituents described above is introduced into the substituents R²³ to R²⁶, the wavelength of the light to be absorbed can be adjusted, and a desired wavelength can be made absorbable by introducing a substituent. Also, solubility or the compatibility with polymer precursors to be combined can also be enhanced. Thereby, the sensitivity can be enhanced while the absorption wavelength of the polyimide component to be combined is taken into consideration.

As a guideline on which substituent should be introduced in order to shift the absorption wavelength to a desired wavelength, reference can be made to the tables described in Interpretation of the Ultraviolet Spectra of Natural Products (A. I. Scott, 1964), or Spectroscopic Identification of Organic Compounds, 5^{th} Edition (R. M. Silverstein, 1993).

Above all, in the base generator according to the present embodiment, it is preferable that at least one of R²³, R²⁴, R²⁵ and R²⁶ be a hydroxyl group, from the viewpoint that solubility in basic aqueous solutions and the like is enhanced, and the absorption wavelength can be increased, as compared with compounds that do not contain a hydroxyl group at R²³, R²⁴, R²⁵ and R²⁶. Also, particularly when R²⁶ is a phenolic hydroxyl group, it is preferable from the viewpoint that since the number of reaction sites increases when a compound that has been isomerized into a cis-form is cyclized, cyclization is made easier.

The structure represented by the formula (a) has a geometric isomer at the (—CH═CH—C(═O)—) moiety, but it is preferable to use a trans-form only. However, there is a possibility that a cis-form which is a geometric isomer may be mixed in at the time of synthesis and purification processes and storage, and in this case, a mixture of a trans-form and a cis-form may be used, but from the viewpoint that the solubility contrast can be increased, it is preferable that the proportion of the cis-form be less than 10%.

Meanwhile, the weight loss temperature of the base generator represented by the formula (a) can be adjusted by appropriately selecting the substituents R²³ to R²⁶.

The heating temperature for generating a base when the base generator represented by the formula (a) is used, is appropriately selected in accordance with the polyimide component to be combined or the purpose, and is not particularly limited. The heating may be heating based on the temperature of the environment in which the base generator is placed in (for example, room temperature), but in that case, a base is slowly generated. Also, since a base is generated even by the heat that is produced as a side-product at the time of irradiation of electromagnetic waves, heating may also be substantially simultaneously carried out by the heat that is produced as a side-product at the time of irradiation of electromagnetic waves. From the viewpoint of increasing the reaction rate and efficiently generating a base, the heating temperature for generating a base is preferably 30° C. or higher, more preferably 60° C. or higher, even more preferably 100° C. or higher, and particularly preferably 120° C. or higher. However, depending on the polyimide component that is used in combination, curing may occur even at unexposed areas by heating at, for example, 60° C. or higher. Therefore, a suitable heating temperature is not limited to the temperature described above.

Also, in order to prevent the decomposition other than base generation of the base generator represented by the formula (a), it is preferable to heat the base generator at a temperature of 300° C. or lower.

The base generator represented by the formula (a) generates a base only by irradiation of electromagnetic waves, but when the base generator is appropriately heated, the generation of a base is accelerated. Therefore, in order to generate a base efficiently, when the base generator represented by the formula (a) is used, the base is generated by performing heating after exposure or simultaneously with exposure. Exposure and heating may also be carried out alternately. The most efficient method is a method of performing heating simultaneously with exposure.

The base generator represented by the formula (a) according to the present embodiment needs to have absorption of at least a portion of the exposure wavelength, in order to sufficiently exhibit the function of base generation to make the polyimide component the final product. The wavelengths of high pressure mercury lamps, which are common exposure light sources, include 365 nm, 405 nm, and 436 nm. Therefore, the base generator represented by the formula (a) according to the present embodiment preferably exhibits absorption for the electromagnetic waves of at least one wavelength among the electromagnetic waves having wavelengths of at least 365 nm, 405 nm, and 436 nm. In this case, it is preferable from the viewpoint that the number of kinds of applicable polyimide components further increases.

The base generator represented by the formula (a) is preferably such that the molar absorbance coefficient of the base generator is 100 or greater for the wavelength of electromagnetic waves of 365 nm, or 1 or greater for 405 nm, from the viewpoint that the number of kinds of applicable polyimide component is further increased.

Meanwhile, it can be verified that the base generator represented by the formula (a) according to the present embodiment has absorption for the wavelength range described above, by dissolving the base generator represented by the formula (a) in a solvent which does not have absorption in the relevant wavelength range (for example, acetonitrile) to a concentration of 1×10⁻⁴ mol/L or less (usually, about 1×10⁻⁴ mol/L to 1×10⁻⁵ mol/L, the concentration may be appropriately adjusted so as to obtain an appropriate absorption intensity), and measuring the absorbance with an ultraviolet/visible spectrophotometer (for example, UV-2550™ manufactured by Shimadzu Corp.).

Also, as the radical-crosslinkable monomer to be used in the present embodiment, for example, a compound having one or two or more ethylenically unsaturated bonds can be used, and more specific examples thereof include amide-based monomers, (meth)acrylate monomers, urethane (meth)acrylate oligomers, polyester (meth)acrylate oligomers, epoxy (meth)acrylate, hydroxyl group-containing (meth)acrylate, and aromatic vinyl compounds such as styrene. Furthermore, in the case where the polyimide component has a carboxylic acid component such as polyamic acid in the structure, when an ethylenically unsaturated bond-containing compound having a tertiary amino group is used, the compound forms ionic bonding with the carboxylic acid of the polyimide component, and the contrast of dissolution rate between the exposed area and the unexposed area obtainable when prepared into a photosensitive polyimide resin composition is increased.

Examples of the acid-crosslinkable monomer that is used in the present embodiment include aliphatic cyclic hydrocarbons having a hydroxyl group or a hydroxyalkyl group, or both, such as 4,4′-methylenebis[2,6-bis(hydroxymethyl)]phenol (MBHP), 4,4′-methylenebis[2,6-bis(methoxymethyl)]phenol (MBMP), 2,3-dihydroxy-5-hydroxymethylnorbornane, 2-hydroxy-5,6-bis(hydroxymethyl)norbornane, cyclohexanedimethanol, 3,4,8 (or 9)-trihydroxytricyclodecane, 2-methyl-2-adamantanol, 1,4-dioxane-2,3-diol, and 1,3,5-trihydroxycyclohexane; and oxygen-containing derivatives thereof.

Furthermore, as the acid-crosslinkable monomer, a compound obtained by allowing an amino group-containing compound such as melamine, acetoguanamine, benzoguanamine, urea, ethyleneurea, propyleneurea or glycoluril, to react with formaldehyde, or with formaldehyde and a lower alcohol, and thereby substituting the hydrogen atom of the amino group with a hydroxymethyl group or a lower alkoxymethyl group, can also be used. Among them, a product obtained by using melamine is called a melamine-based crosslinking agent; a product obtained by using urea is called a urea-based crosslinking agent; a product obtained by using an alkyleneurea such as ethyleneurea or propyleneurea is called an alkyleneurea-based crosslinking agent; and a product obtained by using glycoluril is called a glycoluril-based crosslinking agent.

Examples of the melamine-based crosslinking agent include hexamethoxymethylmelamine, hexaethoxymethylmelamine, hexapropoxymethylmelamine, and hexabutoxybutylmelamine.

Examples of the urea-based crosslinking agent include bismethoxymethylurea, bisethoxymethylurea, bispropoxymethylurea, and bisbutoxymethylurea.

Examples of the alkyleneurea-based crosslinking agent include ethyleneurea-based crosslinking agents such as mono- and/or dihydroxymethylated ethyleneurea, mono- and/or dimethoxymethylated ethyleneurea, mono- and/or diethoxymethylated ethyleneurea, mono- and/or dipropoxymethylated ethyleneurea, and mono- and/or dibutoxymethylated ethyleneurea; propyleneurea-based crosslinking agents such as mono- and/or dihydroxymethylated propyleneurea, mono- and/or dimethoxymethylated propyleneurea, mono- and/or diethoxymethylated propyleneurea, mono- and/or dipropoxymethylated propyleneurea, and mono- and/or dibutoxymethylated propyleneurea; 1,3-di(methoxymethyl)-4,5-dihydroxy-2-imidazolidinone, and 1,3-di(methoxymethyl)-4,5-dimethoxy-2-imidazolidinone.

Examples of the glycoluril-based crosslinking agent include mono-, di-, tri- and/or tetrahydroxymethylated glycoluril, mono-, di-, tri- and/or tetramethoxymethylated glycoluril, mono-, di-, tri- and/or tetraethoxymethylated glycoluril, and mono-, di-, tri- and/or tetrabutoxymethylated glycoluril.

In regard to the photoinitiators such as the photoradical generators and photoacid generators, naphthoquinone diazide compounds, and crosslinkable components such as ethylenic double bond sites to be used in the present embodiment, any compounds that are used in general photosensitive polyimide resin compositions can be used.

In the present embodiment, in the case where there are overlapping portions between the absorption wavelength range of the photobase generator and the absorption wavelength range of the polyimide component, and sufficient sensitivity cannot be obtained, addition of a sensitizer as a means for enhancing sensitivity may be effective. Furthermore, even in the case where the photobase generator has an absorption wavelength in the wavelength band of the electromagnetic waves that penetrate the polyimide component, a sensitizer can be added as a means for enhancing sensitivity. However, it is necessary to consider a decrease in the film properties of the resulting pattern, particularly the film strength and heat resistance, which comes along with a reduction of the content of the polyimide component due to the addition of a sensitizer.

Specific examples of compounds known as sensitizers include thioxanthone, diethylthioxanthone and derivatives thereof, cyanine and derivatives thereof, merocyanine and derivatives thereof, coumarins and derivatives thereof, ketocoumarin and derivatives thereof, ketobiscoumarin and derivatives thereof, cyclopentanone and derivatives thereof, cyclohexanone and derivatives thereof, thiopyrylium salts and derivatives thereof, quinolines and derivatives thereof, styrylquinolines and derivatives thereof, thioxanthenes, xanthenes and derivatives thereof, oxonols and derivatives thereof, rhodamines and derivatives thereof, and pyrylium salts and derivatives thereof.

In the present embodiment, these sensitizers can be used singly or as mixtures of two or more kinds.

c. Solvent

The solvent to be used in the present embodiment is not particularly limited as long as it can uniformly disperse or dissolve the polyimide component or the photosensitive component. Solvents are used singly or in combination.

Among them, suitable examples include polar solvents such as N-methyl-2-pyrrolidone, N,N-dimethylformamide, N,N-dimethylacetamide, N,N-diethylformamide, N,N-diethylacetamide, N,N-dimethylmethoxyacetamide, dimethyl sulfoxide, hexamethylphosphoamide, N-acetyl-2-pyrrolidone, pyridine, dimethylsulfone, tetramethylenesulfone, dimethyltetramethylenesulfone, diethylene glycol dimethyl ether, cyclopentanone, γ-butyrolactone, α-acetyl, and γ-butyrolactone.

Furthermore, in the case of using polyamic acid which is a polyimide precursor as the polyimide component, the solution obtained by the synthesis reaction of polyamic acid is used directly as the solvent, and other components may be incorporated thereto as necessary.

d. Others

The photosensitive polyimide resin composition according to the present embodiment includes at least the polyimide component, the photosensitive component, and a solvent, but if necessary, the resin composition may also include other components.

A photosensitive polyimide resin composition may also be prepared by incorporating, as such other components, a thermosetting component, a non-polymerizable binder resin other than a polyimide precursor, and other additives.

In the present embodiment, various other organic or inorganic low molecular weight or polymeric compounds may be incorporated in order to impart processing characteristics or various functionalities to the photosensitive polyimide resin composition. For example, a dye, a surfactant, a leveling agent, a plasticizer, and fine particles can be used. Examples of the fine particles include organic fine particles of polystyrene, and polytetrafluoroethylene; and inorganic fine particles of colloidal silica, carbon, and lamellar silicates. These fine particles may be porous or may have hollow structures. Furthermore, in view of function or shape, a pigment, a filler, a fiber and the like may also be used.

Furthermore, the mixing proportion of the other arbitrary components in the present embodiment is preferably in the range of 0.1% by weight to 20% by weight relative to the total solids content of the photosensitive polyimide resin composition. If the mixing proportion is less than 0.1% by weight, the effect of adding the additives is not easily exhibited, and if the mixing proportion is greater than 20% by weight, the characteristics of the resin cured product finally obtained may not be reflected in the final product.

(ii) Photosensitive Polyimide Insulating Layer

The photosensitive polyimide insulating layer used in the present embodiment is formed by using the photosensitive polyimide resin composition.

The photosensitive polyimide insulating layer according to the present embodiment may be at least one semiconductor layer-adjoining insulating layer, and as previously explained in FIG. 1 to FIG. 3, the photosensitive polyimide insulating layer is used as a gate insulating layer in a top-gate type TFT, or as a gate insulating layer or a passivation layer in a bottom-gate type TFT.

According to the present embodiment, above all, as for the semiconductor later-adjoining insulating layer, it is preferable for the photosensitive polyimide insulating layer to be used as at least a gate insulating layer in a top-gate type TFT, or as at least one of a gate insulating layer and a passivation layer in a bottom-gate type TFT. Particularly, as for the semiconductor layer-adjoining insulating layer, it is preferable for the photosensitive polyimide insulating layer to be used at least as a gate insulating layer in a top-gate type TFT, or as a passivation layer in a bottom-gate type TFT. Above all, particularly as for the semiconductor layer-adjoining insulating layer, it is preferable for the photosensitive polyimide insulating layer to be used as a gate insulating layer in a top-gate type TFT, or at least as both a gate insulating layer and a passivation layer in a bottom-gate type TFT. More preferably, it is preferable for the photosensitive polyimide insulating layer to be used in all of the semiconductor layer-adjoining insulating layers. The gate insulating layer and the passivation layer have, even among the semiconductor layer-adjoining insulating layers, larger contact areas with the oxide semiconductor layer, and are susceptible to the influence of outgassing from the semiconductor layer-adjoining insulating layer. Accordingly, when the photosensitive polyimide insulating layer is used in these semiconductor layer-adjoining insulating layers, the oxide semiconductor layer can have fewer impurities, and the effect of the present embodiment can be more effectively exhibited. Also, the processes can be made simple.

Furthermore, the gate insulating layer in a top-gate type TFT and the passivation layer in a bottom-gate type TFT are usually formed so as to cover the oxide semiconductor layer. Therefore, in the case where the photosensitive polyimide resin composition contains a polyimide precursor, the photosensitive polyimide insulating layer is formed by applying the photosensitive polyimide resin composition after the formation of the oxide semiconductor layer, and subsequently imidizing the polyimide precursor. Accordingly, without the need to separately perform the steam annealing treatment of the oxide semiconductor layer, the steam annealing treatment of the oxide semiconductor layer can be carried out simultaneously with the imidization, and a TFT substrate having further excellent switching characteristics can be obtained through simple processes.

Furthermore, the effect of the present embodiment can be more effectively exhibited by using the photosensitive polyimide insulating layer in all of the semiconductor layer-adjoining insulating layers.

The photosensitive polyimide insulating layer according to the present embodiment has insulating properties. Specifically, the volume resistivity of the photosensitive polyimide insulating layer is preferably 1.0×10⁹ Ω·m or greater, and above all, more preferably 1.0×10¹⁰ Ω·m or greater, and particularly preferably 1.0×10¹¹ Ω·m or greater.

Meanwhile, the volume resistivity can be measured by a technique equivalent to the standards of JIS K6911, JIS C2318, ASTM D257 and the like.

The thickness of the photosensitive polyimide insulating layer according to the present embodiment is appropriately set in accordance with the semiconductor layer-adjoining insulating layers used same as the thickness of general semiconductor layer-adjoining insulating layers.

The photosensitive polyimide insulating layer according to the present embodiment contains at least the polyimide resin, but to an extent that the amount of outgassing can be regulated in a desired range, the photosensitive polyimide insulating layer may also include additives such as a leveling agent, a plasticizer, a surfactant, a defoamant, and a sensitizer; and insulating organic materials such as an acrylic resin, a phenolic resin, a fluororesin, an epoxy-based resin, a cardo-based resin, a vinyl-based resin, an imide-based resin, and a novolac-based resin.

The imidization ratio of the polyimide resin contained in the photosensitive polyimide insulating layer of the present embodiment is not particularly limited as long as the intended characteristics such as insulating properties, heat resistance, and low outgassing properties can be exhibited. However, specifically, the imidization ratio is preferably 90% or higher, and above all, more preferably 95% or higher, and particularly preferably 100%, that is, it is preferable that the polyimide resin do not contain polyamic acid which is a polyimide precursor. It is because when the imidization ratio is in the range described above, the photosensitive polyimide insulating layer may have especially excellent heat resistance and low outgassing properties.

The method for forming the photosensitive polyimide insulating layer according to the present embodiment is not particularly limited as long as it is a method capable of forming the photosensitive polyimide insulating layer by using the photosensitive polyimide resin composition, and a photolithographic method, a printing method, or the like can be used.

An example of the photolithographic method may be a method of forming a photosensitive polyimide resin film by applying the photosensitive polyimide resin composition on the substrate described above, and then subjecting the photosensitive polyimide resin film to patternwise exposure through a mask and development.

As the coating method, a spin coating method, a die coating method, a dip coating method, a bar coating method, a gravure printing method, or a screen printing method can be used.

Furthermore, examples of the printing method include methods utilizing known printing technologies, such as gravure printing, flexographic printing, screen printing, and inkjet printing.

When the photosensitive polyimide resin composition contains a polyimide precursor as the polyimide component, imidization of the polyimide precursor is carried out.

The method of imidizing a polyimide precursor is not particularly limited as long as it is a method capable of imidizing polyamic acid that is included in the polyimide precursor by means of a dehydration-ring closure reaction, but conventionally, a method of using an annealing treatment (heating treatment) can be used.

Such an annealing temperature (heating temperature) is appropriately set in consideration of the type of the polyimide precursor used, the heat resistance of the members that constitute the TFT substrate of the present embodiment, and the like. However, the annealing treatment is usually carried out at a temperature in the range of 200° C. to 500° C., and above all, the annealing temperature is preferably in the range of 250° C. to 400° C., while from the viewpoints of the properties after curing of the polyimide precursor and the low outgassing properties, the annealing temperature is particularly preferably in the range of 280° C. to 400° C. It is because when the annealing temperature is in the range described above, imidization can be sufficiently carried out, and thermal deterioration of other members can be suppressed.

According to the present embodiment, the timing of performing the imidization is not particularly limited as long as the photosensitive polyimide insulating layer can be stably formed. However, it is preferable to perform imidization after the oxide semiconductor layer has been formed, that is, in the case where the photosensitive polyimide insulating layer is formed by using a photosensitive polyimide resin composition containing a polyimide precursor as described above, it is preferable that the photosensitive polyimide insulating layer be formed by imidizing the polyimide precursor after the oxide semiconductor layer has been formed. It is because the steam annealing treatment of the oxide semiconductor can be simultaneously carried out.

Therefore, in the case where the oxide semiconductor layer is formed on the photosensitive polyimide insulating layer, it is preferable to perform patterning of the coating film of the photosensitive polyimide insulating layer, imidizing a portion of the polyimide precursor (partial imidization) so that the photosensitive polyimide insulating layer can endure the processes before or after imidization, subsequently forming the oxide semiconductor layer, subsequently performing imidization of the remaining polyimide precursor, and performing steam annealing of the oxide semiconductor layer by utilizing the water that is produced as a side product at the time of imidization.

(b) Semiconductor Layer-Adjoining Insulating Layer

It is desirable for the semiconductor layer-adjoining insulating layer used in the present embodiment if at least one is the photosensitive polyimide insulating layer.

According to the present embodiment, the other semiconductor layer-adjoining insulating layer may be insulating layer other than the photosensitive polyimide insulating layer.

These other insulating layers are not particularly limited as long as they can exhibit intended insulating performance, and the same insulating layers as those used in general TFTs can be used. Examples thereof include layers formed by using inorganic insulating materials such as silicon oxide, silicon nitride, aluminum oxide, tantalum oxide, barium strontium titanate (BST), and lead zirconium titanate (PZT); and the organic insulating materials described above.

(2) Oxide Semiconductor Layer

The oxide semiconductor layer used in the present embodiment is formed from an oxide semiconductor.

Examples of such an oxide semiconductor that can be used include zinc oxide (ZnO), titanium oxide (TiO), magnesium zinc oxide (MgₓZn₁₋ₓO), cadmium zinc oxide (CdₓZn₁₋ₓO), cadmium oxide (CdO), indium oxide (In₂O₃), gallium oxide (Ga₂O₃), tin oxide (SnO₂), magnesium oxide (MgO), tungsten oxide (WO), an InGaZnO system, an InGaSnO system, an InGaZnMgO system, an InAlZnO system, an InFeZnO system, an InGaO system, a ZnGaO system, and an InZnO system.

Regarding the forming method and the thickness of the oxide semiconductor layer that is used in the present embodiment, those generally used in the art can be employed.

(3) TFT

The structure of the TFT used in the present embodiment is not particularly limited as long as the TFT has the oxide semiconductor layer and the semiconductor layer-adjoining insulating layer as described above, and examples thereof include a top-gate structure (a staggered type, coplanar type structure), and a bottom-gate structure (an inverted staggered type, coplanar type structure). In the case of the top-gate structure (staggered type) and the bottom-gate structure (inverted staggered type), further examples include a top-contact structure and a bottom-contact structure. These structures are appropriately selected in accordance with the type of the oxide semiconductor layer that constitutes the TFT.

The TFT used in the present embodiment usually has a gate electrode, a source electrode, and a drain electrode, in addition to the oxide semiconductor layer and the semiconductor layer-adjoining insulating layer.

Furthermore, if necessary, the TFT may also have non-semiconductor layer-adjoining insulating layer in addition to the semiconductor layer-adjoining insulating layer.

The gate electrode, source electrode and drain electrode according to the present embodiment are not particularly limited as long as they have intended electroconductivity, and any electroconductive materials that are generally used in TFTs can be used. Examples of these materials include inorganic materials such as tantalum (Ta), titanium (Ti), aluminum (Al), zirconium (Zr), chromium (Cr), niobium (Nb), hafnium (Hf) molybdenum (Mo), gold (Au), silver (Ag), platinum (Pt), a Mo—Ta alloy, a W—Mo alloy, ITO, and IZO; and organic materials having electroconductivity, such as PEDOT/PSS.

Regarding the forming method and the thickness of the gate electrode, the source electrode and the drain electrode, forming methods and thicknesses that are generally used can be employed.

The non-semiconductor layer-adjoining insulating layer according to the present embodiment is not particularly limited as long as it has intended insulating properties, and the layer can contain the materials disclosed in the section “(1) Semiconductor layer-adjoining insulating layer” described above.

In the present embodiment, above all, it is preferable that the non-semiconductor layer-adjoining insulating layer be formed from the photosensitive polyimide resin composition described above. It is because the process can be made simple, cost reduction can be promoted, and also excellent switching characteristics can be obtained.

2. Substrate

The substrate used in the present embodiment is not particularly limited as long as it is a substrate capable of supporting the TFT. For example, a non-flexible substrate, or a flexible substrate having flexibility can be used.

According to the present embodiment, above all, a flexible substrate is preferred. It is because production in a large area is easy, and a flexible TFT substrate having excellent impact resistance can be obtained. Furthermore, it is because, unlike those insulating layers formed from inorganic substances, the photosensitive polyimide insulating layer described above does not cause inconveniences such as cracking even in the case where a flexible substrate is used as the substrate.

Examples of the material for the non-flexible substrate according to the present embodiment include glass, silicon, and metal plates.

Furthermore, as the flexible substrate, a film formed from a resin, or a laminate in which a film is laminated on a metal foil can be used.

According to the present embodiment, among others, a flexible substrate which has a metal foil and a planarizing layer containing a polyimide that is formed on the metal foil is preferred, and particularly, a flexible substrate having an adhesion layer containing an inorganic compound on the planarizing layer is preferred.

It is because when the flexible substrate has a planarizing layer, since a planarizing layer containing a polyimide is formed on a metal foil, the surface unevenness of the metal foil surface can be planarized, and a decrease in the electrical performance of the TFT can be prevented.

Also, it is because when the flexible substrate has an adhesion layer, when the adhesiveness to the TFT is superior, and even if moisture or heat is applied at the time of production of a flexible TFT substrate, and the dimension of the planarizing layer containing a polyimide is changed, the electrodes and oxide semiconductor layer constituting the TFT can be prevented from undergoing peeling or cracking.

Hereinafter, such metal foil, planarizing layer and adhesion layer will be described in detail.

(1) Adhesion Layer

The adhesion layer according to the present embodiment is formed on the planarizing layer and contains an inorganic compound, and the adhesion layer is a layer provided between a planarizing layer containing a polyimide and the TFT produced on a flexible substrate, in order to obtain a sufficient adhesive force.

The adhesion layer is preferably a layer having smoothness. The surface roughness Ra of the adhesion layer may be smaller than the surface roughness Ra of a metal foil, and specifically, the surface roughness is preferably 25 nm or less, and more preferably 10 nm or less. It is because if the surface roughness Ra of the adhesion layer is too large, there is a risk that the electrical performance of the TFT may deteriorate.

Meanwhile, the surface roughness Ra is the value measured by using an atomic force microscope (AFM) or a scanning type white interferometer. For example, in the case of measuring the surface roughness by using an AFM, the Ra can be determined by taking the surface image by using a Nanoscope V Multimode™ (manufactured by Veeco Instruments, Inc.) in the tapping mode, under the conditions of cantilever: MPP11100, scanning range: 50 μm×50 μm, and scanning speed: 0.5 Hz, and calculating the mean difference from the center line of a roughness curve calculated from the image thus obtained. Furthermore, in the case of measuring the surface roughness by using a scanning type white interferometer, the Ra can be determined by taking the surface image of a size of 50 μm×50 μm by using a New View 5000™ (manufactured by Zygo Corp.) under the conditions of object lens: 100 times, zoom lens: 2 times, and scan length: 15 μm, and calculating the mean difference from the centerline of a roughness curve calculated from the image thus obtained.

Furthermore, it is preferable that the adhesion layer have heat resistance. It is because at the time of production of a TFT, a high temperature treatment is usually carried out. The heat resistance of the adhesion layer is preferably such that the 5% weight loss temperature of the adhesion layer is 300° C. or higher.

Meanwhile, for the measurement of the 5% weight loss temperature, a thermogravimetric-differential thermal analysis (TG-DTA) was carried out by using a thermal analyzer (DTG-60™, manufactured by Shimadzu Corp.) under the conditions of atmosphere: nitrogen atmosphere, temperature range: 30° C. to 600° C., and rate of temperature increase: 10° C./min, and the temperature at which the weight of a sample was reduced by 5% was defined as the 5% weight loss temperature (° C.).

The adhesion layer usually has insulating properties. It is because insulating properties are required in order to produce a TFT on a flexible substrate.

Furthermore, it is preferable that the adhesion layer prevent the diffusion of impurity ions and the like that are contained in the planarizing layer containing a polyimide, into the oxide semiconductor layer of the TFT. Specifically, the ion permeability of the adhesion layer is preferably such that the iron (Fe) ion concentration is 0.1 ppm or less, or the sodium (Na) ion concentration is 50 ppb or less. Meanwhile, as the method for measuring the concentrations of Fe ion and Na ion, a method of sampling and extracting the layer formed on the adhesion layer followed by analyzing the layer by an ion chromatographic method is used.

The inorganic compound that constitutes the adhesion layer is not particularly limited as long as the characteristics described above are satisfied, and examples thereof include silicon oxide, silicon nitride, silicon oxynitride, aluminum oxide, aluminum nitride, aluminum oxynitride, chromium oxide, and titanium oxide. These may be used singly or as mixtures of two or more kinds.

The adhesion layer may be a single layer, or may be a multilayer.

When the adhesion layer is a multilayer, plural layers formed from the inorganic compounds described above may be laminated, or layers formed from the inorganic compounds and layers formed from metals may be laminated. The metals used in this case are not particularly limited as long as an adhesion layer which satisfies the characteristics described above can be obtained, and examples thereof include chromium, titanium, aluminum, and silicon.

Furthermore, when the adhesion layer is a multilayer, it is preferable that the outermost layer of the adhesion layer be a silicon oxide film. It is because a silicon oxide film sufficiently satisfies the characteristics described above. In this case, the silicon oxide is preferably SiO_{X} (X is in the range of 1.5 to 2.0).

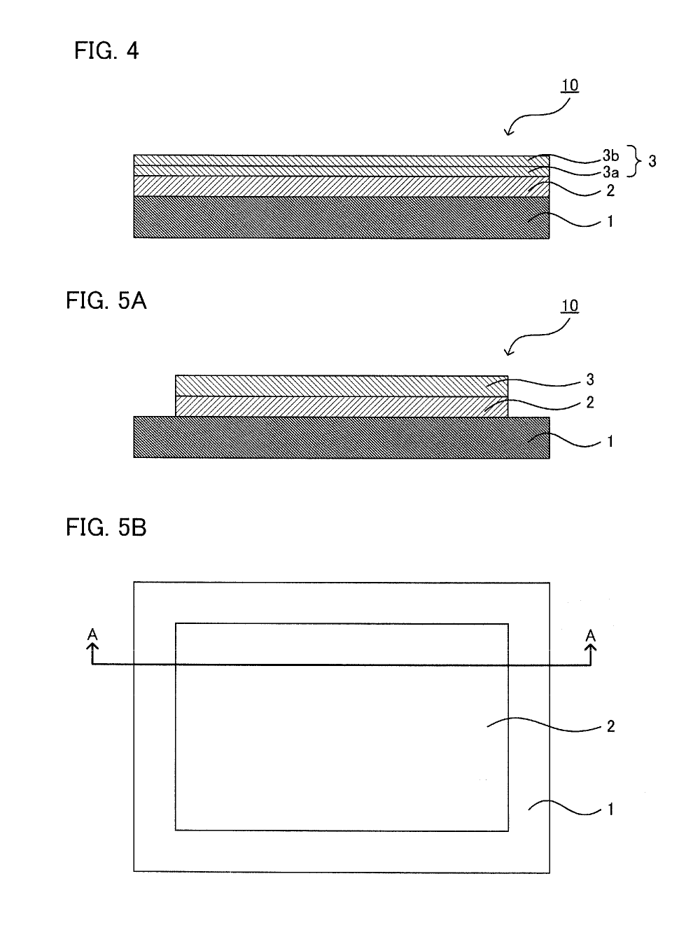

In the present embodiment, above all, as illustrated in FIG. 4, it is preferable that an adhesion layer 3 include a first adhesion layer 3a that is formed on a planarizing layer 2 and is formed from at least one selected from the group consisting of chromium, titanium, aluminum, silicon, silicon nitride, silicon oxynitride, aluminum oxide, aluminum nitride, aluminum oxynitride, chromium oxide and titanium oxide; and a second adhesion layer 3b that is formed on the first adhesion layer 3a and is formed of silicon oxide. It is because the adhesiveness between the planarizing layer and the second adhesion layer can be increased by the first adhesion layer, and the adhesiveness between the planarizing layer and the TFT produced on a flexible substrate can be increased by the second adhesion layer. Furthermore, it is because the second adhesion layer formed of silicon oxide sufficiently satisfies the characteristics described above.

The thickness of the adhesion layer is not particularly limited as long as the thickness can satisfy the characteristics described above, but specifically, the thickness is preferably in the range of 1 nm to 500 nm. Above all, when the adhesion layer includes a first adhesion layer and a second adhesion layer as described above, it is preferable that the thickness of the second adhesion layer be greater than the thickness of the first adhesion layer, and that the first adhesion layer be relatively thinner, while the second adhesion layer be relatively thicker. In this case, the thickness of the first adhesion layer is preferably in the range of 0.1 nm to 50 nm, more preferably in the range of 0.5 nm to 20 nm, and even more preferably in the range of 1 nm to 10 nm. Furthermore, the thickness of the second adhesion layer is preferably in the range of 10 nm to 500 nm, more preferably in the range of 50 nm to 300 nm, and even more preferably in the range of 80 nm to 120 nm. It is because if the thickness is too small, there is a risk that sufficient adhesiveness may not be obtained, and if the thickness is too large, there is a risk that cracks may occur in the adhesion layer.

The adhesion layer may be formed over the entire surface of a metal foil, or may be formed partially over a metal foil. Above all, in the case where a planarizing layer is formed partially on a metal foil as will be described below, it is preferable that the adhesion layer 3 be also formed partially on the metal foil 1 same as the planarizing layer 2, as illustrated in FIG. 5A. It is because if an adhesion layer containing an inorganic compound is formed directly on a metal foil, cracks and the like may occur in the adhesion layer. That is, it is preferable that the adhesion layer and the planarizing layer have the same shape.

The method for forming an adhesion layer is not particularly limited as long as it is a method capable of forming a layer formed from the inorganic compounds described above or a layer formed from the metals described above, and examples of the method include a direct current (DC) sputtering method, a radiofrequency (RF) magnetron sputtering method, and a plasma chemical vapor deposition (CVD) method. Among them, in the case of forming a layer formed from the inorganic compounds described above, and in the case of forming a layer containing aluminum or silicon, it is preferable to use a reactive sputtering method. It is because a film having excellent adhesiveness to the planarizing layer can be obtained.

(2) Planarizing Layer

The planarizing layer according to the present embodiment is formed on a metal foil and contains a polyimide, and the planarizing layer is a layer provided in order to planarize the surface unevenness of the metal foil.

It is desirable if the surface roughness Ra of the planarizing layer is smaller than the surface roughness Ra of the metal foil, but specifically, the surface roughness is preferably 25 nm or less, and more preferably 10 nm or less. Meanwhile, the method for measuring the surface roughness is the same as the method for measuring the surface roughness of the adhesion layer.

The planarizing layer contains a polyimide, and preferably contains a polyimide as a main component. Generally, polyimides have water absorbency. Since many of the semiconductor materials used in TFTs are vulnerable to moisture, in order to reduce moisture inside the element and to realize high reliability in the presence of humidity, it is preferable that the planarizing layer have relatively low water absorbency. One of the indices for water absorbency is the coefficient of hygroscopic expansion, and a smaller coefficient of hygroscopic expansion means lower water absorbency. Therefore, it is more preferable if the coefficient of hygroscopic expansion of the planarizing layer is smaller, and specifically, the coefficient of hygroscopic expansion is preferably in the range of 0 ppm/% RH to 15 ppm/% RH, more preferably in the range of 0 ppm/% RH to 12 ppm/% RH, and even more preferably in the range of 0 ppm/% RH to 10 ppm/% RH. When the coefficient of hygroscopic expansion of the planarizing layer is in the range described above, water absorbency of the planarizing layer can be made sufficiently small, storage of the flexible substrate is made easier, and in the case of producing a flexible TFT substrate, the process is made simple. Furthermore, as the coefficient of hygroscopic expansion is smaller, the dimensional stability is enhanced. If the coefficient of hygroscopic expansion of the planarizing layer is large, due to the difference in the expansion ratio with the metal foil whose coefficient of hygroscopic expansion is approximately close to zero, the flexible substrate may bend backward along with an increase in humidity, or the adhesiveness between the planarizing layer and the metal foil may decreased. Therefore, even in the case of carrying out a wet process in the production process, a smaller coefficient of hygroscopic expansion is preferred.

Meanwhile, the coefficient of hygroscopic expansion is measured as follows. First, a film of a planarizing layer only is produced. Regarding the method for producing a planarizing layer film, there are available a method of producing a planarizing layer film on a heat resistant film (Upilex S50S™ (manufactured by Ube Industries, Ltd.)) or a glass substrate, and then peeling the planarizing layer film; and a method of producing a planarizing layer film on a metal substrate, subsequently removing the metal by etching, and obtaining the planarizing layer film. Subsequently, the planarizing layer film thus obtained is cut to a size of 5 mm in width and 20 mm in length, and thus the cut film is used as an evaluation sample. The coefficient of hygroscopic expansion is measured with a humidity variable mechanical analyzer (Thermo Plus TMA8310™ (manufactured by Rigaku Corporation)). For example, the temperature is set constant at 25° C., and first a sample is brought to a stabilized state in an environment at a humidity of 15% RH. The state is maintained approximately for 30 minutes to 2 hours, and then the humidity at the measurement site is adjusted to 20% RH. The sample is further maintained for 30 minutes to 2 hours to be stabilized. Thereafter, the humidity is changed to 50% RH, and the difference between the sample length obtainable when the sample is stabilized at 50% RH and the sample length in the state of being stabilized at 20% RH is divided by the change in humidity (in this case, 50−20=30). The value is divided by the sample length, and the resulting value is designated as the coefficient of hygroscopic expansion (C.H.E.). During the measurement, the tensile load is set to 1 g/25,000 μm², such that the load per cross-section area of the evaluation sample is uniform.

Furthermore, the coefficient of linear thermal expansion of the planarizing layer is preferably such that, from the viewpoint of dimensional stability, the difference between the coefficient of linear thermal expansion of the planarizing layer and the coefficient of linear thermal expansion of the metal foil is 15 ppm/° C. or less, more preferably 10 ppm/° C. or less, and even more preferably 5 ppm/° C. or less. As the coefficients of linear thermal expansion of the planarizing layer and the metal foil are closer to each other, warpage of the flexible substrate is suppressed, and also, when the thermal environment of the flexible substrate is changed, the stress at the interface between the planarizing layer and the metal foil decreases, while the adhesiveness is increased. Also, it is preferable in view of handleability when the flexible substrate does not bend in a temperature environment in the range of 0° C. to 100° C.; however, since the coefficient of linear thermal expansion of the planarizing layer is large, if the coefficients of linear thermal expansion of the planarizing layer and the metal foil differ greatly from each other, the flexible substrate is bent backward upon a change in the thermal environment.

Meanwhile, when it is said that warpage does not occur in the flexible substrate, it is implied that when one of the edges of a sample obtainable by cutting the flexible substrate into a strip having a width of 10 mm and a length of 50 mm is fixed to a horizontally smooth stand, the floating distance of the other edge of the sample from the stand surface is 1.0 mm or less.

Specifically, the coefficient of linear thermal expansion of the planarizing layer is, from the viewpoint of dimensional stability, preferably in the range of 0 ppm/° C. to 30 ppm/° C., more preferably in the range of 0 ppm/° C. to 25 ppm/° C., even more preferably in the range of 0 ppm/° C. to 18 ppm/° C., particularly preferably in the range of 0 ppm/° C. to 12 ppm/° C., and most preferably in the range of 0 ppm/° C. to 7 ppm/° C.

Meanwhile, the coefficient of linear thermal expansion is measured as follows. First, a film of a planarizing layer only is produced. The method for producing a planarizing layer film is as described above. Subsequently, the planarizing layer film thus obtained is cut to a size of 5 mm in width and 20 mm in length, and thus the cut film is used as an evaluation sample. The coefficient of linear thermal expansion is measured with a thermomechanical analyzer (for example, Thermo Plus TMA8310™ (manufactured by Rigaku Corporation)). Regarding the measurement conditions, the rate of temperature increase is set to 10° C./min, the tensile load is set to 1 g/25,000 μm² such that the load per cross-section area of the evaluation sample is uniform, and the average coefficient of linear thermal expansion in the range of 100° C. to 200° C. is designated as the coefficient of linear thermal expansion (C.T.E.).

The planarizing layer has insulating properties. Specifically, the planarizing layer can be made the same as the photosensitive polyimide insulating layer.

The polyimide that constitutes the planarizing layer is not particularly limited as long as the polyimide satisfies the characteristics described above. For example, the coefficient of hygroscopic expansion or the coefficient of linear thermal expansion can be controlled by appropriately selecting the structure of the polyimide.

From the viewpoint of obtaining a suitable coefficient of linear thermal expansion or suitable coefficient of hygroscopic expansion of the planarizing layer for the flexible substrate, the polyimide is preferably polyimide containing an aromatic backbone. Among polyimides, polyimide having an aromatic backbone has excellent heat resistance or excellent insulating properties as a thin film due to the rigid backbone with high planarity, and also has a low coefficient of linear thermal expansion. Therefore, the polyimide containing an aromatic backbone is preferably used in the planarizing layer of a flexible substrate.

Since it is required that the polyimide exhibit low hygroscopic expansion and low linear thermal expansion, the polyimide preferably has a repeating unit represented by the following formula (21). Such a polyimide exhibits high heat resistance or high insulating properties originating from its rigid backbone, and also exhibits linear thermal expansion equivalent to that of metals. Furthermore, the coefficient of hygroscopic expansion can be made small.

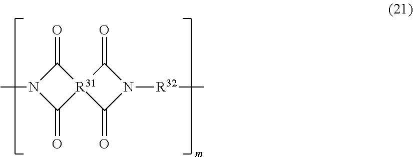

In the formula (21), R³¹ represents a tetravalent organic group; R³² represents a divalent organic group; repeating R³¹'s and R³²'s may be respectively identical with or different from each other; and “m” represents a natural number of 1 or greater.

In the formula (21), generally, R³¹ represents a structure derived from tetracarboxylic acid dianhydride, and R³² represents a structure derived from diamine.

The tetracarboxylic acid dianhydride that is applicable to the polyimide contained in the planarizing layer according to the present embodiment is not particularly limited as long as the tetracarboxylic acid dianhydride can form a polyimide having the characteristics described above, and specifically, the tetracarboxylic acid dianhydrides that are described in the section “1. TFT” to be applicable to the polyimide component can be used.

From the viewpoints of heat resistance, the coefficient of linear thermal expansion and the like of the polyimide contained in the planarizing layer according to the present embodiment, preferably used tetracarboxylic acid dianhydride is aromatic tetracarboxylic acid dianhydride. Particularly preferred examples of the tetracarboxylic acid dianhydride include pyromellitic dianhydride, mellophanic dianhydride, 3,3′,4,4′-benzophenonetetracarboxylic acid dianhydride, 3,3′,4,4′-biphenyltetracarboxylic acid dianhydride, 2,3,3′,4′-biphenyltetracarboxylic acid dianhydride, 2,3,2′,3′-biphenyltetracarboxylic acid dianhydride, 2,2′,6,6′-biphenyltetracarboxylic acid dianhydride, bis(3,4-dicarboxyphenyl)ether dianhydride, 2,2-bis(3,4-dicarboxyphenyl)-1,1,1,3,3,3-hexafluoropropane dianhydride, and bis(3,4-dicarboxyphenyl)ether dianhydride.

Among them, from the viewpoint of reducing the coefficient of hygroscopic expansion, 3,3′,4,4′-biphenyltetracarboxylic acid dianhydride, 2,3,3′,4′-biphenyltetracarboxylic acid dianhydride, 2,3,2′,3′-biphenyltetracarboxylic acid dianhydride, and bis(3,4-dicarboxyphenyl)ether dianhydride are particularly preferred.

When tetracarboxylic acid dianhydride having fluorine introduced thereto is used as the tetracarboxylic acid dianhydride to be used in combination, the coefficient of hygroscopic expansion of the polyimide is decreased. However, a polyimide precursor having a backbone containing fluorine does not easily dissolve in a basic aqueous solution, and it is necessary to carry out development by using a mixed solution of an organic solvent such as an alcohol and a basic aqueous solution.

Furthermore, when rigid tetracarboxylic acid dianhydride such as pyromellitic dianhydride, mellophanic dianhydride, 3,3′,4,4′-biphenyltetracarboxylic acid dianhydride, 2,3,3′,4′-biphenyltetracarboxylic acid dianhydride, 2,3,2′,3′-biphenyltetracarboxylic acid dianhydride, or 1,4,5,8-naphthalenetetracarboxylic acid dianhydride is used, it is preferable because the coefficient of linear thermal expansion of the polyimide is small. Among them, from the viewpoint of the balance between the coefficient of linear thermal expansion and the coefficient of hygroscopic expansion, 3,3′,4,4′-biphenyltetracarboxylic acid dianhydride 2,3,3′,4′-biphenyltetracarboxylic acid dianhydride, and 2,3,2′,3′-biphenyltetracarboxylic acid dianhydride are particularly preferred.

When the tetracarboxylic acid dianhydride has an alicyclic backbone, transparency of the polyimide precursor is increased, and therefore, the polyimide acquires high sensitivity. On the other hand, the heat resistance or insulating properties of the polyimide tend to be poorer as compared with aromatic polyimides.

In the case of using an aromatic tetracarboxylic acid dianhydride, there is an advantage that polyimide which exhibits excellent heat resistance and a low coefficient of linear thermal expansion is obtained. Therefore, in regard to the polyimide, it is preferable that 33% by mole or more of R³¹ in the formula (21) have any one of structures represented by the following formulas:

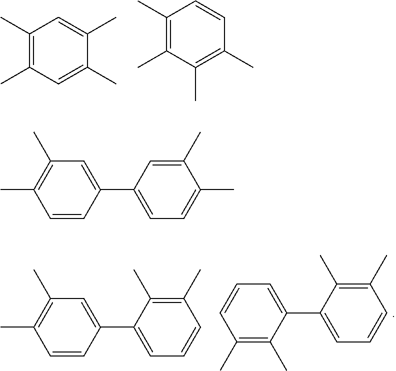

When the polyimide contained in the planarizing layer according to the present embodiment contains any of the structures of the above formulas, the polyimide exhibits low linear thermal expansion and linear hygroscopic expansion originating from these rigid backbones. Also, there is also an advantage that the polyimides are easily commercially available and are less expensive.

Polyimide having a structure such as described above is polyimide which exhibits high heat resistance and a low coefficient of linear thermal expansion. Therefore, it is preferable if the content of the structures represented by the above formulas is closer to 100% by mole of R³¹ in the formula (21), but it is acceptable if the content is at least 33% by mole or greater of R³¹ in the formula (21). Among them, the content of the structures represented by the above formulas is preferably 50% by mole or greater, and more preferably 70% by mole or greater, of R³¹ in the formula (21).

On the other hand, also for the diamine component that is applicable to the polyimide contained in the planarizing layer according to the present embodiment, one kind of a diamine can be used alone, or two or more kinds of diamines can be used in combination. There are no particular limitations on the diamine component to be used, and for example, the diamine components that are applicable to the polyimide component described in the section “1. TFT” can be used.

The diamine can be selected in accordance with the intended properties, and when rigid diamine such as p-phenylenediamine is used, the polyimide acquires a low coefficient of expansion. Examples of the rigid diamine include, as diamines in which two amino groups are bonded to the same aromatic ring, p-phenylenediamine, m-phenylenediamine, 1,4-diaminonaphthalene, 1,5-diaminonaphthalene, 2,6-diaminonaphthalene, 2,7-diaminonaphthalene, and 1,4-diaminoanthracene.

Furthermore, a diamine in which two or more aromatic rings are bonded by a single bond, and two or more amino groups are respectively bonded to different aromatic rings directly or as a part of a substituent, may be used, and for example, such diamine may be represented by the following formula (22). Specific examples thereof include benzidine.

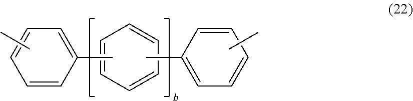

In the formula (22), “b” represents 0 or a natural number of 1 or greater; and amino groups are bonded at the meta-position or the para-position with respect to the bond between the benzene rings.

Furthermore, in the above formula (22), diamine which is not involved in any bond with other benzene rings and has substituents at positions where no amino group is substituted on the benzene ring, can also be used. These substituents may be monovalent organic groups, but the substituents may also be bonded to each other. Specific examples thereof include 2,2′-dimethyl-4,4′-diaminobiphenyl, 2,2′-ditrifluoromethyl-4,4′-diaminobiphenyl, 3,3′-dichloro-4,4′-diaminobiphenyl, 3,3′-dimethoxy-4,4′-diaminobiphenyl, and 3,3′-dimethyl-4,4′-diaminobiphenyl.

Furthermore, when fluorine is introduced as a substituent of the aromatic ring, the coefficient of hygroscopic expansion can be decreased. However, a polyimide precursor, particularly polyamic acid, containing fluorine does not easily dissolve in a basic aqueous solution. In the case of forming a planarizing layer partially on a metal foil, it may be necessary to carry out development with a mixed solution with an organic solvent such as an alcohol at the time of processing of the planarizing layer.

On the other hand, when diamine having a siloxane backbone, such as 1,3-bis(3-aminopropyl)tetramethyldisiloxane is used as the diamine, the adhesiveness to the metal foil may be improved, the elastic modulus of the polyimide can be decreased, and the glass transition temperature can be decreased.

Here, from the viewpoint of heat resistance, the diamine to be selected is preferably aromatic diamine. However, in accordance with the intended properties, diamine other than aromatic diamine, such as aliphatic diamine or siloxane-based diamine may also be used in an amount of no more than 60% by mole, and preferably 40% by mole, of the total content of the diamine.

Furthermore, in the polyamide that is contained in the planarizing layer according to the present embodiment, it is preferable hat 33% by mole or more of R³² in the formula (21) have any one of structures represented by the following formulas:

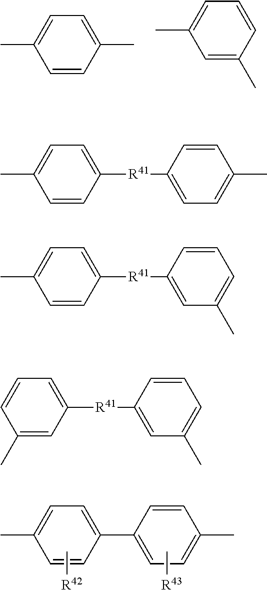

in which R⁴¹ represents a divalent organic group, an oxygen atom, a sulfur atom, or a sulfone group; and R⁴² and R⁴³ each represent a monovalent organic group, or a halogen atom.

When the polyimide contained in the planarizing layer according to the present embodiment contains any one of the structures represented by the above formulas, the polyimide exhibits low linear thermal expansion and low hygroscopic expansion due to these rigid structures. Furthermore, there is an advantage that the polyimide is easily commercially available, and is less expensive.

Polyimide having a structure such as described above is polyimide which exhibits high heat resistance and a low coefficient of linear thermal expansion. Therefore, it is preferable if the content of the structures represented by the above formulas is closer to 100% by mole of R³² in the formula (21), but it is still acceptable if the content is at least 33% by mole or greater of R³² in the formula (21). Above all, the content of the structures represented by the above formulas is preferably 50% by mole or greater, and more preferably 70% by mole or greater, of R³² in the formula (21).

Generally, since the coefficient of linear thermal expansion of a metal foil, that is, the coefficient of linear thermal expansion of a metal, is fixed to a certain degree, it is preferable to determine the coefficient of linear thermal expansion of the planarizing layer in accordance with the coefficient of linear thermal expansion of the metal foil to be used, and thereby appropriately select the structure of the polyimide.

Specifically, it is preferable to determine the coefficient of linear thermal expansion of the metal foil in accordance with the coefficient of linear thermal expansion of the TFT, determine the coefficient of linear thermal expansion of the planarizing layer in accordance with the coefficient of linear thermal expansion of the metal foil, and thereby appropriately select the structure of the polyimide.

In the present embodiment, it is preferable that the planarizing layer contain polyimide having a repeating unit represented by the formula (21) described above, and according to necessity, this polyimide may be used in the planarizing layer in the form of being appropriately laminated or combined with other polyimides.

Furthermore, the polyimide having a repeating unit represented by the formula (21) can be obtained by using a photosensitive polyimide resin composition having a polyimide component and a photosensitive component. It is because when such a photosensitive material is used, production can be achieved by a simple process.

In regard to the characteristics such as the 5% weight loss temperature of such a photosensitive polyimide resin composition, or the various components such as the photosensitive component used therein, the same matters as those described in the section “(1) Semiconductor layer-adjoining insulating layer” of “1. TFT” described above, can be applied.

When the polyimide according to the present embodiment is formed by using a photosensitive polyimide resin composition containing a polyimide precursor as a polyimide component, it is preferable that the polyimide precursor be developable by a basic aqueous solution, from the viewpoint of securing the safety of the working environment and reducing the process cost when the planarizing layer is formed partially on the metal foil. It is because since the basic aqueous solution can be purchased at low price, and the expenses for waste water treatment and the facility expenses for securing work safety are low, production at lower cost is attained.

Generally, since the coefficient of linear thermal expansion of a metal foil, that is, the coefficient of linear thermal expansion of a metal, is fixed to a certain degree, it is preferable to determine the coefficient of linear thermal expansion of the planarizing layer in accordance with the coefficient of linear thermal expansion of the metal foil to be used, and to thereby appropriately select the structure of the polyimide.

Specifically, it is preferable to determine the coefficient of linear thermal expansion of the metal foil in accordance with the coefficient of linear thermal expansion of the TFT, determine the coefficient of linear thermal expansion of the planarizing layer in accordance with the coefficient of linear thermal expansion of the metal foil, and thereby appropriately select the structure of the polyimide.

In the present embodiment, it is preferable that the planarizing layer contain polyimide having a repeating unit represented by the formula (21) described above, and according to necessity, this polyimide may be used in the planarizing layer in the form of being appropriately laminated or combined with other polyimides.

It is desirable as long as the planarizing layer contains polyimide, but above all, it is preferable for the planarizing layer to contain polyimide as a main component. When the planarizing layer contains polyimide as a main component, a planarizing layer having excellent insulating properties and heat resistance can be obtained. Furthermore, when the planarizing layer contains polyimide as a main component, the planarizing layer can be made into a thin film, thermal conductivity of the planarizing layer is enhanced, and a flexible substrate having excellent thermal conductivity can be obtained.

Meanwhile, when it is said that the planarizing layer contains polyimide as a main component, it is implied that the planarizing layer contains a polyimide to the extent that the characteristics described above are satisfied. Specifically, it is meant that the content of the polyimide in the planarizing layer is 75% by mass or greater, and preferably 90% by mass or greater, and it is particularly preferable that the planarizing layer be composed only of the polyimide. When the content of the polyimide in the planarizing layer is in the range described above, characteristics sufficient for achieving the purpose of the present embodiment can be exhibited, and as the content of the polyimide increases, characteristics intrinsic to the polyimide such as heat resistance and insulating properties are improved.

The planarizing layer may contain, if necessary, additives such as a leveling agent, a plasticizer, a surfactant, and a defoamant.

The planarizing layer may be formed over the entire surface of the metal foil, or may be formed partially on the metal foil. That is, on the surface of the metal foil where the planarizing layer and the adhesion layer are formed, a metal foil exposed region where the planarizing layer and the adhesion layer do not exist and the metal foil is exposed may be provided.

When the planarizing layer is partially formed on the metal foil, as illustrated in FIGS. 5A and 5B, the planarizing layer 2 may be formed in an area excluding at least the outer peripheral area of the metal foil 1. Meanwhile, FIG. 5A is a cross-sectional diagram cut along the line A-A of FIG. 5B and the adhesion layer is not depicted in FIG. 5B. When the planarizing layer is formed over the entire surface of the metal foil, and the edge areas of the planarizing layer are exposed, since polyimides generally exhibit hygroscopic properties, there is a risk that moisture may penetrate into the interior of the element through the cross-section of the planarizing layer at the time of production or operation. This moisture may cause deterioration in the element performance, or a change in the dimension of the planarizing layer. Therefore, it is preferable that the planarizing layer be not formed in the outer peripheral area of the metal foil, and the portion of the planarizing layer containing polyimide that is exposed directly to external air be reduced as much as possible.

Meanwhile, in the present embodiment, when it is said that the planarizing layer is formed partially on the metal foil, it is implied that the planarizing layer is not formed over the entire surface of the metal foil.

The planarizing layer may be formed on one surface of the metal foil excluding the outer peripheral area of the metal foil, or may be further formed in a pattern on the metal foil excluding the outer peripheral area of the metal foil.

The thickness of the planarizing layer is not particularly limited as long as it is a thickness that can satisfy the characteristics described above, but specifically, the thickness is preferably in the range of 1 μm to 1000 μm, more preferably in the range of 1 μm to 200 μm, and even more preferably in the range of 1 μm to 100 μm. It is because if the thickness of the planarizing layer is too small, the insulating properties may not be retained, or it may be difficult to planarize the surface unevenness of the metal foil. Furthermore, it is because if the thickness of the planarizing layer is too large, flexibility may decrease or become excessive, drying at the time of film formation may be difficult, or the amount of materials used increases, so that the cost may increase. Furthermore, in the case of imparting a heat dissipation function to the flexible substrate, if the thickness of the planarizing layer is too large, since the polyimide has lower thermal conductivity than metals, the thermal conductibility of the planarizing layer is decreased.

The method for forming the planarizing layer is not particularly limited as long as it is a method for obtaining a planarizing layer having satisfactory smoothness, and for example, a method of applying a polyimide solution or a polyimide precursor solution on a metal foil, a method of bonding a metal foil and a polyimide film by using an adhesive, or a method of heat pressing a metal foil and a polyimide film can be used. Among them, a method of applying a polyimide solution or a polyimide precursor solution is preferred. It is because a planarizing layer having excellent smoothness can be obtained. Particularly, a method of applying a polyimide precursor solution is suitable. It is because polyimides generally lack solubility in solvents. Also, it is because polyimide that is highly soluble in solvents is poor in the properties such as heat resistance, the coefficient of linear thermal expansion, and the coefficient of hygroscopic expansion.

The coating method is not particularly limited as long as it is a method capable of obtaining a planarizing layer with satisfactory smoothness, and the methods described in the section “(1) Semiconductor layer-adjoining insulating layer” of “1. TFT” can be used.

When a polyimide solution or a polyimide precursor solution is applied, fluidity of the film can be increased, and smoothness can be improved by heating the polyimide or polyimide precursor to or above a glass transition temperature after coating.

Furthermore, in the case of forming the planarizing layer partially on the metal foil, as the method for forming the planarizing layer, a printing method, a photolithographic method, or a method of directly processing with a laser or the like can be used. Examples of the photolithographic method include the method described in the section “(1) Semiconductor layer-adjoining insulating layer” of “1. TFT”; a method of forming a film of polyamic acid, which is a polyimide precursor, on a metal foil, subsequently forming a photosensitive resin film on the polyamic acid film, forming a photosensitive resin film pattern by a photolithographic method, subsequently removing the polyamic acid film at the pattern opening areas by using the pattern as a mask, subsequently removing the photosensitive resin film pattern, and imidizing the polyamic acid; a method of developing the polyamic acid film simultaneously with the formation of the photosensitive resin film pattern, subsequently, removing the photosensitive resin film pattern, and imidizing the polyamic acid; a method of laminating a metal foil and a planarizing layer, forming a photosensitive resin film pattern on the planarizing layer in the state of a laminate, etching the planarizing layer according to the pattern by a wet etching method or a dry etching method, and then removing the photosensitive resin pattern; a method of laminating a metal foil, a planarizing layer and a metal foil, patterning one of the metal foil of the laminate, etching the planarizing layer by using the pattern as a mask, and then removing the metal pattern; and a method of forming a pattern of a planarizing layer directly on a metal foil by using a photosensitive polyimide resin composition. As the printing method, the method described in the section “(1) Semiconductor layer-adjoining insulating layer” of “1. TFT” can be used.

(3) Metal Foil

The metal foil according to the present embodiment is to support the planarizing layer and the adhesion layer described above.

The coefficient of linear thermal expansion of the metal foil is preferably in the range of 0 ppm/° C. to 25 ppm/° C., more preferably in the range of 0 ppm/° C. to 18 ppm/° C., even more preferably in the range of 0 ppm/° C. to 12 ppm/° C., and particularly preferably in the range of 0 ppm/° C. to 7 ppm/° C., from the viewpoint of dimensional stability. Meanwhile, the method for measuring the coefficient of linear thermal expansion is the same as the method for measuring the coefficient of linear thermal expansion of the planarizing layer, except that the metal foil is cut to a size of 5 mm in width×20 mm in length, and this is used as the evaluation sample.

Furthermore, it is preferable that the metal foil have oxidation resistance. It is because a high temperature treatment is carried out during the production of a TFT. Particularly, in the case where the TFT has an oxide semiconductor layer, since an annealing treatment is carried out at a high temperature in the presence of oxygen, it is preferable that the metal foil have oxidation resistance.

The metal material that constitutes the metal foil is not particularly limited as long as the material can be formed into a foil and satisfies the characteristics described above, and examples thereof include aluminum, copper, a copper alloy, phosphor bronze, stainless steel (SUS), gold, a gold alloy, nickel, a nickel alloy, silver, a silver alloy, tin, a tin alloy, titanium, iron, an iron alloy, zinc, and molybdenum. Among them, when the coefficients of linear thermal expansion of the metal foil and the TFT are considered, in view of the coefficient of linear thermal expansion, titanium or invar having a coefficient of linear thermal expansion that is lower than that of SUS430 is preferred. However, it is desirable to select the metal material while taking into consideration of not only the coefficient of linear thermal expansion, but also the oxidation resistance, heat resistance, foil processability attributable to malleability and ductility of the metal foil, and the cost.

The thickness of the metal foil is not particularly limited as long as it is a thickness capable of satisfying the characteristics described above, but specifically, the thickness of the metal foil is preferably in the range of 1 μm to 1000 μm, more preferably in the range of 1 μm to 200 μm, and even more preferably in the range of 1 μm to 100 μm. If the thickness of the metal foil is too small, there is a risk that the gas barrier properties for oxygen or water vapor may decrease, or the strength of the flexible substrate may decrease. Also, if the thickness of the metal foil is too large, flexibility may decrease or become excessive, or the cost may increase.

The metal foil may be a rolled foil, or may be an electrolytic foil, and the metal foil is appropriately selected in accordance with the type of the metal material. The metal foil is usually produced by rolling.

The surface roughness Ra of the metal foil is larger than the surface roughness Ra of the adhesion layer and the planarizing layer, and is, for example, about 50 nm to 200 nm. Meanwhile, the method for measuring the surface roughness is the same as the method for measuring the surface roughness of the adhesion layer.

(4) Other Constitution

According to the present embodiment, an intermediate layer may be formed between the metal foil and the planarizing layer. For example, an intermediate layer formed from an oxide film which results from oxidation of the metal constituting the metal foil may be formed between the metal foil and the planarizing layer. Thereby, the adhesiveness between the metal foil and the planarizing layer can be increased. This oxide film is formed as the metal foil surface is oxidized.

Furthermore, the oxide film may also be formed on the surface of the metal foil on the opposite side of the surface where the planarizing layer is formed.

3. TFT Substrate

The TFT substrate of the present embodiment comprises at least the TFT and a substrate, but may also include other members as necessary.

The method for producing the TFT substrate of the present embodiment is not particularly limited as long as it is a method capable of forming a TFT substrate having the TFT and the substrate with high accuracy, and any general method can be used.

Regarding the use of the TFT substrate of the present embodiment, the TFT substrate can be used as a TFT array substrate for display devices that utilizes the TFT mode, and above all, it is preferable for the TFT substrate to be used as a TFT array substrate which is required to have excellent switching characteristics.

Examples of such a display device include liquid crystal display devices, an organic electroluminescent (EL) display devices, and electronic papers. Other examples of the use other than the display devices include circuits for radio-frequency identification (RFID), and sensors.

### II. Second Embodiment

The TFT substrate of the present embodiment comprises: the substrate described above, and a TFT having a semiconductor layer formed on the substrate and a semiconductor layer-adjoining insulating layer formed to be in contact with the semiconductor layer, wherein at least one semiconductor layer-adjoining insulating layer is a low-outgassing photosensitive polyimide insulating layer formed by using a low-outgassing photosensitive polyimide resin composition having a 5% weight loss temperature of 450° C. or higher.

Regarding the TFT substrate of the present embodiment as such, specifically, the same TFT substrate as that illustrated in FIG. 1 to FIG. 3 can be employed.

According to the present embodiment, when at least one semiconductor layer-adjoining insulating layer is the low-outgassing photosensitive polyimide insulating layer, a TFT substrate having a small weight loss of the semiconductor layer-adjoining insulating layer, that is, less outgassing, in a high temperature atmosphere or in a vacuum atmosphere when the semiconductor layer or other members are formed, can be obtained. Thereby, incorporation of volatile substances such as the photosensitive component that scatters away by outgassing, into the semiconductor layer can be suppressed, and the semiconductor layer can be made into a layer having fewer impurities originating from the semiconductor layer-adjoining insulating layer. As a result, the semiconductor layer can be made into a layer containing fewer impurities originating from the semiconductor layer-adjoining insulating layer, and a semiconductor layer having excellent switching characteristics can be obtained.

Furthermore, by employing the low-outgassing photosensitive polyimide insulating layer, that is, by forming a layer by using the low-outgassing photosensitive polyimide resin composition described above, an insulating layer can be formed by applying and patterning the low-outgassing photosensitive polyimide resin composition described above, without conducting a vapor deposition process using vacuum facilities that is required for the formation of insulating layers formed from inorganic compounds. Thus, the process can be made simple. Furthermore, even when compared with the case of forming an insulating layer by using a non-photosensitive resin, since patterning is easily achieved, the processability is excellent, and the insulating layers can be produced by a simple process. Also, since the insulating layers are made of resins, for example, even in the case of producing a flexible TFT substrate by using a flexible substrate as the substrate, cracks do not easily occur in the low-outgassing photosensitive polyimide insulating layers.

From these, the low-outgassing photosensitive polyimide insulating layers can be produced by a simple process, and insulating layers having excellent switching characteristic can be obtained.

Meanwhile, outgassing according to the present embodiment means that decomposition products of the polyimide resin, or decomposition residues of the photosensitive component are generated under high temperature conditions or high vacuum conditions, and these residues do not contain moisture (water vapor) or residual solvent, which can be easily removed by, for example, drying and heating at 100° C. for about 60 minutes.

The TFT substrate of the present embodiment includes at least a substrate and a TFT.

Hereinafter, the various configurations of the TFT substrate of the present embodiment will be described in detail.

Meanwhile, with regard to the substrate, the same matters as those described in the section “2. Substrate” of “I. First embodiment” can be applied. Thus, further explanation will not be repeated here.

1. TFT

The TFT used in the present embodiment has at least the semiconductor layer and the semiconductor layer-adjoining insulating layer described above.

(1) Semiconductor Layer-Adjoining Insulating Layer

The semiconductor layer-adjoining insulating layer used in the present embodiment is formed to be in contact with the semiconductor layer, and at least one is the low-outgassing photosensitive polyimide insulating layer.

(a) Low-Outgassing Photosensitive Polyimide Insulating Layer

The low-outgassing photosensitive polyimide insulating layer used in the present embodiment is formed by a low-outgassing photosensitive polyimide resin composition.

(i) Low-Outgassing Photosensitive Polyimide Resin Composition

The low-outgassing photosensitive polyimide resin composition used in the present embodiment has a 5% weight loss temperature of 450° C. or higher.

Here, a low-outgassing photosensitive polyimide resin composition having a 5% weight loss temperature of 450° C. or higher means that with regard to a polyimide film containing a polyimide resin that is obtained after curing of the low-outgassing photosensitive polyimide resin composition, on the occasion of measuring the weight loss by using a thermogravimetric analyzer, the 5% weight loss temperature measured by increasing the temperature of the polyimide film to 100° C. at a rate of temperature increase of 10° C./min in a nitrogen atmosphere, subsequently heating the polyimide film at 100° C. for 60 minutes, subsequently leaving the polyimide film to cool for 15 minutes or longer in a nitrogen atmosphere, and then measuring the 5% weight loss temperature at a rate of temperature increase of 10° C./min, on the basis of the weight after cooling, is 450° C. or higher.

The 5% weight loss temperature of the low-outgassing photosensitive polyimide resin composition used in the present embodiment, that is, the 5% weight loss temperature of the polyimide film containing a polyimide resin that is obtained by curing of the low-outgassing photosensitive polyimide resin composition, is not particularly limited as long as the temperature is 450° C. or higher. However, the 5% weight loss temperature is preferably 480° C. or higher, and above all, more preferably 500° C. or higher. It is because when the 5% weight loss temperature is in the range described above, a polyimide insulating layer having a small weight loss in a high temperature atmosphere or a vacuum atmosphere when the semiconductor layer or other members are formed, that is, a polyimide insulating layer having less outgassing can be obtained, and thus a TFT substrate having excellent switching characteristics can be obtained.

Furthermore, the outgassed components that are contained in the low-outgassing photosensitive polyimide insulating layer formed by using such a low-outgassing photosensitive polyimide resin composition usually do not increase in the amount under the general TFT production conditions or in a general TFT use environment. Therefore, the 5% weight loss temperature of the low-outgassing photosensitive polyimide insulating layer is equivalent to the 5% weight loss temperature of the low-outgassing photosensitive polyimide resin composition.

Such a low-outgassing photosensitive polyimide resin composition is not particularly limited as long as resin composition can satisfy the characteristics described above. For example, the low-outgassing photosensitive polyimide resin composition may be a composition containing (a) a polyimide component, (b) a photosensitive component, (c) a solvent, and (d) others, and the 5% weight loss temperature can be controlled by appropriately selecting the structures of these various components. For example, control of the 5% weight loss temperature can be realized by reducing the outgassing originating from the various components.

Meanwhile, regarding the polyimide component, photosensitive component, solvent and other components used in the present embodiment, the same matters as those described in the section “(i) Photosensitive polyimide resin composition” of “(a) Photosensitive polyimide insulating layer” of “1. TFT” of “I. First embodiment” can be applied, and therefore, further explanations will not be repeated here.

(ii) Low-Outgassing Photosensitive Polyimide Insulating Layer

The low-outgassing photosensitive polyimide insulating layer used in the present embodiment is formed by using the low-outgassing photosensitive polyimide resin composition described above.

The low-outgassing photosensitive polyimide insulating layer according to the present embodiment may be at least one semiconductor layer-adjoining insulating layer, and as illustrated in FIG. 1 to FIG. 3 previously described, the low-outgassing photosensitive polyimide insulating layer is used as a gate insulating layer in a top-gate type TFT, or as a gate insulating layer and a passivation layer in a bottom-gate type TFT.

In the present embodiment, regarding the layers that are preferably low-outgassing photosensitive polyimide insulating layers among such semiconductor layer-adjoining insulating layers, the same as the photosensitive polyimide insulating layers described in the section “(ii) Photosensitive polyimide insulating layer” of “(a) Photosensitive polyimide insulating layer” of “1. TFT” of “I. First embodiment” can be applied.

Furthermore, it is preferable that the low-outgassing photosensitive polyimide insulating layer according to the present embodiment be used as, among the semiconductor layer-adjoining insulating layers, at least the semiconductor layer-adjoining insulating layer on which the deposited type semiconductor layer is directly laminated, that is, the semiconductor layer-adjoining insulating layer that is formed prior to the deposited type semiconductor layer, on which the deposited type semiconductor layer is formed directly on the surface.

The deposited type semiconductor layer is formed by vapor deposition by which a vaporized semiconductor material is laminated, and if volatile components are present in the surroundings at the time of this vapor deposition, these volatile components are deposited together with the semiconductor material as the deposited type semiconductor layer. That is, when there are volatile components other than the semiconductor material at the time of vapor deposition, the volatile components are easily incorporated into the deposited type semiconductor layer as impurities.

Furthermore, when the semiconductor layer-adjoining insulating layers are formed by using a conventional photosensitive polyimide resin composition, these semiconductor layer-adjoining insulating layers generate outgassing when exposed to a high temperature, vacuum atmosphere. Furthermore, the concentration of such outgassing is higher in the vicinity of the surfaces of these semiconductor layer-adjoining insulating layers.

Therefore, in the case where the deposited type semiconductor layer is formed directly on the surface of a semiconductor layer-adjoining insulating layer, while the semiconductor layer-adjoining insulating layer is formed by using a conventional photosensitive polyimide resin composition, since the semiconductor layer-adjoining insulating layer is exposed to a high temperature, vacuum atmosphere, the semiconductor layer-adjoining insulating layer is particularly prone to generate outgassing. Also, since the concentration of outgassing is high in the vicinity of the surface of the semiconductor layer-adjoining insulating layer, when vapor deposition of the deposited semiconductor layer is carried out under such circumstances, there is a high possibility that the deposited semiconductor layer may be a semiconductor layer having a large amount of incorporated outgassing, that is, a large amount of impurities.

On the contrary, when the low-outgassing photosensitive polyimide insulating layer is used as the semiconductor layer-adjoining insulating layer, since less outgassing may occur even in a high temperature, vacuum atmosphere such as described above, the amount of outgassing incorporated into the deposited type semiconductor layer can be decreased. As a result, even in the case of the deposited type semiconductor layer, the layer can be made into a semiconductor layer having fewer impurities, and the effects of the present embodiment can be exhibited more effectively. Furthermore, the production can be carried out by a simple process.

In the present embodiment, the semiconductor layer-adjoining insulating layer on which the deposited type semiconductor layer is directly laminated varies depending on the method for producing the TFT, and there is a possibility that all of the insulating layers that are in contact with the semiconductor layer may be included.

For example, in the case where the TFT is of bottom-gate type and the TFT is produced by a method of laminating various members from the substrate side, the gate insulating layer illustrated in FIGS. 2A and 2B previously described becomes the semiconductor layer-adjoining insulating layer on which the deposited type semiconductor layer is directly laminated.

In regard to the volume resistivity of the low-outgassing photosensitive polyimide insulating layer according to the present invention, factors such as film thickness, additives and insulating organic materials that can be included, imidization ratio of the polyimide resin included, method for forming the insulating layer, method for imidizing the insulating layer, and the timing for conducting imidization, the same matters as those described in the section “(ii) Photosensitive polyimide insulating layer” of “(a) Photosensitive polyimide insulating layer” of “1. TFT” of “I. First embodiment” can be applied.

(b) Semiconductor Layer-Adjoining Insulating Layer

The semiconductor layer-adjoining insulating layer used in the present embodiment may be such that at least one is the low-outgassing photosensitive polyimide insulating layer.

In the present embodiment, the other semiconductor layer-adjoining insulating layers may be insulating layers other than the low-outgassing photosensitive polyimide insulating layer.

Regarding these other insulating layers, the same matters as those described in the section of “(b) Semiconductor layer-adjoining insulating layer” of “(1) Semiconductor layer-adjoining insulating layer” of “1. TFT” of “I. First embodiment” can be applied.

(2) Semiconductor Layer

The semiconductor layer used in the present embodiment is not particularly limited as long as the semiconductor layer can be formed on the substrate described above, and for example, semiconductor layers formed from silicon, oxide semiconductors, and organic semiconductors are used.

Examples of the silicon that can be used include polysilicon and amorphous silicon.

Regarding the oxide semiconductor, the same matters as those described in the section of “(2) Oxide semiconductor layer” of “1. TFT” of “I. First embodiment” can be applied.

In the present embodiment, above all, it is preferable that the semiconductor layer be a deposited type semiconductor layer formed by a vapor deposition method.

Furthermore, in the present embodiment, it is particularly preferable that the semiconductor layer be an oxide semiconductor layer. It is because since the oxide semiconductor has excellent semiconductor characteristics among the semiconductor materials described above, when the oxide semiconductor is produced into the oxide semiconductor layer, an oxide semiconductor layer having excellent semiconductor characteristics can be obtained.

Furthermore, since the oxide semiconductor layer has a high curing temperature, the oxide semiconductor layer tends to be susceptible to the influence of outgassing. However, when the semiconductor layer-adjoining insulating layer is produced as the low-outgassing photosensitive polyimide insulating layer, the oxide semiconductor layer can be produced as a layer that is less affected by outgassing, the effect of the present embodiment can be more effectively exhibited.

Meanwhile, specific examples of the deposited type semiconductor layer include layers formed from silicon and oxide semiconductors described above.

Regarding the forming method and the thickness of the semiconductor layer used in the present embodiment, a forming method and a thickness that are generally used can be employed.

(3) TFT

The structure of the TFT used in the present embodiment is not particularly limited as long as the TFT includes the semiconductor layer and the semiconductor layer-adjoining insulating layer described above, and the same matters as those described in the section “(3) TFT” of “1. TFT” of “I. First embodiment” can be applied.

2. TFT Substrate

The TFT substrate of the present embodiment includes at least the TFT and the substrate described above, but if necessary, the TFT substrate may also include other members.

Furthermore, regarding the production method and the use of the TFT substrate, the same matters as those described in the section “3. TFT substrate” of “I. First embodiment” can be applied.

### III. Third Embodiment

The TFT substrate of the present embodiment comprises: the substrate described above; and a TFT having a semiconductor layer formed on the substrate, and a semiconductor layer-adjoining insulating layer formed to be in contact with the semiconductor layer, wherein at least one semiconductor layer-adjoining insulating layer is a non-photosensitive polyimide insulating layer formed from a non-photosensitive polyimide resin.

Regarding the TFT substrate of the present embodiment as such, specifically, the same TFT substrate as that illustrated in FIG. 1 to FIG. 3 previously described can be employed.

According to the present embodiment, by employing a non-photosensitive polyimide insulating layer formed from the non-photosensitive polyimide resin, the non-photosensitive polyimide insulating layer can be made into an insulating layer that does not contain a photosensitive component, which is a main cause of outgassing in a high temperature atmosphere or in a vacuum atmosphere when the oxide semiconductor layer or the like is formed, and thus an insulating layer generating less outgassed components can be obtained. As a result, the semiconductor layer can be made into a semiconductor layer with fewer impurities originating from the semiconductor layer-adjoining insulating layer, and a semiconductor layer having excellent switching characteristics can be obtained.

Furthermore, when the non-photosensitive polyimide insulating layer is formed from the non-photosensitive polyimide resin described above, since the non-photosensitive polyimide insulating layer can be formed without carrying out a vapor deposition process by using a vacuum facility that is required in the formation of insulating layers formed from inorganic compounds, and therefore, the production can be achieved by a simple process. Also, as a result, further cost reduction can be attempted.

Furthermore, since the non-photosensitive polyimide insulating layer is formed from the non-photosensitive polyimide resin, an insulating layer having excellent heat resistance can be obtained. Therefore, even in the case where the insulating layer is exposed to a high temperature atmosphere at the time of production of the semiconductor layer and other members, an insulating layer having a smaller decrease in the insulating performance can be obtained, and thus an insulating layer having excellent switching characteristics can be obtained. Furthermore, since the non-photosensitive polyimide insulating layer is made of a resin, for example, even in the case of producing a flexible TFT substrate by using a flexible substrate as the substrate, a non-photosensitive polyimide insulating layer which does not easily have cracks can be obtained.

Meanwhile, outgassing according to the present embodiment means that decomposition products of the polyimide resin, or decomposition residues of the photosensitive component are generated under high temperature conditions or high vacuum conditions, and these residues do not contain moisture (water vapor) or residual solvent, which can be easily removed by drying and heating at 100° C. for about 60 minutes.

The TFT substrate of the present embodiment includes at least a substrate and a TFT.

Hereinafter, the various constitutions of the TFT substrate of the present embodiment will be described in detail.

1. TFT

The TFT used in the present embodiment includes at least the semiconductor layer and semiconductor layer-adjoining insulating layer described above.

(1) Semiconductor Layer-Adjoining Insulating Layer

The semiconductor layer-adjoining insulating layer used in the present embodiment is formed so as to be in contact with the semiconductor layer, and at least one is the non-photosensitive polyimide insulating layer.

(a) Non-Photosensitive Polyimide Insulating Layer

The non-photosensitive polyimide insulating layer used in the present embodiment is formed from a non-photosensitive polyimide resin.

(i) Non-Photosensitive Polyimide Resin

The non-photosensitive polyimide resin used in the present embodiment includes at least a polyimide resin.

Here, the non-photosensitive material means a material which is not capable of forming a pattern under the action of light only by the material itself, and means a material in which unnecessary areas are removed by a liquid, a gas or plasma through the openings provided by a mask formed by a metal or a resist, or a pattern needs to be formed according to a technique of applying the material in advance into a pattern form by an inkjet method or a screen printing method, for example.

More generally, the non-photosensitive material means a material which forms a pattern while the material does not substantially contain a photosensitive component. In the present embodiment, since the semiconductor layer-adjoining insulating layer is formed from a non-photosensitive polyimide resin which is a non-photosensitive material, a purer material which does not contain a photosensitive component can be applied, and there is an advantage that a wide range of materials can be selected. Thus, a material combining characteristics such as low-outgassing properties, low hygroscopic expansion and low linear thermal expansion that are required in the present embodiment can be applied.

The 5% weight loss temperature of the non-photosensitive polyimide resin used in the present embodiment, that is, the 5% weight loss temperature of the non-photosensitive polyimide insulating layer, is not particularly limited as long as an intended amount of outgassing can be obtained. However, the 5% weight loss temperature is preferably 470° C. or higher, and above all, more preferably 490° C. or higher. It is because when the 5% weight loss temperature is in the range described above, a polyimide insulating layer having a small weight loss in a high temperature atmosphere or in a vacuum atmosphere when the semiconductor layer or other members are formed, that is, a polyimide insulating layer having less outgassing can be obtained, and thus a TFT substrate having excellent switching characteristics can be obtained. Particularly, since an inorganic semiconductor layer such as an oxide semiconductor layer as the semiconductor layer is usually formed in a high temperature, vacuum atmosphere, in the case of forming the oxide semiconductor layer in an environment where a large amount of outgassing can occur, there is a high possibility that the outgassed components may be incorporated into the semiconductor layer as impurities. On the contrary, when the non-photosensitive polyimide insulating layer is formed from a non-photosensitive polyimide resin having the 5% weight loss temperature described above, even in a high temperature, vacuum atmosphere, since less outgassing occurs from the non-photosensitive polyimide insulating layers, the oxide semiconductor layer and the like can be made into layers having fewer impurities. Furthermore, by including such a non-photosensitive polyimide insulating layer as in the case of the TFT substrate of the present embodiment, even if used in a high temperature environment, a polyimide insulating layer causing less inconveniences due to outgassing can be obtained.

Here, a non-photosensitive polyimide resin having a 5% weight loss temperature of 470° C. or higher means that on the occasion of measuring the weight loss by using a thermogravimetric analyzer, the 5% weight loss temperature measured by increasing the temperature of the polyimide film to 100° C. at a rate of temperature increase of 10° C./min in a nitrogen atmosphere, subsequently heating the polyimide film at 100° C. for 60 minutes, subsequently leaving the polyimide film to cool for 15 minutes or longer in a nitrogen atmosphere, and then measuring the 5% weight loss temperature at a rate of temperature increase of 10° C./min, on the basis of the weight after cooling is 470° C. or higher.

The polyimide resin used in the present embodiment is not particularly limited as long as desired insulating properties and low-outgassing properties can be imparted to the non-photosensitive polyimide insulating layer, but specifically, a compound having a structure represented by the following formula (x) can be used:

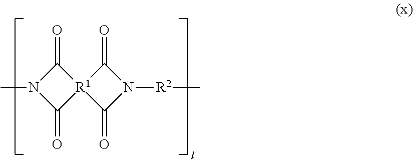

in the formula (x), R¹ represents a tetravalent organic group; R² represents a divalent organic group; repeating R¹'s and R²'s may be respectively identical with or different from each other; and “1” represents a natural number of 1 or greater.

In the formula (x), generally, R¹ represents a structure derived from tetracarboxylic acid dianhydride, and R² represents a structure derived from diamine.

Regarding the tetracarboxylic acid dianhydride and diamine components that can be applied to the polyimide resin in the present embodiment, the same matters as those described in the section “(a) Photosensitive polyimide insulating layer” of “(1) Semiconductor layer-adjoining insulating layers” of “1. TFT” of “I. First embodiment” can be applied, and therefore, further explanations will not be repeated here.

The weight average molecular weight of the polyimide resin used in the present embodiment may vary with the use, but the weight average molecular weight is preferably in the range of 3,000 to 1,000,000, more preferably in the range of 5,000 to 500,000, and even more preferably in the range of 10,000 to 500,000. It is because if the weight average molecular weight is less than 3,000, sufficient strength may not be easily obtained. On the other hand, it is because if the weight average molecular weight is greater than 1,000,000, the viscosity increases, solubility decreases, and thus a coating film or a film having a smooth surface and a uniform thickness may not be easily obtained.

The molecular weight as used herein means the value measured by gel permeation chromatography (GPO) and calculated relative to polystyrene standards.

The polyimide resin used in the present embodiment is included in the non-photosensitive polyimide insulating layer as a main component.

Here, being included as a main component is not particularly limited as long as the amount of outgassing can be adjusted in a desired range, and excellent switching characteristics can be obtained. However, specifically, the polyimide resin is included in the non-photosensitive polyimide resin, that is, in the non-photosensitive polyimide insulating layer, in an amount of 80% by mass or greater, and above all, the polyimide resin is preferably contained in an amount of 90% by mass or greater, and particularly preferable 95% by mass or greater. It is because when the content is in the range described above, the non-photosensitive polyimide insulating layer can be made into an insulating layer having less outgassing.

The imidization ratio of the polyimide resin contained in the non-photosensitive polyimide insulating layer used in the present embodiment is not particularly limited as long as desired characteristics such as insulating properties, heat resistance, and low-outgassing properties can be exhibited. However, specifically, the imidization ratio is preferably 90% or higher, and above all, the imidization ratio is preferably 95% or higher, and particularly preferably 100%, that is, it is preferable that the polyimide resin do not contain polyamic acid which is a polyimide precursor. It is because when the imidization ratio is in the range described above, a TFT substrate having especially excellent heat resistance and low-outgassing properties can be obtained.

The non-photosensitive polyimide resin according to the present embodiment is a resin which includes at least the polyimide resin described above, but if necessary, the non-photosensitive polyimide resin may include other components.

Examples of such other components that may be included include a binder resin other than the polyimide resin described above, other additives, and a thermosetting resin.

In the present embodiment, various organic or inorganic, low molecular weight or polymeric compounds may be incorporated as the additives, in order to impart processing characteristics and various functionalities to the non-photosensitive polyimide resin. Examples thereof that can be used include a dye, a surfactant, a leveling agent, a plasticizer, and fine particles. The fine particles include organic fine particles of polystyrene, polytetrafluoroethylene and the like; and inorganic fine particles of colloidal silica, carbon, lamellar silicates, and the like, and these may have a porous structure or a hollow structure. Furthermore, in view of function or shape, a pigment, a filler, a fiber and the like may also be used.

Furthermore, examples of the binder resin include insulating organic materials such as an acrylic resin, a phenolic resin, a fluororesin, an epoxy-based resin, a cardo-based resin, a vinyl-based resin, an imide-based resin, and a novolac-based resin.

Furthermore, the mixing proportion of the other components in the present embodiment is preferably in the range of 0.1% by weight to 20% by weight in the non-photosensitive polyimide resin, that is, in the non-photosensitive polyimide insulating layer. It is because if the mixing proportion is less than 0.1% by weight, it is difficult for the effect of adding the additives to be exhibited, and if the mixing proportion is greater than 20% by weight, the characteristics of the polyimide resin are not easily reflected on the final product.

The method for forming the non-photosensitive polyimide resin used in the present embodiment is not particularly limited as long as it is a method capable of including the polyimide resin. Specifically, a method of using a non-photosensitive polyimide resin composition containing at least a polyimide component and a solvent may be used.

The polyimide component used in the present embodiment means a component that forms the polyimide resin after curing in the non-photosensitive polyimide resin composition.

Such a polyimide component is not particularly limited as long as the component forms a desired polyimide resin, but in the case where the polyimide resin has a structure represented by the formula (x), specifically, polyimide having a structure represented by the above formula (1) and polyimide precursors having structures represented by the following formulas (2) and (3) can be used.

In the present embodiment, when the semiconductor layer is an oxide semiconductor layer, it is preferable that the polyimide component include at least the polyimide precursor described above. It is because in order to generate water at the time of the annealing treatment for imidization, the oxide semiconductor layer can be subjected to steam annealing simultaneously with the imidization, and the semiconductor characteristics can be enhanced. Furthermore, in regard to the proportions of the ring structures obtainable after imidization that are contained in the formula (1) and formula (3), since the ring structures have lower solubility in solvents than the carboxylic acid moieties before imidization that are contained in the formula (2) and formula (3), when the polyimide resin is dissolved in a solvent and used as a varnish at the time of application, it is preferable to use a polyimide precursor having high solubility, which contains a large proportion of the structure before imidization.

In the present embodiment, above all, the content of a carboxyl group (or an ester thereof) derived from acid anhydride is preferably 50% or greater, and more preferably 75% or greater, relative to the total amount, and it is preferable that the entire polyimide precursor be polyamic acid represented by the formula (2) (and) derivates thereof.

Furthermore, in regard to the polyamic acid represented by the formula (2) (and) derivatives thereof, it is particularly preferable that the polyamic acid be polyamic acid in which R³s are all hydrogen atoms, in view of the ease of synthesis and high solubility in an alkali developing liquid.

As the method for producing the polyimide component used in the present embodiment, a conventionally known technique can be applied. For example, examples of the method for forming a polyimide precursor having a structure represented by the formula (2) include, but are not limited to: (i) a technique of synthesizing a polyimide precursor from acid dianhydride and a diamine; and (ii) a technique of allowing a diamino compound or a derivative thereof to react with the carboxylic acid of ester acid or amide acid monomer that has been synthesized by a reaction between acid dianhydride and monohydric alcohol, an amino compound, an epoxy compound or the like.

Furthermore, the method for forming a polyimide precursor having a structure represented by the formula (3) or polyimide represented by the formula (1), a method of imidizing a polyimide precursor represented by the formula (2) by heating may be used.

As the weight average molecular weight of the polyimide component and the solvent used in the present embodiment, the same matters as those described in the section “(i) Photosensitive polyimide resin composition” of “(a) Photosensitive polyimide insulating layer” of “(1) Semiconductor layer-adjoining insulating layer” of “1. TFT” of “I. First embodiment” can be applied, and thus further explanation will not be repeated here.

The non-photosensitive polyimide resin composition used in the present embodiment includes at least the polyimide component and a solvent, but if necessary, the resin composition may also include other components.

Examples of such other components include a binder resin, additives, and a thermosetting resin, as described above.

(ii) Non-Photosensitive Polyimide Insulating Layer

The non-photosensitive polyimide insulating layer used in the present embodiment is formed from the non-photosensitive polyimide resin described above, and has less outgassing.

The non-photosensitive polyimide insulating layer according to the present embodiment may be at least one semiconductor layer-adjoining insulating layer, and as illustrated in FIG. 1 to FIG. 3 previously described, the non-photosensitive polyimide insulating layer is used as a gate insulating layer in a top-gate type TFT, or a gate insulating layer and a passivation layer in a bottom-gate type TFT.

In the present embodiment, regarding preferred examples of the non-photosensitive polyimide insulating layer among such semiconductor layer-adjoining insulating layers, the same matters as those described in the section “(a) Photosensitive polyimide insulating layer” of “(1) Semiconductor layer-adjoining insulating layers” of “1. TFT” of “I. First embodiment” can be applied.

In regard to the volume resistivity and film thickness of the non-photosensitive polyimide insulating layer according to the present embodiment, the same matters as those described in the section “(a) Photosensitive polyimide insulating layer” of “(1) Semiconductor layer-adjoining insulating layers” of “1. TFT” of “I. First embodiment” can be applied.

Furthermore, regarding the method for forming the non-photosensitive polyimide insulating layer according to the present embodiment, the method is not limited as long as it is a method capable of including the non-photosensitive polyimide resin, and specifically, the method described in the section “B. Method for producing TFT substrate” that will be described below can be used.

(b) Semiconductor Layer-Adjoining Insulating Layer

The semiconductor layer-adjoining insulating layer used in the present embodiment is preferably such that at least one is the non-photosensitive polyimide insulating layer described above.

In the present embodiment, the other semiconductor layer-adjoining insulating layers may be insulating layers other than the non-photosensitive polyimide insulating layer, but it is preferable that all of them be the non-photosensitive polyimide insulating layers.

Furthermore, regarding the other insulating layers according to the present embodiment, the same matters as those described in the section “(b) Semiconductor layer-adjoining insulating layer” of “(1) Semiconductor layer-adjoining insulating layer” of “1. TFT” of “I. First embodiment” can be applied.

(2) Semiconductor Layer

The semiconductor layer used in the present embodiment is not particularly limited as long as the semiconductor layer can be formed on the substrate described above, and for example, layer formed from silicon, oxide semiconductors and organic semiconductors can be used. Specifically, the same matters as those described in the section “II. Second embodiment” can be applied.

(3) TFT

The structure of the TFT used in the present embodiment is not particularly limited as long as the TFT has the semiconductor layer and the semiconductor layer-adjoining insulating layer described above, and the same matters as those described in “(3) TFT” of “1. TFT” of “I. First embodiment” can be applied.

The non-semiconductor layer-adjoining insulating layer according to the present embodiment is not particularly limited as long as the non-semiconductor layer-adjoining insulating layer has desired insulating properties, and the layer containing the materials described in the section “(1) Semiconductor layer-adjoining insulating layer” can be used.

In the present embodiment, above all, it is preferable that the non-semiconductor layer-adjoining insulating layer be formed from the non-photosensitive polyimide resin described above. It is because a layer having excellent switching characteristics can be obtained.

2. Substrate

The substrate used in the present embodiment is not particularly limited as long as it is a substrate capable of supporting the TFT, and for example, a non-flexible substrate, or a flexible substrate having flexibility can be used.

In regard to the flexible substrate, the same matters as those described in the section “2. Substrate” of “I. First embodiment” can be applied, and further explanation will not be repeated here.

The planarizing layer according to the present embodiment is a layer which is formed on a metal foil and contains a polyimide, and is a layer provided so as to planarize the surface unevenness of the metal foil.

Regarding the surface roughness Ra of the planarizing layer, the coefficient of hygroscopic expansion, the coefficient of linear thermal expansion, and the insulating properties, the same matters as those described in the section “2. Substrate” of the “I. First embodiment” can be applied.

Since the polyimide is required to exhibit low hygroscopic expansion and low linear thermal expansion, it is preferable that the polyimide have a repeating unit represented by the formula (21).

Furthermore, in regard to such polyimide, the same matters as those described in the section “2. Substrate” of “I. First embodiment” can be applied, and thus further explanation will not be repeated here.

Also, the polyimide having a repeating unit represented by the formula (21) may be polyimide obtained by using a photosensitive polyimide or polyimide precursor, but it is preferable that the polyimide be obtainable by using a non-photosensitive polyimide or polyimide precursor. It is because the polyimide can be made to have less outgassing, and polyimide having excellent switching characteristics can be obtained.

Meanwhile, the non-photosensitive polyimide and polyimide precursor are not particularly limited as long as they are capable of forming the polyimide described above. Specifically, the same non-photosensitive polyimide resin composition and the like as those described in the section “1. TFT” can be used.

Regarding the site of formation of the planarizing layer on the metal foil, and the thickness, the same matters as described in the section “2. Substrate” of “I. First embodiment” can be applied.

Furthermore, in regard to the forming method, the same matters as those described in the section “2. Substrate” of “I. First embodiment” can be applied, but in the present embodiment, above all, a method of applying a non-photosensitive polyimide solution or polyimide precursor solution is preferred. As discussed in the above, it is because the planarizing layer can be made into a layer which does not contain a photosensitive component that is a main cause of outgassing, and a planarizing layer having less outgassing can be obtained. Also, it is because as a result, a planarizing layer having excellent switching characteristics can be obtained.

In regard to the method of application or the method of forming the planarizing layer partially on a metal foil, the methods described in the section “B. Method for producing TFT substrate” that will be described below, or a method of producing a laminate of a metal foil, a planarizing layer and a metal foil, patterning one of the metal foils of the laminate, etching the planarizing layer by using the pattern as a mask, and then removing the metal pattern may be used.

3. TFT Substrate

The TFT substrate of the present embodiment includes at least the TFT described above a substrate; however, if necessary, the TFT substrate may also include other members.

Furthermore, in regard to the production method and use of the TFT substrate, the same matters as those described in the section “3. TFT substrate” of “I. First embodiment” can be applied.

B. Method for Producing TFT Substrate

Next, the method for producing a TFT substrate of the present invention will be explained.

The method for producing a TFT substrate of the present invention is a method for producing a TFT substrate which comprises: a substrate, and a TFT having an oxide semiconductor layer formed on the substrate and a semiconductor layer-adjoining insulating layer formed to be in contact with the oxide semiconductor layer, in which at least one semiconductor layer-adjoining insulating layer is a non-photosensitive polyimide insulating layer formed from a non-photosensitive polyimide resin. The production method can be divided into two embodiments on the basis of the difference in the object of patterning.

Hereinafter, the method for producing a TFT substrate of the present invention will be described separately in a first embodiment and a second embodiment.

### 1. First Embodiment

The first embodiment of the method for producing a TFT substrate of the present invention will be described. The method for producing a TFT substrate of the present embodiment is a production method described above, and the method comprises steps of: a non-photosensitive polyimide film forming step of forming a non-photosensitive polyimide film formed from a non-photosensitive polyimide resin on a substrate; and a non-photosensitive polyimide film patterning step of patterning the non-photosensitive polyimide film and forming the non-photosensitive polyimide insulating layer.

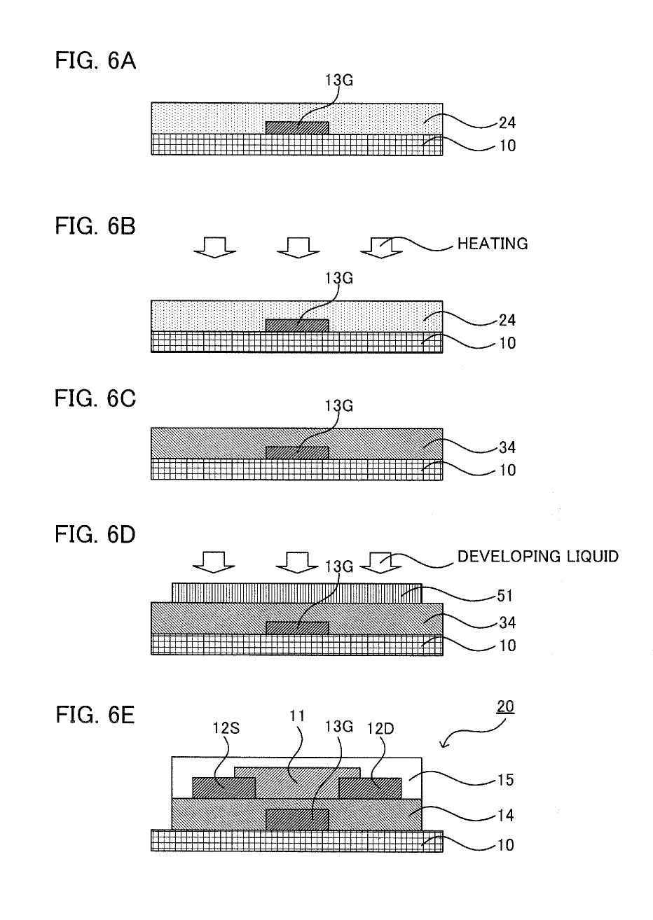

The method for producing a TFT substrate of the present embodiment as such will be explained with reference to the drawings. FIGS. 6A to 6E is a process diagram illustrating an example of the TFT substrate of the present embodiment. As illustrated in FIGS. 6A to 6E, the method for producing a TFT substrate of the present embodiment comprises steps of: a non-photosensitive polyimide film forming step of forming a non-photosensitive polyimide precursor film forming a non-photosensitive polyimide precursor film 24 (FIG. 6A) by applying a non-photosensitive polyimide resin composition containing a polyimide precursor on a substrate 10 and drying the resin composition, subsequently heating the non-photosensitive polyimide precursor film 24 to imidize the polyimide precursor (FIG. 6B), and thereby forming a non-photosensitive polyimide film 34 formed of a non-photosensitive polyimide resin (FIG. 6C); and a non-photosensitive polyimide film patterning step of forming a resist pattern 51 on the non-photosensitive polyimide film 34, developing the non-photosensitive polyimide film to thereby perform patterning of the non-photosensitive polyimide film 34, and thus forming a non-photosensitive polyimide insulating layer (gate insulating layer) (FIG. 6D). Thereafter, a source electrode 12S, a drain electrode 12D and an oxide semiconductor layer 11 are formed on the non-photosensitive polyimide insulating layer (gate insulating layer) 14, and a passivation layer 15 formed of the non-photosensitive polyimide resin is formed in the same manner as in the case of the gate insulating layer, on the source electrode 12S, drain electrode 12D and oxide semiconductor layer 11. Thereby, a TFT substrate 20 is formed.

According to the present embodiment, by having the non-photosensitive polyimide film patterning step, that is, by patterning an imidized non-photosensitive polyimide film, the members at a site that is covered by the non-photosensitive polyimide insulating layer can be made unsusceptible to be affected by the developing process. Therefore, a TFT with high reliability can be obtained.

The method for producing a TFT substrate of the present embodiment comprises at least a non-photosensitive polyimide film forming step and a non-photosensitive polyimide film patterning step.

Hereinafter, the respective steps of the method for producing a TFT substrate of the present embodiment will be described in detail.

(1) Non-Photosensitive Polyimide Film Forming Step

The non-photosensitive polyimide film forming step according to the present embodiment is a step of forming a non-photosensitive polyimide film formed from a non-photosensitive polyimide resin on the substrate described above.

The non-photosensitive polyimide film according to the present step is formed from the non-photosensitive polyimide resin described above, that is, contains an imidized polyimide resin.

The imidization ratio of the polyimide resin according to the present step is not particularly limited as long as intended characteristics such as insulating properties and heat resistance can be imparted to the non-photosensitive polyimide insulating layer by the imidization ratio. Specifically, the same matters as those described in the section “(a) Non-photosensitive polyimide insulating layer” of “(1) Semiconductor layer-adjoining insulating layer” of “1. TFT” of “III. Third embodiment” of “A. TFT substrate” can be applied.

Such a method for forming a non-photosensitive polyimide film is not particularly limited as long as it is a method capable of forming the film from the non-photosensitive polyimide resin described above, and for example, a method of applying a non-photosensitive polyimide resin composition containing polyimide as the polyimide component, and drying the resin composition; or a method of applying a non-photosensitive polyimide resin composition containing a polyimide precursor as the polyimide component, drying the resin composition, and imidizing the polyimide precursor may be used. Furthermore, a method of bonding a polyimide film formed from a non-photosensitive polyimide resin containing the polyimide resin may also be used.

As the coating method according to the present step, a spin coating method, a die coating method, a dip coating method, a bar coating method, a gravure printing method, or a screen printing method can be used.

Furthermore, the drying method is not particularly limited as long as it is a method capable of adjusting the content of the solvent that is contained in the coating film formed from the non-photosensitive polyimide resin composition to an intended amount or less, and for example, a method of drying the non-photosensitive polyimide resin composition by heating may be used. Furthermore, as the heating method, known apparatuses and techniques such as an oven and a hot plate can be used. The heating temperature is preferably in the range of 80° C. to 140° C.

In regard to the present step, the method for imidizing the polyimide precursor is not particularly limited as long as a polyimide resin having an intended imidization ratio can be obtained, but usually, a method of using an annealing treatment (heating treatment) is used.

Such an annealing temperature (heating temperature) is appropriately selected while taking into consideration of factors such as the type of the polyimide precursor used, the heat resistance of the members constituting the TFT substrate of the present invention, and the like. However, the annealing treatment is usually carried out in the range of 200° C. to 500° C., and above all, the annealing treatment is preferably carried out in the range of 250° C. to 400° C. Particularly, from the viewpoints of the properties after curing of the polyimide precursor and the low outgassing properties, the annealing temperature is preferably in the range of 280° C. to 400° C. It is because when the annealing temperature is in the temperature range described above, imidization can be sufficiently achieved, and thermal deterioration of other members can be suppressed.

Regarding the heating retention time in the annealing treatment, it is necessary to appropriately set the heating retention time depending on the heating temperature or the heating technique, but the heating retention time can be set to 1 minute to 300 minutes.

Furthermore, in the case where the substrate contains a metal that is susceptible to oxidation, it is preferable that the annealing treatment be carried out in an inert atmosphere, from the viewpoint of preventing metal oxidation. Specific examples of the inert atmosphere in this case include under reduced pressure in nitrogen atmosphere, and in an atmosphere of a noble gas such as argon or helium.

Meanwhile, regarding the non-photosensitive polyimide resin and the non-photosensitive polyimide resin composition, the same matters as those described in the section “(1) Semiconductor layer-adjoining insulating layer” of “1. TFT” of “III. Third embodiment” of “A. TFT substrate” can be applied.

Furthermore, in the present invention, in the non-photosensitive polyimide film patterning step that will be described below, it is preferable to use a non-photosensitive polyimide resin and a non-photosensitive polyimide resin composition that use pyromellitic dianhydride as the acid dianhydride when patterning is performed by using a strong alkali reagent liquid. Among the acid dianhydrides used, the content of pyromellitic dianhydride is preferably 50% or greater, and more preferably 75% or greater.

(2) Non-Photosensitive Polyimide Film Patterning Step

The non-photosensitive polyimide film patterning step according to the present embodiment is a step of patterning the non-photosensitive polyimide film, and forming the non-photosensitive polyimide insulating layer.

In the present step, the method of patterning the non-photosensitive polyimide film is not particularly limited as long as it is a method of forming a non-photosensitive polyimide film having an intended pattern, and known methods such as a printing method, a photolithographic method, and a method of directly processing with a laser or the like can be used.

In the present step, among others, a photolithographic method is preferred. It is because pattern formation can be carried out with high accuracy.

Regarding the photosensitive resin film pattern (resist pattern) used in the photolithographic method in the present step, any photosensitive resin film may be used as long as it can form a desired pattern, and the resin film may be formed from a negative type photosensitive resin (negative resist) or may be formed from a positive type photosensitive resin (positive resist). In the case of using a negative resist, since peeling of the resist pattern can be achieved by using an aqueous solution-based peeling liquid, explosion-proof facilities are unnecessary, and the adverse effect on the health of operators can be reduced. Furthermore, there is an advantage that the burden on the natural environment can be reduced. Furthermore, in the case of using a positive resist, there is an advantage that peeling can be achieved under relatively mild conditions by exposing the entire surface of the resist pattern.

As the resist pattern and the method for forming a resist pattern as such, those methods that are generally used in the patterning of polyimide resin films can be used, and for example, the methods described in JP 2008-076956 A and JP 2008-083181 A can be used.

In the present step, regarding the method of developing the non-photosensitive polyimide film by a photolithographic method, any method capable of removing a non-photosensitive polyimide film that is located at the openings of the photosensitive resin film pattern with high accuracy may be used, and for example, a method of performing development by using a strong alkali reagent liquid or plasma may be used. The method of using a reagent liquid is advantageous in that the etching rate is high, and productivity is excellent. Furthermore, the method of using plasma is advantageous in that the method is capable of coping with polyimides having a relatively wide range of compositions.

(3) Others

The method for producing a TFT substrate of the present embodiment includes at least the non-photosensitive polyimide film forming step and the non-photosensitive polyimide film patterning step, but if necessary, the production method may also include other steps.

Examples of such other steps include a semiconductor layer forming step of forming the semiconductor layer described above; a substrate forming step of forming the substrate described above; and an electrode forming step of forming electrodes that the TFT substrate described above conventionally has, such as a source electrode, a drain electrode, and a gate electrode. As the methods for forming various members that are included in the TFT substrate in such other steps, those methods that are conventionally used for the formation of the TFT substrate can be used.

Also, when the non-photosensitive polyimide film patterning step involves patterning by a photolithographic method, the production method usually includes a peeling step of peeling the resist pattern, after the non-photosensitive polyimide film patterning step. Furthermore, when a positive resist is used in the photolithographic method, the production method usually includes an entire surface exposure step of exposing the entire surface of the resist pattern, before the peeling step. In regard to the method for peeling a resist pattern in such a peeling step, or the method for exposing the entire surface of the resist pattern in the entire surface exposure method, those methods that are generally used in the patterning of polyimide film can be used, and for example, the methods described in JP 2008-076956 A and JP 2008-083181 A can be used.

### 2. Second Embodiment

A second embodiment of the method for producing a TFT substrate of the present invention will be described. The method for producing a TFT substrate of the present embodiment is a production method such as described above, and comprises steps of: a non-photosensitive polyimide precursor film forming step of forming a non-photosensitive polyimide precursor film containing a polyimide precursor on the substrate described above; a non-photosensitive polyimide precursor pattern forming step of patterning the non-photosensitive polyimide precursor film and forming the non-photosensitive polyimide precursor pattern; and an imidization step of imidizing the polyimide precursor contained in the non-photosensitive polyimide precursor pattern and forming the non-photosensitive polyimide insulating layer.

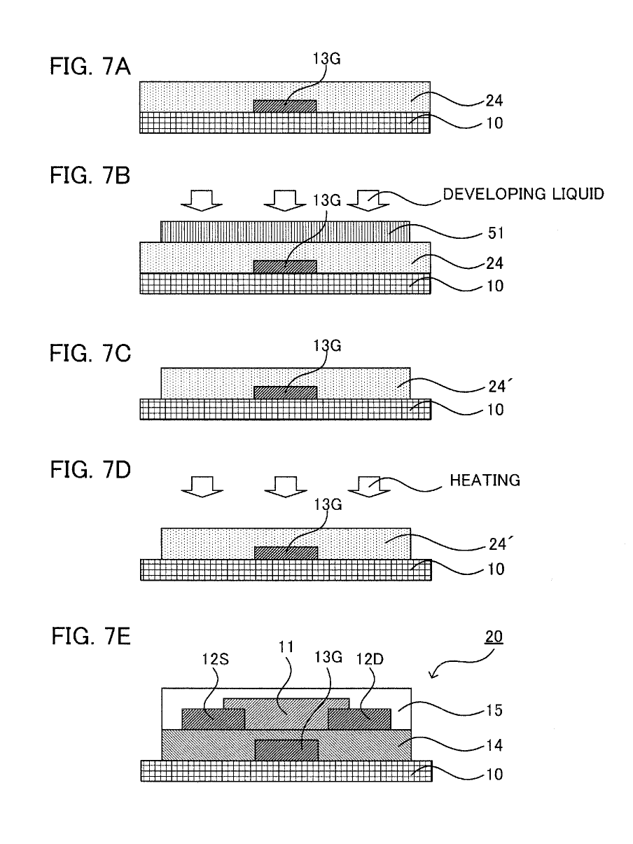

The method for producing a TFT substrate of the present embodiment as such will be described with reference to the drawings. FIGS. 7A to 7E are a process diagram illustrating an example of the TFT substrate of the present embodiment. As illustrated in FIGS. 7A to 7E, the method for producing a TFT substrate of the present invention comprises steps of: a non-photosensitive polyimide precursor film forming step of forming a non-photosensitive polyimide precursor film 24 containing a polyimide precursor on the substrate 10 described above (FIG. 7A); a non-photosensitive polyimide precursor pattern forming step of forming a resist pattern 51 on the non-photosensitive polyimide precursor film 24, performing development, thereby patterning the non-photosensitive polyimide precursor film 24 (FIG. 7B), and forming the non-photosensitive polyimide precursor pattern 24′ (FIG. 7C); and an imidization step of imidizing the polyimide precursor contained in the non-photosensitive polyimide precursor pattern 24′ by heating, and forming a non-photosensitive polyimide insulating layer (gate insulating layer) formed from the non-photosensitive polyimide resin (FIG. 7D). Thereafter, a source electrode 12S, a drain electrode 12D and an oxide semiconductor layer 11 are formed on the non-photosensitive polyimide insulating layer (gate insulating layer) 14, and a passivation layer 15 formed from the non-photosensitive polyimide resin is formed on the source electrode 12S, the drain electrode 12D and the oxide semiconductor layer 11, in the same manner as in the case of the gate insulating layer. Thereby, a TFT substrate 20 is formed.

According to the present embodiment, the non-photosensitive polyimide insulating layer can be formed with high pattern accuracy, and a TFT substrate having an excellent product quality can be obtained.

The method for producing a TFT substrate of the present embodiment comprises steps of: at least the non-photosensitive polyimide precursor film forming step, the non-photosensitive polyimide precursor pattern forming step, and the imidization step.

Hereinafter, the various steps of the method for producing a TFT substrate of the present embodiment will be described in detail.

(1) Non-Photosensitive Polyimide Precursor Film Forming Step

Non-photosensitive polyimide precursor film forming step according to the present embodiment is a step of forming a non-photosensitive polyimide precursor film containing a polyimide precursor on the substrate described above.

The method for forming a non-photosensitive polyimide precursor film in the present step is not particularly limited as long as it is a method capable of forming the non-photosensitive polyimide precursor film containing a polyimide precursor to an intended thickness; however, for example, a method of applying a non-photosensitive polyimide resin composition containing the polyimide precursor described above, and drying the resin composition may be used.

The content ratio of the polyimide precursor, that is, the content ratio of the carboxyl group (or an ester thereof) derived from an acid anhydride, contained in the solids content of the non-photosensitive polyimide precursor film in the present step is not particularly limited as long as desired coatability, developability and the like can be obtained. However, the content ratio of the polyimide precursor is preferably 50% or greater, more preferably 75% or greater, and even more preferably 100%. It is because excellent solubility of the polyimide component such as the polyimide precursor in a solvent can be obtained, and excellent coatability and the like can be obtained. Also, it is because steam annealing can be efficiently carried out for the oxide semiconductor layer.

In regard to the polyimide precursor, the non-photosensitive polyimide resin composition, the coating method and the drying method employed in the present step, the same matters as those described in the section “1. First embodiment” can be applied.

(2) Non-Photosensitive Polyimide Precursor Pattern Forming Step

Non-photosensitive polyimide precursor pattern forming step according to the present embodiment is a step of patterning the non-photosensitive polyimide precursor film and forming the non-photosensitive polyimide precursor pattern.

In the present step, the method for patterning the non-photosensitive polyimide precursor film, and the method for forming a resist pattern in the case of using a photolithographic method are not particularly limited as long as they are methods capable of forming a non-photosensitive polyimide precursor film having an intended pattern, and the methods described in the section “(2) Non-photosensitive polyimide film patterning step” of “1. First embodiment” can be used.

In the present step, the method for developing the non-photosensitive polyimide precursor film by a photolithographic method may be any method capable of removing, with high accuracy, the non-photosensitive polyimide precursor film that is located at the openings of the photosensitive resin film pattern. In the present step, since the polyimide precursor has carboxyl groups, a developing method using a basic aqueous solution can be used. Furthermore, since the polyimide precursor has superior solubility in organic solvents than a polyimide resin, a developing method using an organic solvent can also be used.

There are no particular limitations on the basic aqueous solution used in the present step, but examples thereof include an aqueous solution of tetramethylammonium hydroxide (TMAH) having a concentration of 0.01% by weight to 10% by weight, and preferably 0.05% by weight to 5% by weight, as well as aqueous solutions of diethanolamine, diethylaminoethanol, sodium hydroxide, potassium hydroxide, sodium carbonate, potassium carbonate, sodium hydrogen carbonate, potassium hydrogen carbonate, triethylamine, diethylamine, methylamine, dimethylamine, dimethylaminoethyl acetate, dimethylaminoethanol, dimethylaminoethyl methacrylate, cyclohexylamine, ethylenediamine, hexamethylenediamine, and tetramethylammonium.

One kind or two or more kinds of solutes may be used, and if water is contained in an amount of 50% or greater, and preferably 70% or greater, of the total weight of the solution, the solution may also include an organic solvent.

There are no particular limitations on the organic solvent, but examples thereof include polar solvents such as N-methyl-2-pyrrolidone, N,N-dimethylformamide, N,N-dimethylacetamide, dimethyl sulfoxide, γ-butyrolactone, and dimethylacrylamide; alcohols such as methanol, ethanol, and isopropanol; esters such as ethyl acetate, and propylene glycol monomethyl ether acetate; ketones such as cyclopentanone, cyclohexanone, isobutyl ketone, and methyl isobutyl ketone; tetrahydrofuran, chloroform, and acetonitrile. These may be used singly or in combination of two or more kinds. After development, washing is carried out with water or a poor solvent. In this case as well, alcohols such as ethanol and isopropyl alcohol; esters such as ethyl lactate and propylene glycol monomethyl ether acetate; and the like may be added to water.

Examples of the developing method include a spray method, a puddle method, a dipping method, and an oscillation immersion method.

In the present step, after the forming of the non-photosensitive polyimide precursor pattern and before the peeling of the resist pattern, partial imidization of imidizing a portion of the polyimide precursor contained in the non-photosensitive polyimide precursor pattern may be carried out.

Furthermore, in the present step, simultaneously with the forming of the resist pattern, that is, forming of the resist pattern by developing the photosensitive resin film (resist film), development of the non-photosensitive polyimide precursor film may be carried out.

(3) Imidization Step

The imidization step according to the present embodiment is a step of forming a non-photosensitive polyimide insulating layer formed from the non-photosensitive polyimide resin by imidizing the polyimide precursor that is contained in the non-photosensitive polyimide precursor pattern, that is, including the polyimide resin.

Regarding the imidization ratio of the polyimide resin contained in the non-photosensitive polyimide insulating layer formed in the present step, and the method for imidization in the present step, the same matters as those described in the section “1. First embodiment” can be applied, and further explanation will not be repeated here.

Furthermore, in regard to the timing for carrying out the present step, when the semiconductor layer is an oxide semiconductor layer, it is preferable that the present step is carried out subsequent to the forming of the oxide semiconductor layer. It is because when the present step is carried out after the oxide semiconductor layer is formed, the steam annealing treatment of the oxide semiconductor layer can be carried out simultaneously, and a TFT substrate having excellent switching characteristics can be conveniently obtained.

Therefore, when the oxide semiconductor layer is formed on the non-photosensitive polyimide insulating layer, it is preferable to carry out oxide semiconductor layer forming step of forming the oxide semiconductor layer after non-photosensitive polyimide precursor patterning step, and then to carry out the present step.

Meanwhile, when oxide semiconductor layer forming step is included between non-photosensitive polyimide precursor patterning step and the present step as described above, a partial imidization step of imidizing a portion of the polyimide precursor contained in the non-photosensitive polyimide precursor pattern may be included before the oxide semiconductor layer forming step.

(4) Others

The method for producing a TFT substrate of the present embodiment comprises at least the non-photosensitive polyimide precursor film forming step, the non-photosensitive polyimide precursor pattern forming step, and the imidization step, but if necessary, the production method may also include other steps.

Examples of such other steps include the processes described in the section “1. First embodiment” described above.

Meanwhile, the present invention is not intended to be limited to the embodiments described above. The above-described embodiments are only for illustrative purposes, and any embodiment which has substantially the same constitution as the technical idea described in the claims of the present invention and provides the same operating effect will be regarded to be included in the technical scope of the present invention.

### EXAMPLES

Hereinafter, the present invention will be described in detail by way of Examples and Comparative Examples.

### I. Examples of First Embodiment

### 1. Preparation of Polyimide Varnish (Polyimide Precursor Solution)

### Preparation Example 1

4.0 g (20 mmol) of 4,4′-diaminodiphenyl ether (ODA) and 8.65 g (80 mmol) of para-phenylenediamine (PPD) were introduced into a 500 ml separable flask and were dissolved in 200 g of dehydrated N-methyl-2-pyrrolidone (NMP). Under a nitrogen gas stream, the solution was heated and stirred in an oil bath such that the liquid temperature was monitored with a thermocouple to be increased to 50° C. After it was confirmed that the compounds were completely dissolved, 29.1 g (99 mmol) of 3,3′,4,4′-biphenyltetracarboxylic acid dianhydride (BPDA) was added thereto over 30 minutes in small portions, and after completion of the addition, the mixture was stirred for 5 hours at 50° C. Thereafter, the mixture was cooled to room temperature, and thus a polyimide precursor solution 1 was obtained.

### Preparation Example 2

Polyimide precursor solutions 2 to 17 were synthesized at the mixing ratios indicated in the following Table 1, by the same method as that used in Preparation Example 1, except that the reaction temperature was adjusted, and the amount of NMP was adjusted so that the concentration of the solution would be 17% by weight to 19% by weight.

As the acid dianhydride, 3,3′,4,4′-biphenyltetracarboxylic acid dianhydride (BPDA) or pyromellitic acid dianhydride (PMDA), p-phenylenebistrimellitic acid monoester acid dianhydride (TAHQ), or p-biphenylenebistrimellitic acid monoester acid dianhydride (BPTME) was used. As the diamine, one kind or two kinds of 4,4′-diaminodiphenyl ether (ODA), para-phenylenediamine (PPD), 1,4-bis(4-aminophenoxy)benzene (4APB), 2,2′-dimethyl-4,4′-diaminobiphenyl (TBHG), and 2,2′-bis(trifluoromethyl)-4,4-diaminobiphenyl (TFMB) were used.

TABLE 1

| | Acid dianhydride | | Diamine | | Diamine | | |
|---|---|---|---|---|---|---|---|
| | | Amount of | | Amount of | | Amount of | Reaction |
| | | addition | | addition | | addition | temperature |
| | Type | (mmol) | Type | (mmol) | Type | (mmol) | (° C.) |
| Polyimide precursor solution 1 | BPDA | 99 | PPD | 80 | ODA | 20 | 50 |
| Polyimide precursor solution 2 | BPDA | 99 | PPD | 100 | — | — | 50 |
| Polyimide precursor solution 3 | BPDA | 99 | — | — | ODA | 100 | 50 |
| Polyimide precursor solution 4 | BPDA | 99 | PPD | 80 | 4APB | 20 | 50 |
| Polyimide precursor solution 5 | BPDA | 99 | — | — | TBHG | 100 | 50 |
| Polyimide precursor solution 6 | BPDA | 99 | ODA | 80 | TBHG | 20 | 50 |
| Polyimide precursor solution 7 | BPDA | 99 | ODA | 75 | TBHG | 25 | 50 |
| Polyimide precursor solution 8 | BPDA | 99 | — | — | TFMB | 100 | 50 |
| Polyimide precursor solution 9 | BPDA | 99 | PPD | 80 | TFMB | 20 | 50 |
| Polyimide precursor solution 10 | BPDA | 99 | PPD | 70 | TFMB | 30 | 50 |
| Polyimide precursor solution 11 | BPDA | 99 | TBHG | 50 | TFMB | 50 | 50 |
| Polyimide precursor solution 12 | PMDA | 99 | — | — | TBHG | 100 | 0 |
| Polyimide precursor solution 13 | PMDA | 99 | — | — | ODA | 100 | 0 |
| Polyimide precursor solution 14 | PMDA | 99 | PPD | 50 | ODA | 50 | 0 |
| Polyimide precursor solution 15 | BPTME | 99 | — | — | ODA | 100 | 50 |
| Polyimide precursor solution 16 | TAHQ | 99 | — | — | ODA | 100 | 50 |
| Polyimide precursor solution 17 | TAHQ | 99 | PPD | 75 | ODA | 25 | 50 |

(Evaluation of Coefficient of Linear Thermal Expansion and Coefficient of Hygroscopic Expansion)

Each of the polyimide precursor solutions 1 to 17 was applied on a heat resistant film (Upilex S 50S™; manufactured by Ube Industries, Ltd.) bonded to a glass plate, and the precursor solution was dried on a hot plate at 80° C. for 10 minutes. The dried film was peeled from the heat resistant film, and thus a film having a thickness of 15 μm to 20 μm was obtained. Thereafter, the film was fixed to a frame made of a metal, and was heat treated at 350° C. for one hour (rate of temperature increase: 10° C./min, natural cooling) in a nitrogen atmosphere. Thus, films of the polyimide resins 1 to 17 having a thickness of 9 μm to 15 μm were obtained.

<Coefficient of Linear Thermal Expansion>

A film produced by the method described above was cut to a size of 5 mm in width×20 mm in length, and the cut film was used as an evaluation sample. The coefficient of linear thermal expansion was measured by using a thermomechanical analyzer, Thermo Plus TMA8310™ (manufactured by Rigaku Corporation). For the measurement conditions, the length of observation of the evaluation sample was set to 15 mm.

<Coefficient of Humidity Expansion>

A film produced by the method described above was cut to a size of 5 mm in width×20 mm in length, and the cut film was used as an evaluation sample. The coefficient of humidity expansion was measured by using a humidity variable mechanical analyzer, Thermo Plus TMA8310™ (manufactured by Rigaku Corporation).

(Evaluation of Substrate Warpage)

Polyimide films of the polyimide resins 1 to 17 were formed on a SUS304-HTA Foil™ (manufactured by Toyo Seihaku Co., Ltd.) having a thickness of 18 μm by using the polyimide precursor solutions 1 to 17, such that the thickness of the polyimide film after imidization would be 10 μm±1 μm, under the same process conditions as those used for the production of samples for the evaluation of the coefficient of linear thermal expansion. Subsequently, the laminates of the SUS304 foil and the polyimide film were each cut to a size of 10 mm in width×50 mm in length, and the cut laminates were used as samples for the evaluation of substrate warpage.

Each of these samples was fixed to the surface of a SUS plate by fixing only one of shorter edges of the sample by using a Capton tape, and the sample was heated in an oven at 100° C. for one hour. Subsequently, the distance between the opposite shorter edge of the sample and the SUS plate was measured in the oven heated to 100° C. A sample having a distance thus measured of from 0 mm to 0.5 mm was rated as ◯; a sample having a distance of greater than 0.5 mm and less than or equal to 1.0 mm was rated as Δ; and a sample having a distance of greater than 1.0 mm was rated as x.

In the same manner, this sample was fixed to the surface of a SUS plate by fixing only one of shorter edges of the sample by using a Capton tape, and the sample was left to stand for one hour in a constant temperature, constant humidity chamber at 23° C. and 85% RH. Subsequently, the distance between the opposite shorter edge of the sample and the SUS plate was measured. A sample having a distance thus measured of from 0 mm to 0.5 mm was rated as ◯; a sample having a distance of greater than 0.5 mm and less than or equal to 1.0 mm was rated as Δ; and a sample having a distance of greater than 1.0 mm was rated as x.

These evaluation results are presented in Table 2.

TABLE 2

| | CTE | CHE | Evaluation of | |
|---|---|---|---|---|
| | (ppm/ | (ppm/ | substrate warpage | |
| | ° C.) | Rh %) | 100° C. | 85% Rh |
| Polyimide precursor solution 1 | 18.9 | 8.4 | ∘ | ∘ |
| Polyimide precursor solution 2 | 10.9 | 8.5 | ∘ | ∘ |
| Polyimide precursor solution 3 | 43.9 | 21.8 | x | x |
| Polyimide precursor solution 4 | 19.3 | 10.9 | ∘ | ∘ |
| Polyimide precursor solution 5 | 4.6 | 5.1 | Δ | ∘ |
| Polyimide precursor solution 6 | 12.3 | 6.1 | ∘ | ∘ |
| Polyimide precursor solution 7 | 22.0 | 8.7 | ∘ | ∘ |
| Polyimide precursor solution 8 | 31.1 | 3.5 | x | ∘ |
| Polyimide precursor solution 9 | 11.4 | 5.9 | ∘ | ∘ |
| Polyimide precursor solution 10 | 15.4 | 3.4 | ∘ | ∘ |
| Polyimide precursor solution 11 | 10.8 | 6.7 | ∘ | ∘ |
| Polyimide precursor solution 12 | 14.2 | 3.8 | ∘ | ∘ |
| Polyimide precursor solution 13 | 35.2 | 20.4 | x | Δ |
| Polyimide precursor solution 14 | 17.2 | 21.6 | ∘ | x |
| Polyimide precursor solution 15 | 34.7 | 4.0 | x | ∘ |
| Polyimide precursor solution 16 | 37.7 | 6.5 | x | ∘ |
| Polyimide precursor solution 17 | 15.6 | 9.7 | ∘ | ∘ |

Since the coefficient of linear thermal expansion of the SUS304 foil was 17 ppm/° C., it was confirmed that if the difference in the coefficient of linear thermal expansion between the polyimide film and the metal foil was large, the warpage of the laminate was large.

Furthermore, from Table 2, it can be seen that as the coefficient of hygroscopic expansion of the polyimide film is smaller, the warpage of the laminate in a high humidity environment is smaller.

### 2. Synthesis of Photobase Generator

(Synthesis of Photobase Generator 1)

In a nitrogen atmosphere, 8.2 g (39 mmol) of 4,5-dimethoxy-2-nitrobenzaldehyde was dissolved in 100 mL of dehydrated 2-propanol in a 200-mL three-necked flask equipped with a Dean-Stark apparatus, and 2.0 g (10 mmol, 0.25 eq.) of aluminum isopropoxide was added to the solution. The mixture was heated and stirred at 105° C. for 7 hours. In the middle of the process, 40 mL of 2-propanol was added 4 times to the system along with the evaporation and reduction of the solvent. The reaction was terminated with 150 mL of 0.2 N hydrochloric acid, subsequently extraction with chloroform was carried out, and the solvent was distilled off under reduced pressure. Thereby, 7.2 g of 6-nitroveratryl alcohol was obtained.

In a nitrogen atmosphere, 5.3 g (25 mmol) of 6-nitroveratryl alcohol was dissolved in 100 mL of dehydrated dimethylacetamide in a 200-mL three-necked flask, and 7.0 mL (50 mmol, 2.0 eq.) of triethylamine was added thereto. In an ice bath, 5.5 g (27 mmol, 1.1 eq.) of p-nitrophenyl chloroformate was added thereto, and the mixture was stirred for 16 hours at room temperature. The reaction liquid was poured into 2 L of water, and a precipitate thus produced was filtered. Subsequently, the precipitation was purified by silica gel column chromatography, and thereby 6.4 g of 4,5-dimethoxy-2-nitrobenzyl-p-nitrophenyl carbonate was obtained.

In a nitrogen atmosphere, 3.6 g (9.5 mmol) of 4,5-dimethoxy-2-nitrobenzyl-p-nitrophenyl carbonate was dissolved in 50 mL of dehydrated dimethylacetamide in a 100-mL three-necked flask, and 5 mL (37 mmol, 3.9 eq.) of 2,6-dimethylpiperidine and 0.36 g (0.3 eq.) of 1-hydroxybenzotriazole were added to the solution. The mixture was heated and stirred at 90° C. for 18 hours. The reaction solution was poured into 1 L of a 1% aqueous solution of sodium hydrogen carbonate, and a precipitate thus produced was filtered and then washed with water. Thereby, 2.7 g of N-{[(4,5-dimethoxy-2-nitrobenzyl)oxy]carbonyl}-2,6-dimethyl piperidine, which was a photobase generator 1 represented by the following formula was obtained.

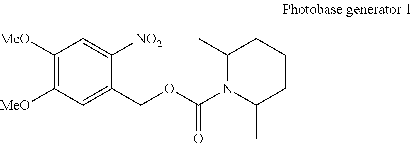 [SMILES: COc1cc(COC(=O)N2C(C)CCCC2C)c([N+](=O)[O-])cc1OC]

(Synthesis of Photobase Generator 2)

In a nitrogen atmosphere, 0.50 g (3.1 mmol) of o-coumaric acid (manufactured by Tokyo Chemical Industries, Ltd.) was dissolved in 40 mL of dehydrated tetrahydrofuran in a 100-mL three-necked flask, and 0.59 g (3.1 mmol, 1.0 eq.) of 1-ethyl-3-(3-dimethylaminopropyl)carbodiimide hydrochloride (manufactured by Tokyo Chemical Industries, Ltd.) was added to the solution. In an ice bath, 0.3 ml (3.1 mmol, 1.0 eq.) of piperidine (manufactured by Tokyo Chemical Industries, Ltd.) was added thereto, and the mixture was stirred overnight at room temperature. The reaction liquid was concentrated, and was extracted with chloroform. The extract was washed with dilute hydrochloric acid, a saturated aqueous solution of sodium hydrogen carbonate, and brine, and the residue was filtered. Thus, 450 mg of a photobase generator 2 represented by the following formula was obtained.

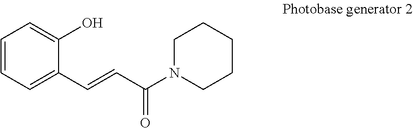 [SMILES: O=C(/C=C/c1ccccc1O)N1CCCCC1]

(Synthesis of Photobase Generator 3)

In a 100-mL flask, 2.00 g of potassium carbonate was added to 15 mL of methanol. In a 50-mL flask, 2.67 g (6.2 mmol) of ethoxycarbonylmethyl(triphenyl)phosphonium bromide and 945 mg (6.2 mmol) of 2-hydroxy-4-methoxybenzaldehyde were dissolved in 10 mL of methanol, and the solution was slowly added dropwise to a thoroughly stirred potassium carbonate solution. After stirring for 3 hours, completion of the reaction was confirmed by thin layer chromatography (TLC), and then the reaction liquid was filtered to remove potassium carbonate. The filtrate was concentrated under reduced pressure. After the concentration, 50 mL of 1 N aqueous solution of sodium hydroxide was added to the filtrate, and the mixture was stirred for one hour. After completion of the reaction, triphenylphosphine oxide was removed by filtration, and then concentrated hydrochloric acid was added dropwise to the filtrate to acidify the reaction liquid. A precipitate generated therefrom was collected by filtration, and was washed with a small amount of chloroform. Thereby, 1.00 g of 2-hydroxy-4-methoxycinnamic acid was obtained. Subsequently, in a 100-mL three-necked flask, 500 mg (3.0 mmol) of 2-hydroxy-4-methoxycinnamic acid was dissolved in 40 mL of dehydrated tetrahydroxyfuran, and 586 g (3.0 mmol) of EDCO was added thereto. After 30 minutes, 0.3 mL (3.0 mmol) of piperidine was added thereto. After completion of the reaction, the reaction solution was concentrated and dissolved in water. The mixture was extracted with diethyl ether, and then the extract was washed with a saturated aqueous solution of sodium hydrogen carbonate, 1 N hydrochloric acid, and saturated brine. Thereafter, the extract was purified by silica gel column chromatography (spreading solvent: chloroform/methanol=100/1 to 10/1), and thereby 64 mg of a photobase generator 3 represented by the following formula was obtained.

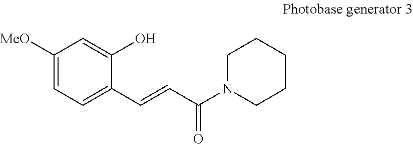 [SMILES: COc1ccc(/C=C/C(=O)N2CCCCC2)c(O)c1]

(Synthesis of Photobase Generator 4)

80 mg of a photobase generator 4 represented by the following formula was obtained in the same manner as in the synthesis of the photobase generator 3, except that cyclohexylamine was used instead of the piperidine used in the synthesis of the photobase generator 3.

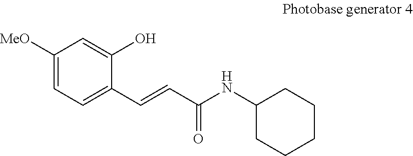 [SMILES: COc1ccc(/C=C/C(=O)NC2CCCCC2)c(O)c1]

(Synthesis of Photobase Generator 5)

75 mg of a photobase generator 5 represented by the following formula was obtained in the same manner as in the synthesis of the photobase generator 3, except that 1-hydroxy-2-naphthaldehyde was used in the synthesis of the photobase generator 3 instead of the 2-hydroxy-4-methoxybenzaldehyde.

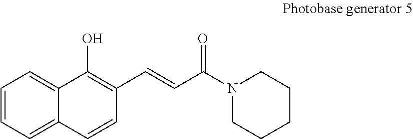 [SMILES: O=C(/C=C/c1ccc2ccccc2c1O)N1CCCCC1]

(Synthesis of Photobase Generator 6)

90 mg of a photobase generator 6 represented by the following formula was obtained in the same manner as in the synthesis of the photobase generator 3, except that 2-hydroxy-1-naphthaldehyde was used, instead of the 2-hydroxy-4-methoxybenzaldehyde, in the synthesis of the photobase generator 3.

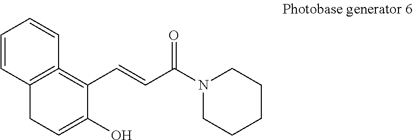

[Evaluation of Base Generators]

The photobase generators 1 to 6 thus synthesized were subjected to the following analyses and thus evaluated. The results of the molar extinction coefficient and the base generation capacity are presented in Table 3. Meanwhile, in Table 3, the photoreaction ratio refers to the percentage of the mole number of photoreacted photobase generator with respect to the mole number of the photobase generator used. The results of the 5% weight loss temperature are presented in Table 1.

(1) Molar Extinction Coefficient

Each of the photobase generators 1 to 6 was dissolved in acetonitrile at a concentration of 1×10⁻⁴ mol/L, the solution was filled in a quartz cell (light path length: 10 mm), and the absorbance was measured. Meanwhile, the molar extinction coefficient E is the value obtained by dividing the absorbance of the solution by the thickness of the absorption layer and the molar concentration of the solute (L/(mol·cm)).

(2) Evaluation of Photoreaction Ratio

For each of the photobase generators 1 to 6, three 1-mg samples were prepared, and each of them was dissolved in deuterated acetonitrile in an NMR tube made of quartz. One of the sample solutions was subjected to light irradiation at 2 J/cm², and another one of the sample solutions was subjected to light irradiation at 20 J/cm², by using a filter which cuts light having a wavelength of 350 nm or less and transmits 20% of i-line, and a high pressure mercury lamp. The remaining one sample solution was not subjected to light irradiation. The sample solutions were respectively subjected to ¹H-NMR, and the proportions of photoreaction were determined.

Meanwhile, in regard to the photoreaction ratio, the photobase generator and the photoreaction product were quantitatively determined together by NMR, and from their proportions, the photoreaction ratio (%) was calculated by the following formula:

Photoreaction ratio=Amount of photoreaction product/(amount of undecomposed photobase generator+amount of photoreaction product)×100

TABLE 3

| | Molar extinction | | | |
|---|---|---|---|---|
| | coefficient | | Evaluation of | |
| | ε | ε | photoreaction ratio | |
| | (365 nm) | (405 nm) | 2 J/cm² | 20 J/cm² |
| Photobase generator 1 | 4820 | 290 | 0 | 7 |
| Photobase generator 2 | 110 | 0 | 6 | 22 |
| Photobase generator 3 | 260 | 40 | 23 | 90 |
| Photobase generator 4 | 30 | 0 | 7 | 33 |
| Photobase generator 5 | 7700 | 240 | 10 | 58 |
| Photobase generator 6 | 5780 | 0 | 51 | 95 |

From Table 3, it was confirmed that the photobase generators 1 to 6 cause a photoreaction under irradiation at 20 J/cm², and thus it was clear that the photobase generators 1 to 6 have sensitivity to the i-line. In the photobase generator 1, generation of a base under irradiation at 2 J/cm² was not recognized. The photobase generator 6 exhibited the highest sensitivity, and then the photobase generator 3 exhibited the second highest sensitivity.

(3) Thermogravimetric Analysis

In order to evaluate the heat resistance of the photobase generators 1 to 6 and nifedipine (manufactured by Tokyo Chemical Industries, Ltd.), each of the compounds was subjected to a thermogravimetric analysis under the conditions of a rate of temperature increase of 10° C./min, on the basis of the weight at 30° C. The results are presented in Table 4.

TABLE 4

| | Weight loss | | Weight loss |
|---|---|---|---|
| | temperature (° C.) | | ratio (%) |
| | 5% | 50% | 300° C. |
| Photobase generator 1 | 249 | 295 | 63 |
| Photobase generator 2 | 199 | 247 | 98 |
| Photobase generator 3 | 208 | 233 | 87 |
| Photobase generator 4 | 205 | 237 | 78 |
| Photobase generator 5 | 191 | 244 | 71 |
| Photobase generator 6 | 199 | 255 | 98 |
| Nifedipine | 255 | 292 | 69 |

### Preparation Example 1

The photobase generator 1 was added to the polyimide precursor solution 1 in an amount of 15% by weight of the solids content of the solution, and thus a photosensitive polyimide resin composition 1 was obtained.

### Preparation Example 2

The photobase generator 3 was added to the polyimide precursor solution 1 in an amount of 10% by weight of the solids content of the solution, and thus a photosensitive polyimide resin composition 2 was obtained.

### Preparation Example 3

The photobase generator 3 was added to the polyimide precursor solution 11 in an amount of 15% by weight of the solids content of the solution, and thus a photosensitive polyimide resin composition 3 was obtained.

### Preparation Example 4

The photobase generator 1 was added to the polyimide precursor solution 11 in an amount of 15% by weight of the solids content of the solution, and thus a photosensitive polyimide resin composition 4 was obtained.

### Preparation Example 5

The photobase generator 2 was added to the polyimide precursor solution 11 in an amount of 15% by weight of the solids content of the solution, and thus a photosensitive polyimide resin composition 5 was obtained.

### Preparation Example 6

The photobase generator 4 was added to the polyimide precursor solution 11 in an amount of 15% by weight of the solids content of the solution, and thus a photosensitive polyimide resin composition 6 was obtained.

### Preparation Example 7

The photobase generator 5 was added to the polyimide precursor solution 11 in an amount of 15% by weight of the solids content of the solution, and thus a photosensitive polyimide resin composition 7 was obtained.

### Preparation Example 8

The photobase generator 6 was added to the polyimide precursor solution 11 in an amount of 15% by weight of the solids content of the solution, and thus a photosensitive polyimide resin composition 8 was obtained.

### Preparation Example 9

Nifedipine (manufactured by Tokyo Chemical Industries, Ltd.) was added to the polyimide precursor solution 11 in an amount of 30% by weight of the solids content of the solution, and thus a photosensitive polyimide resin composition 9 was obtained.

### 3. Evaluation of Photosensitive Resin Composition: Evaluation of Pattern Formation Capacity

The photosensitive polyimide resin composition 1 and the photosensitive polyimide resin composition 2 prepared in the Preparation Examples were each spin coated on a chromium-plated glass plate to a final film thickness of 4 μm, and the resin compositions were dried for 15 minutes on a hot plate at 80° C. Thus, coating films of the photosensitive polyimide resin composition 1 and the photosensitive polyimide resin composition 2 were produced. Patternwise exposure was carried out through a photomask by using a manual exposure machine and a high pressure mercury lamp, and the coating film of the photosensitive polyimide resin composition 1 was exposed at a dose of 2000 mJ/cm², while the coating film of the photosensitive polyimide resin composition 2 was exposed at a dose of 100 mJ/cm². Thereafter, the coating films were respectively heated for 10 minutes at 155° C.

Each of the coating films was immersed in a solution prepared by mixing a 2.38 wt % aqueous solution of tetramethylammonium hydroxide and isopropanol at 9:1. As a result, patterns in which the exposed areas remained undissolved by the developing liquid were obtained. Furthermore, the patterns were heated at 350° C. for one hour to perform imidization. As such, it was made clear that satisfactory patterns can be formed by using the photosensitive polyimide resin compositions 1 and 2.

The photosensitive polyimide resin compositions 3 to 8 prepared in the Preparation Examples were each spin coated on a chromium-plated glass plate to a final film thickness of 4 μm, and were dried for 15 minutes on a hot plate at 100° C. Thus, coating films of the photosensitive polyimide resin compositions 3 to 8 were produced. Patternwise exposure was carried out through a photomask by using a manual exposure machine and a high pressure mercury lamp, and the coating film of the photosensitive polyimide resin composition 3 was exposed at a dose of 80 mJ/cm²; the photosensitive polyimide resin composition 4 was exposed at a dose of 1500 mJ/cm²; the photosensitive polyimide resin composition 5 was exposed at a dose of 500 mJ/cm²; the photosensitive polyimide resin composition 6 was exposed at a dose of 400 mJ/cm²; the photosensitive polyimide resin composition 7 was exposed at a dose of 200 mJ/cm²; while the coating film of the photosensitive polyimide resin composition 8 was exposed at a dose of 80 mJ/cm². Thereafter, the coating films were respectively heated for 10 minutes at 170° C.

Each of the coating films was immersed in a solution prepared by mixing a 2.38 wt % aqueous solution of tetramethylammonium hydroxide and isopropanol at 8:2. As a result, patterns in which the exposed areas remained undissolved by the developing liquid were obtained.

### 4. Evaluation of Coefficient of Linear Thermal Expansion and Coefficient of Hygroscopic Expansion

Furthermore, the photosensitive polyimide resin compositions 1, 2 and 3 were each applied on a heat resistant film (Upilex S 50S™: manufactured by Ube Industries, Ltd.) adhered to a glass plate, and the resin compositions were dried for 10 minutes on a hot plate at 100° C. Subsequently, the resin composition were exposed with a high pressure mercury lamp at 2000 mJ/cm² in terms of illumination with a wavelength of 365 nm, and the dried resin compositions were heated at 170° C. for 10 minutes on a hot plate. Subsequently, the heated resin compositions were peeled off from the heat resistant films, and thus films having a thickness of 10 μm were obtained. Thereafter, each of the films was fixed to a metal frame, and in a nitrogen atmosphere, the film was heat treated at 350° C. for one hour (rate of temperature increase: 10° C./min, natural cooling). Thus, films of photosensitive polyimide 1, photosensitive polyimide 2 and photosensitive polyimide 3, each having a thickness of 6 μm, were obtained.

Evaluations of the coefficient of linear thermal expansion, coefficient of hygroscopic expansion, and substrate warpage were carried out in the same manner as described above. The results are presented in Table 5.

TABLE 5

| | CTE | CHE | Evaluation of | |
|---|---|---|---|---|
| | (ppm/ | (ppm/ | substrate warpage | |
| | ° C.) | Rh %) | 100° C. | 85% Rh |
| Photosensitive polyimide | 26.1 | 16.0 | Δ | Δ |
| resin composition 1 | | | | |
| Photosensitive polyimide | 22.1 | 13.0 | ∘ | ∘ |
| resin composition 2 | | | | |
| Photosensitive polyimide | 15.5 | 8.9 | ∘ | ∘ |
| resin composition 3 | | | | |

As can be seen from Table 5, since the coefficient of linear thermal expansion of the SUS304 foil was 17 ppm/° C., it was verified that if the difference in the coefficient of linear thermal expansion between the polyimide film and the metal foil is large, the warpage of the laminate is large.

Also, from Table 5, it was found that as the coefficient of hygroscopic expansion of the polyimide film was smaller, the warpage of the laminate in a high humidity environment was smaller.

### 5. Outgassing Test

The photosensitive polyimide resin composition 3 and the photosensitive polyimide resin composition 4 prepared in the Preparation Examples were each spin coated on a glass plate to a final film thickness of 10 μm, and the resin compositions were dried for 15 minutes on a hot plate at 100° C. Thus, coating films of the photosensitive polyimide resin composition 3 and the photosensitive polyimide resin composition 4 were produced. Exposure was carried out through a photomask by using a manual exposure machine and a high pressure mercury lamp, and the coating film of the photosensitive polyimide resin composition 3 was exposed at a dose of 500 mJ/cm², while the coating film of the photosensitive polyimide resin composition 4 was exposed at a dose of 2000 mJ/cm². Thereafter, the coating films were respectively heated for 10 minutes at 170° C. The coating films were respectively heated at 350° C. for one hour to achieve imidization, and thus outgassing measurement samples 1 and 2 were obtained.

Furthermore, the polyimide precursor solution 11 was spin coated on a glass plate to a final film thickness of 10 and was dried for 15 minutes on a hot plate at 100° C. Thus, a coating film of the polyimide solution 11 was produced. The coating film was heated for one hour at 350° C. to achieve imidization, and thus an outgassing measurement sample 3 was obtained.

The photosensitive polyimide resin composition 9 prepared in Preparation Example 9 was spin coated on a glass plate to a final film thickness of 10 μm, and the resin composition was dried for 15 minutes on a hot plate at 100° C. Thus, a coating film of a comparative photosensitive polyimide resin composition 1 was produced. Exposure was carried out at 1000 mJ/cm² through a photomask by using a manual exposure machine and a high pressure mercury lamp. Thereafter, the coating film was heated for 10 minutes at 185° C., and then was heated for one hour at 350° C. to achieve imidization, and thus an outgassing measurement sample 4 was obtained.

UR-5100FX™ (manufactured by Toray Industries, Inc.) was spin coated on a glass plate to a final film thickness of 10 μm, and the agent was dried for 8 minutes on a hot plate at 95° C. Thus, a coating film of UR-5100FX™ was produced. Exposure was carried out at 70 mJ/cm² through a photomask by using a manual exposure machine and a high pressure mercury lamp. Thereafter, the coating film was heated for 1 minute at 80° C., and then was heated for 30 minutes at 140° C. and for one hour at 350° C. to achieve imidization, and thus an outgassing measurement sample 5 was obtained.

XP-1530™ (manufactured by HD Microsystems, Ltd.) was spin coated on a glass plate to a final film thickness of 10 μm, and the agent was dried for 2 minutes on a hot plate at 70° C. and for 2 minutes on a hot plate at 85° C. Thus, a coating film of XP-1530™ was produced. Exposure was carried out at 300 mJ/cm² through a photomask by using a manual exposure machine and a high pressure mercury lamp. Thereafter, the coating film was heated for 1 minute at 105° C., and then was heated for 30 minutes at 200° C. and for one hour at 350° C. to achieve imidization, and thus an outgassing measurement sample 6 was obtained.

For the outgassing measurement samples 1 to 6 thus produced, the samples were scraped off from the glass plates, and in a nitrogen atmosphere, the samples were heated to 100° C. at a rate of temperature increase of 10° C./min, and then were heated for 60 minutes at 100° C. Subsequently, the samples were cooled naturally for 15 minutes in a nitrogen atmosphere, and then the 5% weight loss temperature was measured on the basis of the weight after cooling as measured at a rate of temperature increase of 10° C./min. The results are presented in Table 6.

TABLE 6

| | 5% weight loss |
|---|---|
| | temperature |
| Outgassing measurement sample 1 | 504 |
| Outgassing measurement sample 2 | 463 |
| Outgassing measurement sample 3 | 500 |
| Outgassing measurement sample 4 | 449 |
| Outgassing measurement sample 5 | 361 |
| Outgassing measurement sample 6 | 364 |

As can be seen from Table 6, the samples prepared by using photobase generators (outgassing measurement samples 1 and 2) both had 5% weight loss temperatures of 450° C. or higher. The outgassing measurement sample 1 exhibited very low outgassing properties to an extent equivalent to that of simple polyamic acid (outgassing measurement sample 3) (because the 50% weight loss temperatures of the photobase generators were low, and because there was less residue originating from the photosensitive component). The other measurement samples all exhibited 5% weight loss temperatures of lower than 450° C.

### Example 1-1

The polyimide precursor solution 1 was applied on a SUS304-HTA™ base material (manufactured by Koyama Steel Co., Ltd.) having a thickness of 100 μm by using a spin coater such that the film thickness after imidization would be 7 μm±1 μm, and the polyimide precursor solution was dried in air in an oven at 100° C. for 60 minutes, and then heat treated (rate of temperature increase: 10° C./min, natural cooling) for one hour at 350° C. in a nitrogen atmosphere. Thus, an insulating layer was formed.

Subsequently, an aluminum film was formed as a first adhesion layer on the insulating layer by a direct current (DC) sputtering method (film forming pressure: 0.2 Pa (argon), input power: 1 kW, and film forming time: 10 seconds) to a thickness of 5 nm. Next, a silicon oxide film as a second adhesion layer was formed thereon by a radiofrequency (RF) magnetron sputtering method (film forming pressure: 0.3 Pa (argon:oxygen=3:1), input power: 2 kW, and film forming time: 30 minutes) to a thickness of 100 nm. Thereby, a TFT substrate was obtained.

A TFT having a bottom-gate, bottom-contact structure was produced on the TFT substrate. First, an aluminum film having a thickness of 100 nm was formed as a gate electrode film, and then a resist pattern was formed thereon by a photolithographic method, followed by wet etching with a phosphoric acid solution. The aluminum film was patterned into a predetermined pattern, and thus a gate electrode was formed. Subsequently, a silicon oxide film having a thickness of 300 nm was formed over the entire surface as a gate insulating film so as to cover the gate electrode. This gate insulating film was formed by using an RF magnetron sputtering apparatus and a 6-inch SiO₂ target under the film forming conditions of an input power of 1.0 kW (=3 W/cm²), a pressure of 1.0 Pa, with a gas mixture of argon and O₂ (50%). Thereafter, a resist pattern was formed by a photolithographic method, and then dry etching was carried out to form contact holes. Next, a titanium film, an aluminum film and an IZO film, each having a thickness of 100 nm, were deposited over the entire surface of the gate insulating film so as to use them as a source electrode and a drain electrode. Subsequently, a resist pattern was formed thereon by a photolithographic method, and then wet etching was carried out serially with an aqueous solution of hydrogen peroxide and a phosphoric acid solution. The titanium film was patterned into a predetermined pattern, and thus a source electrode and a drain electrode were formed. At this time, the source electrode and the drain electrode were formed on the gate insulating film, in a pattern of being partitioned immediately above the center of the gate electrode.

Next, an InGaZnO-based amorphous oxide thin film (InGaZnO₄) containing In, Ga and Zn at a ratio of 1:1:1 was formed to a thickness of 25 nm, over the entire surface so as to cover the source electrode and the drain electrode. The amorphous oxide thin film was formed by using an RF magnetron sputtering apparatus and a 4-inch InGaZnO (In:Ga:Zn=1:1:1) target, under the conditions of room temperature (25° C.) with a gas mixture of Ar:O₂ of 30:50. Thereafter, a resist pattern was formed by photolithography on the amorphous oxide thin film, and then wet etching was carried out with an oxalic acid solution. The amorphous oxide thin film was patterned, and thus an amorphous oxide thin film constituting a predetermined pattern was formed. The amorphous oxide thin film thus obtained was formed on the gate insulating film, so as to be in contact with the source electrode and the drain electrode on both sides and also to bridge across the source electrode and the drain electrode.

Subsequently, the photosensitive polyimide resin composition 3 was spin coated to a final film thickness of 0.1 μm so as to cover the entire surface, and the resin composition was dried for 15 minutes at 100° C. Patternwise exposure was carried out at 80 mJ/cm² through a photomask by using a manual exposure machine and a high pressure mercury lamp. Thereafter, the assembly was heated for 10 minutes at 170° C., and then development was carried out with a solution prepared by mixing a 2.38 wt % aqueous solution of tetramethylammonium hydroxide and isopropanol at 8:2. The assembly was further heated for one hour at 350° C. in a nitrogen atmosphere to achieve imidization.

Subsequently, annealing was carried out for one hour at 300° C. in air, and thus a TFT was produced.

When the TFT thus obtained was operated, the TFT exhibited satisfactory operation.

### Comparative Example 1

The TFT production method described above was carried out in the same manner as in Example 1-1, up to the step of forming an amorphous oxide thin film. Subsequently, a silicon oxide film having a thickness of 100 nm was formed as a protective film by an RF magnetron sputtering method so as to cover the entire surface, and then a resist pattern was formed thereon by a photolithographic method. Subsequently, dry etching was carried out, and annealing was carried out for one hour at 300° C. in air. Thus, a TFT substrate was produced.

[Evaluation Results]

In the TFTs produced in the Examples, a decrease in the S value in the transfer characteristics of the TFTs was observed, as compared with the TFTs of the Comparative Examples. It is speculated that it is because the trap density at the interface between the oxide semiconductor and the gate insulating film decreased due to steam annealing.

### II. Examples of Second Embodiment

### Preparation Example

### 1. Preparation of Polyimide Varnish (Polyimide Precursor Solution)

Polyimide precursor solutions 1 to 17 were prepared by the same method as that used in “I. Examples of first embodiment”, and evaluations of the coefficient of linear thermal expansion and the coefficient of hygroscopic expansion, and an evaluation of the substrate warpage were carried out. The evaluation results are presented in Table 1 and Table 2 described above.

### 2. Synthesis of Photobase Generator

Photobase generators 1 to 6 were prepared by the same method as that used in “I. Examples of first embodiment” described above, and evaluations of the molar extinction coefficient and the photoreaction ratio, and an evaluation of the base generators by a thermogravimetric analysis were carried out. The evaluation results are presented in Table 3 and Table 4 described above.

Furthermore, photosensitive polyimide resin compositions 1 to 8 were prepared in the same manner as in the case of the photosensitive polyimide resin compositions 1 to 8 described in “I. Examples of first embodiment” described above. Furthermore, a comparative photosensitive polyimide resin composition 1 was prepared in the same manner as in the case of the photosensitive polyimide resin composition 9 described in “I. Examples of first embodiment” described above.

### 3. Evaluation of Photosensitive Resin Composition: Evaluation of Pattern Formation Capacity

Subsequently, an evaluation of the photosensitive polyimide resin compositions 1 to 8 (evaluation of pattern formation capacity) was carried out in the same manner as in “I. Examples of first embodiment” described above.

### 4. Evaluations of Coefficient of Linear Thermal Expansion and Coefficient of Hygroscopic Expansion

For the photosensitive polyimide resin compositions 1 to 3, evaluations of the coefficient of linear thermal expansion, the coefficient of hygroscopic expansion, and the substrate warpage were carried out in the same manner as in “I. Examples of first embodiment”. The evaluation results are presented in Table 5 described above.

### 5. Outgassing Test

Furthermore, outgassing measurement samples 1 to 3, 5 and 6 were produced by the same method as that used for the outgassing measurement samples 1 to 3, 5 and 6 of “I. Examples of first embodiment” described above.

Furthermore, a comparative photosensitive polyimide resin composition 1 prepared in Comparative Preparation Example was spin coated on a glass plate to a final film thickness of 10 μm, and the resin composition was dried for 15 minutes on a hot plate at 100° C. Thus, a coating film of the comparative photosensitive polyimide resin composition 1 was produced. Exposure was carried out at 1000 mJ/cm2 through a photomask by using a manual exposure machine and a high pressure mercury lamp. Thereafter, the assembly was heated for 10 minutes at 185° C., and then was heated for one hour at 350° C. to achieve imidization. Thus, an outgassing measurement sample 4 was obtained.

For the outgassing measurement samples 1 to 6 thus produced, measurement of the 5% weight loss temperature was carried out in the same manner as in “I. Examples of first embodiment” described above. The evaluation results are presented in Table 6 described above.

### Example 2-1

A TFT was produced in the same manner as in [Example 1-1] of “I. Examples of first embodiment”.

The TFT thus obtained was operated, and the TFT exhibited satisfactory operation.

### Reference Example 1

A comparative TFT was produced by the same process as the TFT production method described above, except that the comparative photosensitive polyimide resin composition was used instead of the photosensitive polyimide resin composition 3.

The comparative TFT thus obtained was operated, and four samples out of 10 samples did not operate satisfactorily. It is speculated that impurities were incorporated into the oxide semiconductor, into the insulating films, or into their interfaces, as a result of outgassing, and the TFTs did not function properly.

### III. Examples of Third Embodiment

### Preparation Example

### 1. Preparation of Polyimide Varnish (Polyimide Precursor Solution)

Polyimide precursor solutions 1 to 17 were prepared in the same manner as in “I. Examples of first embodiment” described above, and evaluations of the coefficient of linear thermal expansion and the coefficient of hygroscopic expansion, and an evaluation of the substrate warpage were carried out. The evaluation results are presented in Table 1 and Table 2 described above.

### 2. Synthesis of Photobase Generator

A photobase generator 1 was prepared in the same manner as in “I. Examples of first embodiment” described above.

### 3. Preparation of Photosensitive Polyimide Resin Composition

(1) Preparation of Photosensitive Polyimide Resin Composition 1

The photobase generator 1 was added to the polyimide precursor solution 11 in an amount of 15% by weight of the solids content of the solution, and thus a photosensitive polyimide resin composition 1 was obtained.

(2) Preparation of Photosensitive Polyimide Resin Composition 2

Nifedipine (manufactured by Tokyo Chemical Industries, Ltd.) was added to the polyimide precursor solution 11 in an amount of 30% by weight of the solids content of the solution, and thus a photosensitive polyimide resin composition 2 was obtained.

### 4. Patterning of Non-Photosensitive Polyimide

### (1) Preparation Example A

The polyimide precursor solution 1 was applied with a die coater on a SUS304-HTA™ foil (manufactured Toyo Seihaku Co., Ltd.) having a thickness of 18 μm, which was cut to a size of 15 cm on all four sides. The polyimide precursor solution was dried for 60 minutes in air in an oven at 80° C. Thereafter, a resist was provided on the polyimide precursor film by using a dry film resist, and simultaneously with the development of this resist, the polyimide precursor film was developed. Thereafter, the resist pattern was peeled, and then in a nitrogen atmosphere, the assembly was heat treated at 350° C. for one hour (rate of temperature increase: 10° C./min, natural cooling). Thus, a laminate 1P having an intended pattern removed therefrom was obtained.

The laminate 1P was stable against changes in the temperature or humidity environment, and had reliable flatness.

### (2) Preparation Example B

The polyimide precursor solution 12 was applied with a die coater on a SUS304-HTA™ foil (manufactured Toyo Seihaku Co., Ltd.) having a thickness of 18 μm, which was cut to a size of 15 cm on all four sides. The polyimide precursor solution was dried for 60 minutes in air in an oven at 80° C. Thereafter, the assembly was heat treated at 350° C. for one hour (rate of temperature increase: 10° C./min, natural cooling) in a nitrogen atmosphere, and thus a laminate 12 was obtained. A resist pattern was formed on the polyimide film of the laminate 12. The areas where the polyimide film was exposed were removed by using a polyimide etching liquid, TPE-3000™ (manufactured by Toray Engineering Co., Ltd.), and then the resist pattern was peeled. Thus, a laminate 10P having an intended pattern removed therefrom was obtained.

The laminate 10P was stable against changes in the temperature or humidity environment, and had reliable flatness.

### 5. Outgassing Test

(1) Outgassing Measurement Sample 1

The polyimide precursor solution 11 as a non-photosensitive polyimide resin composition was spin coated on a glass plate to a final film thickness of 10 μm, and the polyimide precursor solution was dried for 15 minutes on a hot plate at 100° C. Thus, a coating film of the polyimide solution 11 was produced. This coating film was heated for one hour at 350° C., and imidization was carried out. Thus, an outgassing measurement sample 1 was obtained.

(2) Outgassing Measurement Sample 2

The photosensitive polyimide resin composition 1 was spin coated on a glass plate to a final film thickness of 10 μm, and the resin composition was dried for 15 minutes on a hot plate at 100° C. Thus, a coating film of the photosensitive polyimide resin composition 1 was produced. Exposure was carried out at 2000 mJ/cm² through a photomask by using a manual exposure machine and a high pressure mercury lamp. Thereafter, this coating film was heated for 10 minutes at 185° C. and was heated for one hour at 350° C., and imidization was carried out. Thus, an outgassing measurement sample 2 was obtained.

(3) Outgassing Measurement Sample 3

The photosensitive polyimide resin composition 2 was spin coated on a glass plate to a final film thickness of 10 μm, and the resin composition was dried for 15 minutes on a hot plate at 100° C. Thus, a coating film of the photosensitive polyimide resin composition 2 was produced. Exposure was carried out at 1000 mJ/cm² through a photomask by using a manual exposure machine and a high pressure mercury lamp. Thereafter, this coating film was heated for 10 minutes at 185° C. and was heated for one hour at 350° C., and imidization was carried out. Thus, an outgassing measurement sample 3 was obtained.

(4) Outgassing Measurement Sample 4

UR-5100FX™ (manufactured by Toray Industries, Inc.), which is a photosensitive polyimide resin composition, was spin coated on a glass plate to a final film thickness of 10 μm, and the resin composition was dried for 8 minutes on a hot plate at 95° C. Thus, a coating film of UR-5100FX™ was produced. Exposure was carried out at 70 mJ/cm² through a photomask by using a manual exposure machine and a high pressure mercury lamp. Thereafter, this coating film was heated for 1 minute at 80° C. and then was heated for 30 minutes at 140° C. and for one hour at 350° C., and imidization was carried out. Thus, an outgassing measurement sample 4 was obtained.

(5) Outgassing Measurement Sample 5

XP-1530™ (manufactured by HD Microsystems, Ltd.), which is a photosensitive polyimide resin composition, was spin coated on a glass plate to a final film thickness of 10 μm, and the resin composition was dried for 2 minutes on a hot plate at 70° C. and for 2 minutes on a hot plate at 85° C. Thus, a coating film of XP-1530™ was produced. Exposure was carried out at 300 mJ/cm² through a photomask by using a manual exposure machine and a high pressure mercury lamp. Thereafter, this coating film was heated for 1 minute at 105° C. and then was heated for 30 minutes at 200° C. and for one hour at 350° C., and imidization was carried out. Thus, an outgassing measurement sample 5 was obtained.

(6) Outgassing Measurement

For the outgassing measurement samples 1 to 5 thus produced, the samples were scraped off from the glass plates, and in a nitrogen atmosphere, the samples were heated to 100° C. at a rate of temperature increase of 10° C./min, and then were heated for 60 minutes at 100° C. Subsequently, the samples were cooled naturally for more than 15 minutes in a nitrogen atmosphere, and then the 5% weight loss temperature was measured on the basis of the weight after cooling as measured at a rate of temperature increase of 10° C./min. The results are presented in Table 7.

TABLE 7

| | 5% weight loss |
|---|---|
| | temperature (° C.) |
| Outgassing measurement sample 1 | 500 |
| Outgassing measurement sample 2 | 463 |
| Outgassing measurement sample 3 | 449 |
| Outgassing measurement sample 4 | 361 |
| Outgassing measurement sample 5 | 364 |

As shown in Table 7, the sample 1 produced by using a non-photosensitive polyimide resin composition exhibited very low outgassing properties as compared with the samples 2 to 5 produced by using photosensitive polyimide resin compositions.

### Example 3-1

The polyimide precursor solution 1 was applied on a SUS304-HTA™ base material (manufactured by Koyama Steel Co., Ltd.) having a thickness of 100 μm by using a spin coater such that the film thickness after imidization would be 7 μm±1 μm, and the polyimide precursor solution was dried in air in an oven at 100° C. for 60 minutes, and then heat treated (rate of temperature increase: 10° C./min, natural cooling) for one hour at 350° C. in a nitrogen atmosphere. Thus, an insulating layer was formed.

Subsequently, an aluminum film was formed as a first adhesion layer on the insulating layer by a DC sputtering method (film forming pressure: 0.2 Pa (argon), input power: 1 kW, and film forming time: 10 seconds) to a thickness of 5 nm. Next, a silicon oxide film as a second adhesion layer was formed thereon by an RF magnetron sputtering method (film forming pressure: 0.3 Pa (argon:oxygen=3:1), input power: 2 kW, and film forming time: 30 minutes) to a thickness of 100 nm. Thereby, a TFT substrate was obtained.

A TFT having a bottom-gate, bottom-contact structure was produced on the TFT substrate. First, an aluminum film having a thickness of 100 nm was formed as a gate electrode film, and then a resist pattern was formed thereon by a photolithographic method, followed by wet etching with a phosphoric acid solution. The aluminum film was patterned into a predetermined pattern, and thus a gate electrode was formed. Subsequently, a silicon oxide film having a thickness of 300 nm was formed over the entire surface as a gate insulating film so as to cover the gate electrode. This gate insulating film was formed by using an RF magnetron sputtering apparatus and a 6-inch SiO₂ target under the film forming conditions of an input power of 1.0 kW (=3 W/cm²), a pressure of 1.0 Pa, with a gas mixture of argon and O₂ (50%). Thereafter, a resist pattern was formed by a photolithographic method, and then dry etching was carried out to form contact holes. Next, a titanium film, an aluminum film and an IZO film, each having a thickness of 100 nm, were deposited over the entire surface of the gate insulating film so as to use them as a source electrode and a drain electrode. Subsequently, a resist pattern was formed thereon by a photolithographic method, and then wet etching was carried out serially with an aqueous solution of hydrogen peroxide and a phosphoric acid solution. The titanium film was patterned into a predetermined pattern, and thus a source electrode and a drain electrode were formed. At this time, the source electrode and the drain electrode were formed on the gate insulating film, in a pattern of being partitioned immediately above the center of the gate electrode.

Next, an InGaZnO-based amorphous oxide thin film (InGaZnO₄) containing In, Ga and Zn at a ratio of 1:1:1 was formed to a thickness of 25 nm, over the entire surface so as to cover the source electrode and the drain electrode. The amorphous oxide thin film was formed by using an RF magnetron sputtering apparatus and a 4-inch InGaZnO (In:Ga:Zn=1:1:1) target, under the conditions of room temperature (25° C.) with a gas mixture of Ar:O₂ of 30:50. Thereafter, a resist pattern was formed by photolithography on the amorphous oxide thin film, and then wet etching was carried out with an oxalic acid solution. The amorphous oxide thin film was patterned, and thus an amorphous oxide thin film constituting a predetermined pattern was formed. The amorphous oxide thin film thus obtained was formed on the gate insulating film, so as to be in contact with the source electrode and the drain electrode on both sides and also to bridge across the source electrode and the drain electrode.

Subsequently, the polyimide precursor solution 1 was spin coated to a final film thickness of 0.1 μm so as to cover the entire surface, and the resin composition was dried for 15 minutes at 100° C. Thereafter, patterning of the non-photosensitive polyimide resin composition layer was carried out by the method of Preparation Example A described above, the non-photosensitive polyimide resin composition layer was heated for one hour at 350° C. in a nitrogen atmosphere, and imidization was carried out.

Subsequently, annealing was carried out for one hour at 300° C. in air, and thus a TFT was produced.

The TFT thus obtained was operated, and the TFT exhibited satisfactory operation.

### Reference Example 3-1

The TFT production method described above was carried out in the same manner as in Example 3-1, up to the step of forming an amorphous oxide thin film. Subsequently, the photosensitive polyimide resin composition 2 was spin coated thereon to a final film thickness of 0.1 μm so as to cover the entire surface, and the resin composition was dried for 15 minutes at 100° C. Subsequently, patternwise exposure was carried out at 200 mJ/cm² through a photomask by using a manual exposure machine and a high pressure mercury lamp. Thereafter, this coating film was heated for 10 minutes at 185° C. and then was developed with a solution prepared by mixing a 2.38 wt % aqueous solution of tetramethylammonium hydroxide and isopropanol at 8:2. Furthermore, the coating film was heated for one hour at 350° C. in a nitrogen atmosphere, and imidization was carried out.

Subsequently, annealing was carried out for one hour at 300° C. in air, and a TFT was produced.

The TFT thus obtained was operated, and four samples out of 10 samples did not operate satisfactorily. It is speculated that impurities were incorporated into the oxide semiconductor, into the insulating films, or into their interfaces, as a result of outgassing, and the TFTs did not function properly.

### REFERENCE SIGNS LIST

1 Metal foil
2 Planarizing layer
3 Adhesion layer
10 Substrate
11 Oxide semiconductor layer
12S Source electrode
12D Drain electrode
13G Gate electrode
14 Gate insulating layer
15 Passivation layer
20 TFT substrate

1. A thin film transistor substrate comprising:
a substrate; and
a thin film transistor having an oxide semiconductor layer that is formed on the substrate and is formed from an oxide semiconductor, and a semiconductor layer-adjoining insulating layer formed to be in contact with the oxide semiconductor layer,
wherein at least one semiconductor layer-adjoining insulating layer included in the thin film transistor being a photosensitive polyimide insulating layer that is formed by using a photosensitive polyimide resin composition.

2. The thin film transistor substrate according to claim 1, wherein the photosensitive polyimide resin composition contains a polyimide component and a photosensitive component, and
the polyimide component includes a polyimide precursor.

3. The thin film transistor substrate according to claim 1, wherein a 5% weight loss temperature of the photosensitive polyimide resin composition is 450° C. or higher.

4. The thin film transistor substrate according to claim 3, wherein the photosensitive polyimide resin composition comprises a polyimide component and a photosensitive component, and
a content of the photosensitive component is in the range of greater than or equal to 0.1 part by weight and less than 30 parts by weight relative to 100 parts by weight of the polyimide component.

5. The thin film transistor substrate according to claim 1, wherein as for the semiconductor layer-adjoining insulating layer, a gate insulating layer in a top-gate type thin film transistor, or at least one of a gate insulating layer and a passivation layer in a bottom-gate type thin film transistor is at least the photosensitive polyimide insulating layer.

6. The thin film transistor substrate according to claim 5, wherein as for the semiconductor layer-adjoining insulating layer, the gate insulating layer in the top-gate type thin film transistor, or the passivation layer in the bottom-gate type thin film transistor is at least the photosensitive polyimide insulating layer.

7. A thin film transistor substrate comprising:
a substrate; and
a thin film transistor having a semiconductor layer formed on the substrate, and a semiconductor layer-adjoining insulating layer formed to be in contact with the semiconductor layer,
wherein at least one semiconductor layer-adjoining insulating layer being a low-outgassing photosensitive polyimide insulating layer formed by using a low-outgassing photosensitive polyimide resin composition having a 5% weight loss temperature of 450° C. or higher.

8. The thin film transistor substrate according to claim 7, wherein the low-outgassing photosensitive polyimide resin composition contains a polyimide component and a photosensitive component, and a content of the photosensitive component is in the range of greater than or equal to 0.1 part by weight and less than 30 parts by weight relative to 100 parts by weight of the polyimide component.

9. The thin film transistor substrate according to claim 7, wherein as for the semiconductor layer-adjoining insulating layer, a gate insulating layer in a top-gate type thin film transistor, or at least one of a gate insulating layer and a passivation layer in a bottom-gate type thin film transistor is at least the low-outgassing photosensitive polyimide insulating layer.

10. The thin film transistor substrate according to claim 7, wherein the semiconductor layer is a deposited type semiconductor layer formed by a vapor deposition method.

11. The thin film transistor substrate according to claim 10, wherein the deposited type semiconductor layer is an oxide semiconductor layer.

12. The thin film transistor substrate according to claim 10, wherein as for the semiconductor layer-adjoining insulating layer, at least a semiconductor layer-adjoining insulating layer on which the deposited type semiconductor layer is directly laminated is the low-outgassing photosensitive polyimide insulating layer.

13. The thin film transistor substrate according to claim 2, wherein the photosensitive component includes a photoacid generator or a photobase generator as a main component.

14. The thin film transistor substrate according to claim 13, wherein the photosensitive component is the photobase generator.

15. The thin film transistor substrate according to claim 13, wherein a base generated from the photobase generator is aliphatic amine or amidine.

16. The thin film transistor substrate according to claim 13, wherein a 5% weight loss temperature of the photobase generator is in the range of 150° C. to 300° C.

17. The thin film transistor substrate according to claim 13, wherein the photobase generator is a compound represented by the following formula: 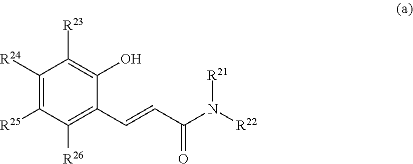
in the formula (a), R²¹ and R²², which may be identical with or different from each other, each independently represent a hydrogen atom or a monovalent organic group; R²¹ and R²² may be bonded to each other and form a cyclic structure, or may contain a bond to a heteroatom, provided that at least one of R²¹ and R²² is a monovalent organic group; R²³, R²⁴, R²⁵ and R²⁶, which may be identical with or different from each other, each independently represent a hydrogen atom, a halogen atom, a hydroxyl group, a mercapto group, a sulfide group, a silyl group, a silanol group, a nitro group, a nitroso group, a sulfino group, a sulfo group, a sulfonato group, a phosphino group, a phosphinyl group, a phosphono group, a phosphonato group, an amino group, an ammonia group or a monovalent organic group; and two or more of R²³, R²⁴, R²⁵ and R²⁶ may be bonded to each other and form a cyclic structure, or may contain a bond to a heteroatom.

18. A thin film transistor substrate comprising:
a substrate; and
a thin film transistor having a semiconductor layer formed on the substrate, and a semiconductor layer-adjoining insulating layer formed to be in contact with the semiconductor layer,
wherein at least one semiconductor layer-adjoining insulating layer being a non-photosensitive polyimide insulating layer formed from a non-photosensitive polyimide resin.

19. The thin film transistor substrate according to claim 18, wherein a content of a polyimide resin contained in the non-photosensitive polyimide insulating layer is 80% by mass or greater.

20. The thin film transistor substrate according to claim 18, wherein a 5% weight loss temperature of the non-photosensitive polyimide insulating layer is 470° C. or higher.

21. The thin film transistor substrate according to claim 18, wherein the semiconductor layer is an oxide semiconductor layer.

22. The thin film transistor substrate according to claim 21, wherein the non-photosensitive polyimide insulating layer is formed by using a non-photosensitive polyimide resin composition containing at least a polyimide precursor as a polyimide component.

23. The thin film transistor substrate according to claim 18, wherein as for the semiconductor layer-adjoining insulating layer, a gate insulating layer in a top-gate type thin film transistor, or at least one of a gate insulating layer and a passivation layer in a bottom-gate type thin film transistor is at least the non-photosensitive polyimide insulating layer.

24. The thin film transistor substrate according to claim 1, wherein the substrate is a flexible substrate having a metal foil and a planarizing layer that is formed on the metal foil and contains polyimide.

25. The thin film transistor substrate according to claim 24, wherein the flexible substrate includes, on the planarizing layer, an adhesion layer containing an inorganic compound.

26. A method for producing a thin film transistor substrate, the thin film transistor substrate comprising a substrate, and a thin film transistor that has a semiconductor layer formed on the substrate, and a semiconductor layer-adjoining insulating layer formed to be in contact with the semiconductor layer, in which at least one semiconductor layer-adjoining insulating layer is a non-photosensitive polyimide insulating layer formed from a non-photosensitive polyimide resin,
the method comprising steps of:
a non-photosensitive polyimide film forming step of forming a non-photosensitive polyimide film formed from the non-photosensitive polyimide resin on the substrate; and
a non-photosensitive polyimide film patterning step of patterning the non-photosensitive polyimide film and forming the non-photosensitive polyimide insulating layer.

27. A method for producing a thin film transistor substrate, the thin film transistor substrate comprising a substrate, and a thin film transistor that has a semiconductor layer formed on the substrate, and a semiconductor layer-adjoining insulating layer formed to be in contact with the semiconductor layer, in which at least one semiconductor layer-adjoining insulating layer is a non-photosensitive polyimide insulating layer formed from a non-photosensitive polyimide resin,
the method comprising steps of:
a non-photosensitive polyimide precursor film forming step of a non-photosensitive polyimide precursor film containing a polyimide precursor on the substrate;
a non-photosensitive polyimide precursor pattern forming step of patterning the non-photosensitive polyimide precursor film, and forming a non-photosensitive polyimide precursor pattern; and
an imidization step of imidizing the polyimide precursor contained in the non-photosensitive polyimide precursor pattern, and forming the non-photosensitive polyimide insulating layer.
